(19) United States
(12) Patent Application Publication
(10) Pub. No.: US 2025/0228070 A1
(43) Pub. Date: Jul. 10, 2025

(54) LIGHT-EMITTING DEVICE AND ELECTRONIC APPARATUS AND ELECTRONIC EQUIPMENT EACH INCLUDING THE SAME

(71) Applicant: Samsung Display Co., Ltd., Yongin-si (KR)

(72) Inventors: Gyeongheon Kim, Yongin-si (KR); Donguk Kang, Yongin-si (KR); Seran Kim, Yongin-si (KR); Hoilim kim, Yongin-si (KR); Saerom Park, Yongin-si (KR); Dongsun Yoo, Yongin-si (KR); Junyoung Lee, Yongin-si (KR)

(21) Appl. No.: 19/008,451

(22) Filed: Jan. 2, 2025

(30) Foreign Application Priority Data
Jan. 4, 2024 (KR) 10-2024-0001552

(51) Int. Cl. H10K 50/858; C07F 5/02; H10K 50/15; H10K 101/30

(52) U.S. Cl. CPC H10K 50/858; C07F 5/027; H10K 50/156; H10K 2101/30

(57) ABSTRACT

An electronic apparatus and electronic equipment each include a light-emitting device. The light-emitting device includes a first electrode, a second electrode opposite the first electrode, an interlayer arranged between the first electrode and the second electrode, and a capping layer, wherein the interlayer may include a hole transport region and an emission layer, the hole transport region may be arranged between the first electrode and the emission layer, the hole transport region may include a first layer and a second layer, the first layer may be arranged between the first electrode and the second layer, the first layer may include a first hole transport material and a p-dopant, the second layer may include a second hole transport material.

### CROSS-REFERENCE TO RELATED APPLICATION

The present application claims priority to and the benefit of Korean Patent Application No. 10-2024-0001552, filed on Jan. 4, 2024, in the Korean Intellectual Property Office, the entire content of which is incorporated herein by reference.

### BACKGROUND

### 1. Field

Embodiments of the present disclosure described herein are related to a light-emitting device and an electronic apparatus and electronic equipment each including the same.

### 2. Description of the Related Art

Self-emissive devices (for example, organic light-emitting devices and/or the like) among light-emitting devices have relatively wide viewing angles, high contrast ratios, short response times, and excellent or suitable characteristics in terms of luminance, driving voltage, and response speed.

In a light-emitting device, a first electrode is located on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. These excitons transit (relax) from an excited state to a ground state to thereby generate light (e.g., to display images).

### SUMMARY

Aspects according to one or more embodiments of the present disclosure are directed toward a light-emitting device having a low driving voltage, high luminescence efficiency, and long lifespan and an electronic apparatus and electronic equipment each including the light-emitting device.

Additional aspects will be set forth in part in the description which follows and, in part, will be apparent from the description, or may be learned by practice of the presented embodiments of the disclosure.

According to one or more embodiments, a light-emitting device includes a first electrode, a second electrode opposite the first electrode (e.g., facing the first electrode), an interlayer arranged between the first electrode and the second electrode, and a capping layer,
the interlayer may include a hole transport region and an emission layer,
the hole transport region may be arranged between the first electrode and the emission layer,
the hole transport region may include a first layer and a second layer,
the first layer may be arranged between the first electrode and the second layer,
the first layer may include a first hole transport material and a p-dopant,
the second layer may include a second hole transport material,
a difference between triplet energy of the p-dopant and triplet energy of the second hole transport material (e.g., an absolute value of the difference) may be about 1.50 eV or greater,
the second hole transport material may be an amine-containing compound including i) a 1,1′:3′,1″-terphen-2′-yl group and ii) a cycloalkane group having 3 to 10 carbon atoms,
the emission layer may be configured to emit first light,
the capping layer may be arranged in a path of travel of the first light,
the capping layer may include a first capping material, and
the first capping material may satisfy at least one selected from among Conditions 1 to 3:

### Condition 1

the first capping material has a refractive index of about 1.70 or greater for light having a wavelength of about 633 nm;

### Condition 2

The first capping material has a refractive index of about 1.90 or greater for light having a wavelength of about 530 nm; and

### Condition 3

the first capping material has a refractive index of about 2.10 or greater for light having a wavelength of about 450 nm.

According to one or more embodiments, a light-emitting device includes a first electrode, a second electrode opposite the first electrode (e.g., facing the first electrode), an interlayer arranged between the first electrode and the second electrode, and a capping layer,
the interlayer may include a hole transport region and an emission layer,
the hole transport region may be arranged between the first electrode and the emission layer,
the hole transport region may include a first layer and a second layer,
the first layer may be arranged between the first electrode and the second layer,
the first layer may include a first hole transport material and a p-dopant,
the second layer may include a second hole transport material,
a difference between triplet energy of the p-dopant and triplet energy of the second hole transport material (e.g., an absolute value of the difference) may be about 1.50 eV or greater,
the second hole transport material may be an amine-containing compound including i) a 1,1′:3′,1″-terphen-2′-yl group and ii) a cycloalkane group having 3 to 10 carbon atoms,
the emission layer may be configured to emit first light,
the capping layer may be arranged in a path of travel of the first light,
the capping layer may include a first capping material, and
the first capping material may be a compound represented by Formula 8-1:

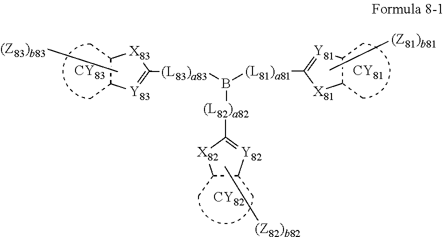

wherein in Formula 8-1,
L₈₁ to L₈₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a81 to a83 may each independently be an integer from 1 to 5,
X₈₁ to X₈₃ may each independently be O or S,
Y₈₁ to Y₈₃ may each independently be N or C,
ring CY₈₁ to ring CY₈₃ may each independently be a C₃-C₆₀ carbocyclic group or a C₁-C₆₀ heterocyclic group,
Z₈₁ to Z₈₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b81 to b83 may each independently be an integer from 0 to 20,
R₁₀ₐ may be
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, and Q₃₁ to Q₃₃ may each independently be hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

For example, ring CY₈₁ to ring CY₈₃ may each independently be a benzene group, a naphthalene group, a phenanthrene group, an anthracene group, a pyrene group, a quinoline group, an isoquinoline group, or a phenanthroline group, wherein at least one selected from among ring CY₈₁ to ring CY₈₃ may be a naphthalene group, a phenanthrene group, an anthracene group, a pyrene group, a quinoline group, an isoquinoline group, or a phenanthroline group.

According to one or more embodiments, a light-emitting device includes a first electrode, a second electrode opposite the first electrode (e.g., facing the first electrode), an interlayer arranged between the first electrode and the second electrode, and a capping layer,
the interlayer may include a hole transport region and an emission layer,
the hole transport region may be arranged between the first electrode and the emission layer,
the hole transport region may include a first layer and a second layer,
the first layer may be arranged between the first electrode and the second layer,
the first layer may include a first hole transport material and a p-dopant,
the second layer may include a second hole transport material,
the p-dopant may be a compound represented by Formula 1,
the second hole transport material may be an amine-containing compound including i) a 1,1′: 3′, 1″-terphen-2′-yl group and ii) a cycloalkane group having 3 to 10 carbon atoms,
the emission layer may be configured to emit first light,
the capping layer may be arranged in a path of travel of the first light,
the capping layer may include a first capping material, and
the first capping material may satisfy at least one selected from among Conditions 1 to 3:

### Condition 1

the first capping material has a refractive index of about 1.70 or greater for light having a wavelength of about 633 nm;

### Condition 2

the first capping material has a refractive index of about 1.90 or greater for light having a wavelength of about 530 nm; and

### Condition 3

the first capping material has a refractive index of about 2.10 or greater for light having a wavelength of about 450 nm.

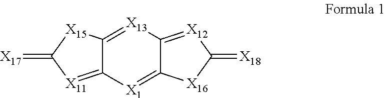

wherein in Formula 1,
X₁₁ may be C(Z₁₁) or N, X₁₂ may be C(Z₁₂) or N, X₁₃ may be C-[(L₁₃)ₐ₁₃-(Z₁₃)_{b13}] or N, X₁₄ may be C-[(L₁₄)ₐ₁₄-(Z₁₄)_{b14}] or N,
X₁₅ and X₁₆ may each independently be O, S, Se, S(═O), or S(═O)₂,
X₁₇ may be C(Z₁₇ₐ)(Z_{17b}), N(Z₁₇), O, S, or Se,
X₁₈ may be C(Z₁₈ₐ)(Z_{18b}), N(Z₁₈), O, S, or Se,
L₁₃ and L₁₄ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a13 and a14 may each independently be an integer from 1 to 5,
Z₁₁ to Z₁₄, Z₁₇ₐ, Z_{17b}, Z₁₇, Z₁₈ₐ, Z_{18b}, and Z₁₈ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b13 and b14 may each independently be an integer from 0 to 20,
Formula 1 may include at least one electron-withdrawing group,
Q₁ to Q₃ are each the same as described herein, and
R₁₀ₐ is the same as described herein.

For example, the electron-withdrawing group may be
—F or a cyano group, or
a C₁-C₆₀ alkyl group, a C₁-C₆₀ alkoxy group, or a C₆-C₆₀ aryl group, each substituted with —F, a cyano group, or any combination thereof.

According to one or more embodiments, a light-emitting device includes a first electrode, a second electrode opposite the first electrode (e.g., facing the first electrode), an interlayer arranged between the first electrode and the second electrode, and a capping layer,
the interlayer may include a hole transport region and an emission layer,
the hole transport region may be arranged between the first electrode and the emission layer,
the hole transport region may include a first layer and a second layer,
the first layer may be arranged between the first electrode and the second layer,
the first layer may include a first hole transport material and a p-dopant,
the second layer may include a second hole transport material,
the p-dopant may be a compound represented by Formula 1,
the second hole transport material may be an amine-containing compound including i) a 1,1′: 3′, 1″-terphen-2′-yl group and ii) a cycloalkane group having 3 to 10 carbon atoms,
the emission layer may be configured to emit first light,
the capping layer may be arranged in a path of travel of the first light,
the capping layer may include a first capping material, and
the first capping material may be a compound represented by Formula 8.

According to one or more embodiments, an electronic apparatus includes the light-emitting device.

According to one or more embodiments, electronic equipment includes the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a structure of a light-emitting device according to one or more embodiments;

FIGS. 2 and 3 are each a schematic cross-sectional view of a structure of a light-emitting apparatus, which is one selected from among electronic apparatuses according to one or more embodiments; and

FIGS. 4, 5, 6A, 6B, and 6C are each a schematic view of a structure of electronic equipment according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail, by referring to the drawings, to explain aspects of the present description. As utilized herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

As used herein, the singular forms “a,” “an” and “the” are intended to include the plural forms as well, unless the context clearly indicates otherwise.

In the present disclosure, when dot, dots, particle, or particles are spherical, “size” or “diameter” indicates a particle diameter or an average particle diameter, and when they are non-spherical, the “size” or “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

A light-emitting device according to one or more embodiments may include: a first electrode; a second electrode opposite the first electrode (e.g., facing the first electrode); an interlayer arranged between the first electrode and the second electrode; and a capping layer.

In one or more embodiments, the first electrode may be an anode, and the second electrode may be a cathode.

The interlayer may include a hole transport region and an emission layer. The hole transport region may be arranged between the first electrode and the emission layer.

The hole transport region may include a first layer and a second layer, and the first layer may be arranged between the first electrode and the second layer. Accordingly, the light-emitting device may have a structure in which the first electrode, the first layer, the second layer, the emission layer, and the second electrode are sequentially stacked.

The first layer may include a first hole transport material and a p-dopant, and the second layer may include a second hole transport material. The first hole transport material may be a matrix material, and the first hole transport material may be doped with the p-dopant in a substantially uniform or ununiform manner.

In one or more embodiments, an amount of the p-dopant may be about 0.01 parts by weight to about 10 parts by weight, about 0.1 parts by weight to about 8 parts by weight, or about 0.5 parts by weight to about 5 parts by weight, based on 100 parts by weight of the first layer.

The second layer may not include (e.g., may exclude) any p-dopant.

In one or more embodiments, the second layer may include (e.g., consist of) the hole transport material.

A difference between the triplet energy of the p-dopant and the triplet energy of the second hole transport material, i.e., the absolute value of the difference between the triplet energy of the p-dopant and the triplet energy of the second hole transport material may be about 1.50 eV or greater, about 1.50 eV to about 3.00 eV, about 1.50 eV to about 2.80 eV, about 1.50 eV to about 2.60 eV, about 2.00 eV to about 3.00 eV, about 2.00 eV to about 2.80 eV, about 2.00 eV to about 2.60 eV, about 2.20 eV to about 3.00 eV, about 2.20 eV to about 2.80 eV, about 2.20 eV to about 2.60 eV, about 2.40 eV to about 3.00 eV, about 2.40 eV to about 2.80 eV, or about 2.40 eV to about 2.60 eV.

In one or more embodiments, the triplet energy of the p-dopant may be about 0.05 eV to about 0.30 eV, about 0.10 eV to about 0.27 eV, or about 0.10 eV to about 0.24 eV.

In one or more embodiments, singlet energy of the p-dopant may be about 1.00 eV to about 2.50 eV, about 1.10 eV to about 2.50 eV, about 1.30 eV to about 2.50 eV, about 1.38 eV to about 2.50 eV, or about 1.38 eV to about 2.29 eV.

In one or more embodiments, a difference between the triplet energy and singlet energy of the p-dopant may be about 0.80 eV to about 2.50 eV, about 0.80 eV to about 2.45 eV, about 0.90 eV to about 2.50 eV, about 1.00 eV to about 2.50 eV, about 1.19 eV to about 2.50 eV, or about 1.19 eV to about 2.08 eV.

In one or more embodiments, the highest occupied molecular orbital (HOMO) energy level of the p-dopant may be about −7.80 eV to about −6.30 eV, about −7.59 eV to about −6.30 eV, or about −7.59 eV to about −6.78 eV.

In one or more embodiments, the lowest unoccupied molecular orbital (LUMO) energy level of the p-dopant may be about −5.90 eV to about −4.70 eV, about-5.78 eV to about −4.70 eV, or about −5.78 eV to about −4.88 eV.

More details for the p-dopant are as described herein.

The first hole transport material and the second hole transport material may each be an amine-containing compound.

For example, the first hole transport material may be different from the second hole transport material.

In one or more embodiments, the first hole transport material may be a diamine-containing compound, and the second hole transport material may be a monoamine-containing compound.

The second hole transport material may be an amine-containing compound including i) a 1,1′: 3′, 1″-terphen-2′-yl group and ii) a cycloalkane group having 3 to 10 carbon atoms.

In the specification, in “the amine-containing compound including i) a 1,1′: 3′, 1″-terphen-2′-yl group and ii) a cycloalkane group having 3 to 10 carbon atoms”, i) “a 1,1′: 3′, 1″-terphen-2′-yl group” may be unsubstituted or substituted with a substituent such as Z₂₃ₐ of Formula 2 described herein (excluding hydrogen), and ii) “a cycloalkane group having 3 to 10 carbon atoms” may be unsubstituted or substituted with a substituent Z₂₂ of Formula 2 described herein (excluding hydrogen).

In one or more embodiments, the HOMO energy level of the second hole transport material may be about −5.30 eV to about −4.60 eV, about −5.06 eV to about −4.60 eV, or about −5.06 eV to about −4.94 eV.

In one or more embodiments, the LUMO energy level of the second hole transport material may be about −1.40 eV to about −1.00 eV, about −1.29 eV to about-1.00 eV, or about −1.29 eV to about −1.10 eV.

The first hole transport material may be selected from among compounds which may be included in the hole transport region descried in the specification (for example, a compound represented by Formula 201, a compound represented by Formula 202, and/or the like.)

More details for the second hole transport material may each independently be the same as described in the specification.

The emission layer may be configured to emit a first light, and the capping layer may be arranged in a path of travel of the first light. The first light may have a first emission spectrum, and the first emission spectrum may have an emission peak wavelength (maximum emission wavelength), and/or the like.

The capping layer may be located in a path of travel of the first light and is extracted to the outside of the light-emitting device, thereby increasing the external extraction rate of the first light.

For example, the first electrode may be a semi-transmissive electrode or a transmissive electrode, and the capping layer may be arranged outside the first electrode.

In one or more embodiments, the second electrode may be a semi-transmissive electrode or a transmissive electrode, and the capping layer may be arranged outside the second electrode.

For example, the first light may be red light, green light, or blue light.

In one or more embodiments, the emission peak wavelength (or, maximum emission wavelength) of the first light may be about 610 nm to about 680 nm.

In one or more embodiments, the emission peak wavelength of the first light may be about 500 nm to about 590 nm.

In one or more embodiments, the emission peak wavelength of the first light may be about 400 nm to about 490 nm.

The capping layer may include a first capping material, and the first capping material may satisfy at least one selected from among Conditions 1 to 3:

### Condition 1

The first capping material has a refractive index of about 1.70 or greater (for example, about 1.70 to about 2.00 or about 1.80 to about 1.90) for light having a wavelength of about 633 nm;

### Condition 2

The first capping material has a refractive index of about 1.90 or greater (for example, about 1.90 to about 2.10 or about 1.95 to about 2.05) for light having a wavelength of about 530 nm; and

### Condition 3

The first capping material has a refractive index of 2.10 or greater (for example, about 2.10 to about 2.35 or about 2.20 to about 2.30) for light having a wavelength of about 450 nm.

In one or more embodiments, the light-emitting device may satisfy all of Conditions 1 to 3.

In one or more embodiments, the first capping material may satisfy Condition 1, the first light may be red light, and the first capping material may have a refractive index of about 1.70 or greater (for example, about 1.70 to about 2.00 or about 1.80 to about 1.90) for the first light.

In one or more embodiments, the first capping material may satisfy Condition 2, the first light may be green light, and the first capping material may have a refractive index of about 1.90 or greater (for example, about 1.90 to about 2.10 or about 1.95 to about 2.05) for the first light.

In one or more embodiments, the first capping material may satisfy Condition 3, the first light may be blue light, and the first capping material may have a refractive index of 2.10 or greater (for example, about 2.10 to about 2.35 or about 2.20 to about 2.30) for the first light.

The refractive index of the first capping material may be evaluated by measuring a refractive index of a film including (e.g., consisting of) the first capping material (see, for example, Evaluation Example 2).

The first capping material may be a boron-containing compound.

In one or more embodiments, the first capping material may include a benzoxazole group, a benzothiazole group, a naphthooxazole group, a naphthothiazole group, a phenanthrooxazole group, or a phenanthrothiazole group.

More details for the first capping material may each independently be the same as described in the specification.

The capping layer of the light-emitting device may be located outside the first electrode and/or outside the second electrode.

In one or more embodiments, the light-emitting device may further include at least one of a first capping layer located outside of the first electrode or a second capping layer located outside of the second electrode, wherein at least one of the first capping layer or the second capping layer may include the first capping material described in the specification.

In one or more embodiments, the light-emitting device may include:
a first capping layer located outside the first electrode and including the first capping material described in the specification;
a second capping layer located outside the second electrode and including the first capping material described in the specification; or
the first capping layer and the second capping layer.

In one or more embodiments, the light-emitting device may further include a third capping layer, and the third capping layer may include a compound which is different from the first capping material described in the specification. The third capping layer may be located in a path of travel of the first light emitted from the emission layer travels.

In one or more embodiments, the third capping layer may include a material having a refractive index of about 1.6 or more (at about 589 nm).

In one or more embodiments, the third capping layer may be an organic capping layer including an organic material, an inorganic capping layer including an inorganic material, or an organic-inorganic composite capping layer including an organic material and an inorganic material.

For example, the third capping layer may include a carbocyclic compound, a heterocyclic compound, an amine group-containing compound, a porphine derivative, a phthalocyanine derivative, a naphthalocyanine derivative, an alkali metal complex, an alkaline earth-metal complex, or any combination thereof. Optionally, the carbocyclic compound, the heterocyclic compound, and the amine group-containing compound may be substituted with a substituent including O, N, S, Se, Si, F, Cl, Br, I, or any combination thereof.

For example, the third capping layer may include a compound represented by Formula 201, a compound represented by Formula 202, or any combination thereof.

In one or more embodiments, the third capping layer may include at least one selected from among the Compounds HT28 to HT33, at least one selected from among Compounds CP1 to CP6, β-NPB, or any compound thereof:

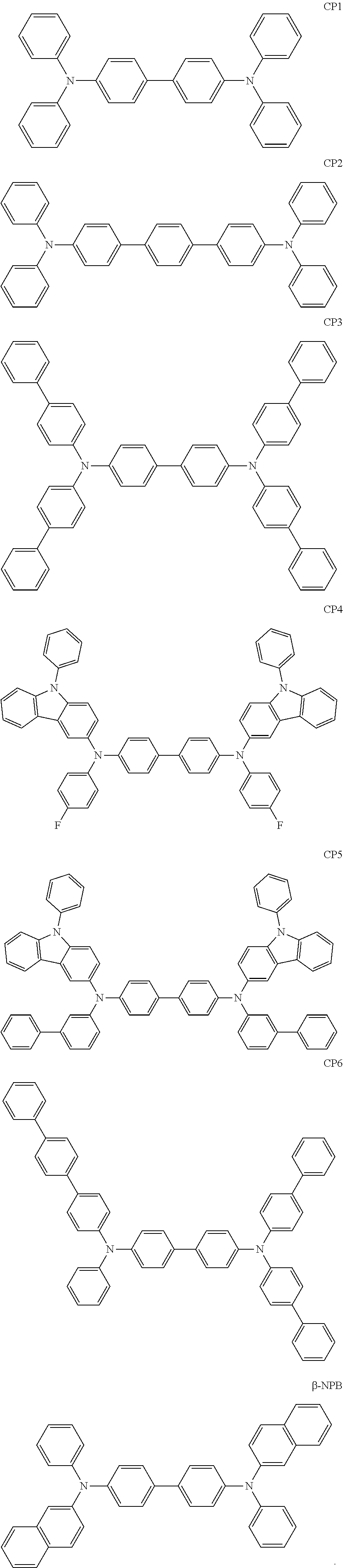

In one or more embodiments, the light-emitting device may further include:
i) a structure in which the first electrode, the interlayer, the second electrode, and the second capping layer (including the first capping material described in the specification) are sequentially stacked;
ii) a structure in which the first electrode, the interlayer, the second electrode, the third capping layer (including a compound different from the first capping material described in the specification), and the second capping layer (including the first capping material described in the specification) are sequentially stacked; or
ii) a structure in which the first electrode, the interlayer, the second electrode, the second capping layer (including the first capping material described in the specification), and the third capping layer (including a compound different from the first capping material described in the specification) are sequentially stacked.

In this regard, the first light emitted from the emission layer included in the interlayer may be extracted to the outside of the light-emitting device through the second electrode and then the second capping layer (or the second capping layer and the third capping layer), and the second electrode may be a semi-transmissive electrode or a transmissive electrode.

According to one or more embodiments of the disclosure, 1) in the light-emitting device, the difference between the triplet energy of the p-dopant and the triplet energy of the second hole transport material may be 1.50 eV or greater, 2) the second hole transport material may be an amine-containing compound including i) a 1,1′: 3′, 1″-terphen-2′-yl group and ii) a cycloalkane group having 3 to 10 carbon atoms, and 3) the light-emitting device may include the capping layer including the first capping material satisfying at least one selected from among Conditions 1 to 3 (for example, a compound represented by Formula 8 or a compound represented by Formula 8-1). Accordingly, both (e.g., simultaneously) internal and external luminescence efficiency may be improved, and the light-emitting device may have a low driving voltage, high luminescence efficiency, and long lifespan.

According to one or more embodiments of the disclosure, 1) in the light-emitting device, the p-dopant may be a compound represented by Formula 1, 2) the second hole transport material may be an amine-containing compound including i) a 1,1′: 3′, 1″-terphen-2′-yl group and ii) a cycloalkane group having 3 to 10 carbon atoms, and 3) the light-emitting device may include the capping layer including the first capping material satisfying at least one selected from among Conditions 1 to 3 (for example, a compound represented by Formula 8 or a compound represented by Formula 8-1). Accordingly, both (e.g., simultaneously) internal and external luminescence efficiency may be improved, and the light-emitting device may have a low driving voltage, high luminescence efficiency, and long lifespan.

In the specification, the HOMO energy level, LUMO energy level, singlet energy, triplet energy, and ΔE_{ST} energy may be evaluated by utilizing the density functional theory (DFT) and time dependent DFT (TD-DFT) (for example, see Evaluation Example 1).

The term “interlayer” as utilized herein refers to a single layer and/or all of a plurality of layers located between the first electrode and the second electrode of the light-emitting device.

One or more embodiments provide an electronic apparatus including the light-emitting device. The electronic apparatus may further include a thin-film transistor. For example, the electronic apparatus may further include a thin-film transistor including a source electrode and a drain electrode, wherein the first electrode of the light-emitting device may be electrically connected to the source electrode or the drain electrode. In one or more embodiments, the electronic apparatus may further include a color filter, a color conversion layer, a touch screen layer, a polarizing layer, or any combination thereof. More details for the electronic apparatus are as described herein.

One or more embodiments provide electronic equipment including the light-emitting device.

For example, the electronic equipment may be one selected from among a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard.

### Description of Formulae

In one or more embodiments, the p-dopant may be a compound represented by Formula 1:

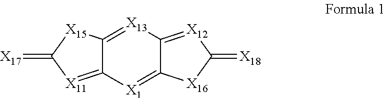

wherein in Formula 1,
X₁₁ may be C(Z₁₁) or N, X₁₂ may be C(Z₁₂) or N, X₁₃ may be C-[(L₁₃)ₐ₁₃-(Z₁₃)_{b13}] or N, X₁₄ may be C-[(L₁₄)ₐ₁₄-(Z₁₄)_{b14}] or N,
X₁₅ and X₁₆ may each independently be O, S, Se, S(═O), or S(═O)₂,
X₁₇ may be C(Z₁₇ₐ)(Z_{17b}), N(Z₁₇), O, S, or Se,
X₁₈ may be C(Z₁₈ₐ)(Z_{18b}), N(Z₁₈), O, S, or Se,
L₁₃ and L₁₄ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a13 and a14 may each independently be an integer from 1 to 5,
Z₁₁ to Z₁₄, Z₁₇ₐ, Z_{17b}, Z₁₇, Z₁₈ₐ, Z_{18b}, and Z₁₈ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b13 and b14 may each independently be an integer from 0 to 20,

Formula 1 may include at least one electron-withdrawing group,
Q₁ to Q₃ are each the same as described herein, and
R₁₀ₐ is the same as described herein.

In one or more embodiments, the electron-withdrawing group may be:
—F or a cyano group; or
a C₁-C₆₀ alkyl group, a C₁-C₆₀ alkoxy group, or a C₆-C₆₀ aryl group, each substituted with —F, a cyano group, or any combination thereof.

In one or more embodiments, the electron-withdrawing group may be:
—F or a cyano group; or
a C₁-C₁ alkyl group, a C₁-C₁ alkoxy group, or a phenyl group, each substituted with —F, a cyano group, or any combination thereof.

In one or more embodiments, at least one selected from among Z₁₃ and Z₁₄ may be —F, a fluorinated C₁-C₁₀ alkyl group, a fluorinated C₁-C₁₀ alkoxy group, or a fluorinated phenyl group.

In one or more embodiments, X₁₇ may be C(Z₁₇ₐ)(Z_{17b}), X₁₈ may be C(Z₁₈ₐ)(Z_{18b}), and Z₁₇ₐ, Z_{17b}, Z₁₈ₐ, and Z_{18b} may each be a cyano group.

In one or more embodiments, X₁₃ may be C-[(L₁₃)ₐ₁₃-(Z₁₃)_{b13}], X₁₄ may be C-[(L₁₄)ₐ₁₄-(Z₁₄)_{b14}], L₁₃ and L₁₄ may each be a single bond or a benzene group, a13 and a14 may each be 1, Z₁₃ and Z₁₄ may each independently be —F, a fluorinated C₁-C₁₀ alkyl group, a fluorinated C₁-C₁₀ alkoxy group, or a fluorinated phenyl group, and b13 and b14 may each independently be an integer from 1 to 5.

The second hole transport material may be a compound represented by Formula 2:

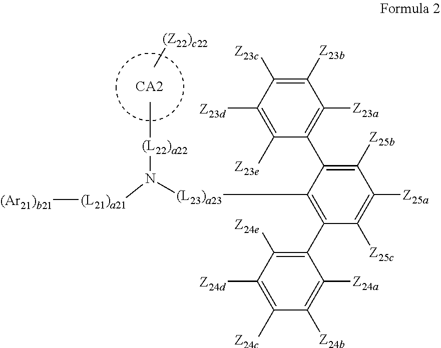

wherein in Formula 2,
L₂₁ to L₂₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₂₁ may be a C₃-C₆₀ carbocyclic group unsubstituted or substituted with at least one R₁₀ₐ or a C₁-C₆₀ heterocyclic group unsubstituted or substituted with at least one R₁₀ₐ,
a21 to a23 and b21 may each independently be an integer from 1 to 5, and c22 may be an integer selected from 5 to 19
ring CA2 may be a cycloalkane group having 3 to 10 carbon atoms,
Z₂₂, Z₂₃ₐ to Z₂₃ₑ, Z₂₄ₐ to Z₂₄ₑ, and Z₂₅ₐ to Z_{25c} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
Q₁ to Q₃ are each the same as described herein, and
R₁₀ₐ is the same as described herein.

In one or more embodiments, at least one of Ar₂₁ may be a fluorene group, a spirobifluorene group, a dibenzofuran group, or a dibenzothiophene group.

In one or more embodiments, ring CA2 may be a cyclopentane group, a cyclohexane group, a cycloheptane group, a cyclooctane group, an adamantane group, a norbornane group (bicyclo[2.2.1]heptane group), a bicyclo[1.1.1]pentane group, a bicyclo[2.1.1]hexane group, or a bicyclo[2.2.2]octane group.

In one or more embodiments, at least one of Z₂₃ₐ, Z₂₄ₐ, or Z₂₅ₐ may be a phenyl group unsubstituted or substituted with deuterium, a C₁-C₆₀ alkyl group, a deuterated C₁-C₆₀ alkyl group, or any combination thereof.

The first capping material may be a compound represented by Formula 8:

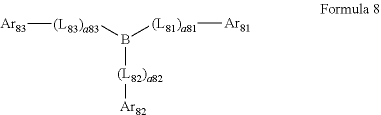

wherein in Formula 8,
L₈₁ to L₈₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a81 to a83 may each independently be an integer from 1 to 5,
Ar₈₁ to Ar₈₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
R₁₀ₐ is the same as described herein.

In one or more embodiments, Ar₈₁ to Ar₈₃ may each independently be a benzoxazole group, a benzothiazole group, a naphthooxazole group, a naphthothiazole group, a phenanthrooxazole group, or a phenanthrothiazole group, each unsubstituted or substituted with at least one R₁₀ₐ.

In one or more embodiments, at least one selected from among Ar₈₁ to Ar₈₃ may each independently be a naphthooxazole group, a naphthothiazole group, a phenanthrooxazole group, or a phenanthrothiazole group, each unsubstituted or substituted with at least one R₁₀ₐ.

For example, the first capping material may be a compound represented by Formula 8-1:

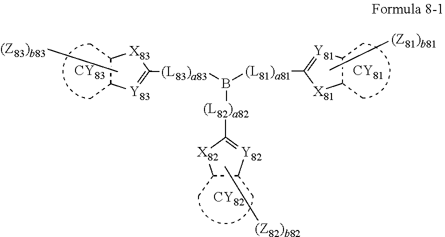

wherein in Formula 8-1,
L₈₁ to L₈₃ and a81 to a83 may each independently be the same as described herein,
X₈₁ to X₈₃ may each independently be O or S,
Y₈₁ to Y₈₃ may each independently be N or C,
ring CY₈₁ to ring CY₈₃ may each independently be a C₃-C₆₀ carbocyclic group or a C₁-C₆₀ heterocyclic group,
Z₈₁ to Z₈₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b81 to b83 may each independently be an integer from 0 to 20,
Q₁ to Q₃ are each the same as described herein in connection with Q₁₁, and
R₁₀ₐ is the same as described herein.

In one or more embodiments, ring CY₈₁ to ring CY₈₃ may each independently be: a 6-membered ring; or a polycyclic group in which two or more 6-membered rings are condensed with each other, and the 6-membered ring may be a benzene group, a pyridine group, a pyrimidine group, a pyridazine group, or a pyrazine group.

In one or more embodiments, at least one selected from among ring CY₈₁ to ring CY₈₃ may each independently be a polycyclic group in which two or more 6-membered rings are condensed with each other, and the 6-membered ring may be a benzene group, a pyridine group, a pyrimidine group, a pyridazine group, or a pyrazine group.

In one or more embodiments, at least one selected from among ring CY₈₁ to ring CY₈₃ may be a naphthalene group, a phenanthrene group, an anthracene group, a pyrene group, a quinoline group, an isoquinoline group, or a phenanthroline group.

In one or more embodiments, ring CY₈₁ to ring CY₈₃ may each independently be a benzene group, a naphthalene group, a phenanthrene group, an anthracene group, a pyrene group, a quinoline group, an isoquinoline group, or a phenanthroline group, wherein at least one selected from among ring CY₈₁ to ring CY₈₃ may be a naphthalene group, a phenanthrene group, an anthracene group, a pyrene group, a quinoline group, an isoquinoline group, or a phenanthroline group.

In Formulae 1, 2, 8, and 8-1, L₁₃, L₁₄, L₂₁ to L₂₃, and L₈₁ to L₈₃ may each independently be:
a single bond; or
a benzene group, a naphthalene group, a fluorene group, a spirobifluorene group, a dibenzofuran group, a dibenzothiophene group, or a carbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a trimethylsilyl group, a triphenylsilyl group, or any combination thereof.

In Formulae 1, 2, 8, and 8-1, a13, a14, a21 to a23, and a81 to a83 may each independently be 1, 2, or 3.

In Formulae 1, 2, 8, and 8-1, Z₁₁ to Z₁₄, Z₁₇ₐ, Z_{17b}, Z₁₇, Z₁₈ₐ, Z_{18b}, Z₁₈, Z₂₂, Z₂₃ₐ to Z₂₃ₑ, Z₂₄ₐ to Z₂₄ₑ, Z₂₅ₐ to Z_{25c}, Z₈₁ to Z₈₃, and R₁₀ₐ may each independently be:

hydrogen, deuterium, —F, or a cyano group;

a C₁-C₂₀ alkyl group, a C₁-C₂₀ alkoxy group, or a C₃-C₁₀ cycloalkyl group, each unsubstituted or substituted with deuterium, —F, a cyano group, a C₁-C₂₀ alkyl group, a C₁-C₂₀ alkoxy group, or any combination thereof;

a phenyl group, a naphthyl group, a fluorenyl group, a spirobifluorenyl group, a dibenzofuranyl group, a dibenzothiophenyl group (or dibenzothienyl group), or a carbazolyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a trimethylsilyl group, a triphenylsilyl group, or any combination thereof; or
a trimethylsilyl group or a triphenylsilyl group.

In Formulae 1, 2, 8, and 8-1, R₁₀ₐ may not be hydrogen.

In the specification, R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyrdazinyl group, a pyrazinyl group, a triazinyl group, or any combination thereof.

The term “biphenyl group” as utilized herein refers to a monovalent substituent having a structure in which two benzene groups are connected to each other through a single bond.

Examples of the C₃-C₁₀ cycloalkyl group as utilized herein are a cyclopentyl group, a cyclohexyl group, a cycloheptyl group, an adamantanyl group, a norbornanyl group, and/or the like.

The term “deuterated” as utilized herein includes the meaning of both (e.g., simultaneously) fully deuterated and partially deuterated.

The term “fluorinated” as utilized herein includes the meaning of both (e.g., simultaneously) fully fluorinated and partially fluorinated.

In one or more embodiments, in Formulae 1, 2, 8, and 8-1, Z₁₁ to Z₁₄, Z₁₇ₐ, Z_{17b}, Z₁₇, Z₁₈ₐ, Z_{18b}, Z₁₈, Z₂₂, Z₂₃ₐ to Z₂₃ₑ, Z₂₄ₐ to Z₂₄ₑ, Z₂₅ₐ to Z_{25c}, Z₈₁ to Z₈₃, and R₁₀ₐ may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzothiazolyl group, a benzoisoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof:

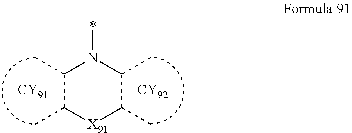

wherein in Formula 91,
ring CY₉₁ and ring CY₉₂ may each independently be a C₅-C₃₀ carbocyclic group unsubstituted or substituted with at least one R₁₀ₐ or a C₁-C₃₀ heterocyclic group unsubstituted or substituted with at least one R₁₀ₐ,
X₉₁ may be a single bond, O, S, N(R₉₁), B(R₉₁), C(R₉₁ₐ)(R_{91b}), or Si(R₉₁ₐ)(R_{91b}),
R₉₁, R₉₁ₐ, and R_{91b} may respectively be understood by referring to the descriptions provided herein,
R₁₀ₐ may be understood by referring to the description of R₁₀ₐ provided herein, and
* indicates a binding site to an adjacent atom.

For example, in Formula 91,
ring CY₉₁ and ring CY₉2 may each independently be a benzene group, a pyridine group, a pyrimidine group, a pyrazine group, a pyridazine group, or a triazine group, each unsubstituted or substituted with at least one R₁₀ₐ,
R₉₁, R₉₁ₐ, and R_{91b} may each independently be:
hydrogen or a C₁-C₁ alkyl group; or
a phenyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof.

In one or more embodiments, in Formulae 1, 2, 8 and 8-1, Z₁₁ to Z₁₄, Z₁₇ₐ, Z_{17b}, Z₁₇, Z₁₈ₐ, Z_{18b}, Z₁₈, Z₂₂, Z₂₃ₐ to Z₂₃ₑ, Z₂₄ₐ to Z₂₄ₑ, Z₂₅ₐ to Z_{25c}, Z₈₁ to Z₈₃, and R₁₀ₐ may each independently be hydrogen, deuterium, —F, a cyano group, a nitro group, —CH₃, —CD₃, —CD₂H, —CDH₂, —CF₃, —CF₂H, —CFH₂, a group represented by one (e.g., any one) selected from among Formulae 9-1 to 9-19, a group represented by one (e.g., any one) selected from among Formulae 10-1 to 10-246, —C(Q₁)(Q₂)(Q₃), —Si(Q₁)(Q₂)(Q₃), or —P(═O)(Q₁)(Q₂), wherein Q₁ to Q₃ are each the same as described above, and R₁₀ₐ is not hydrogen:

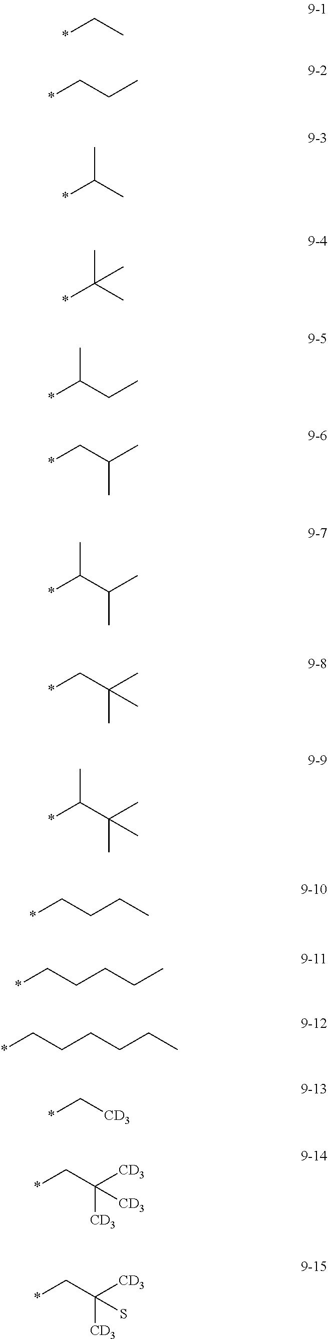

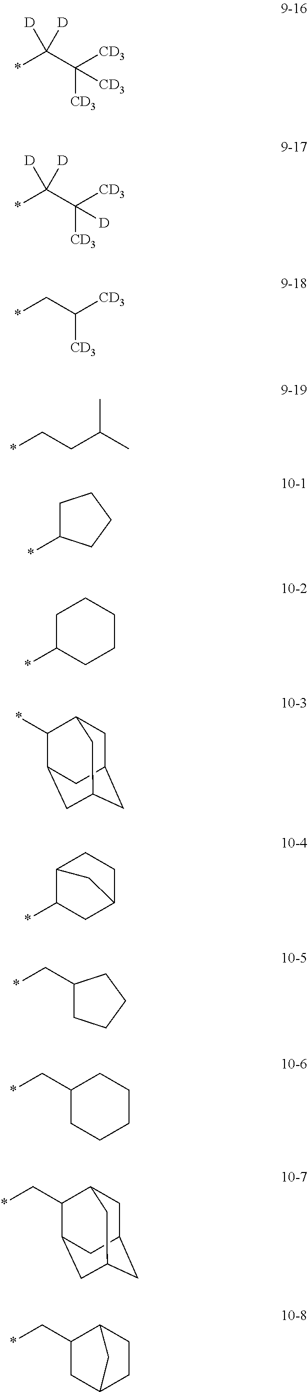

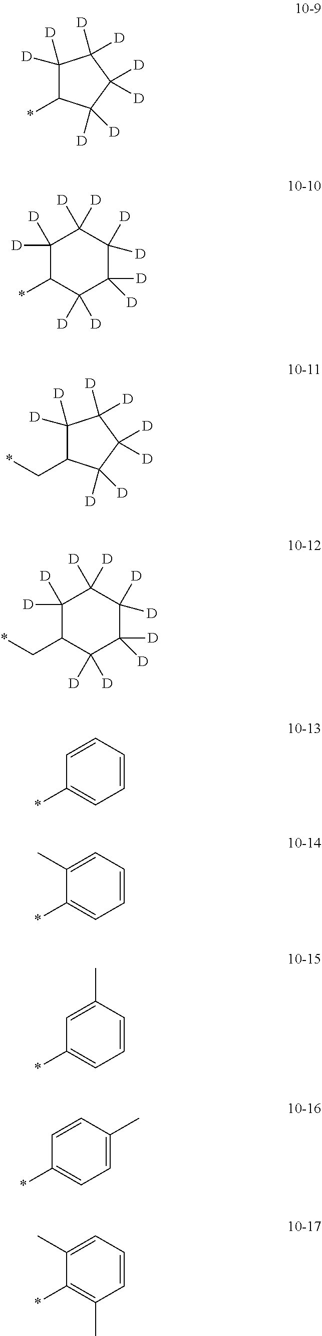

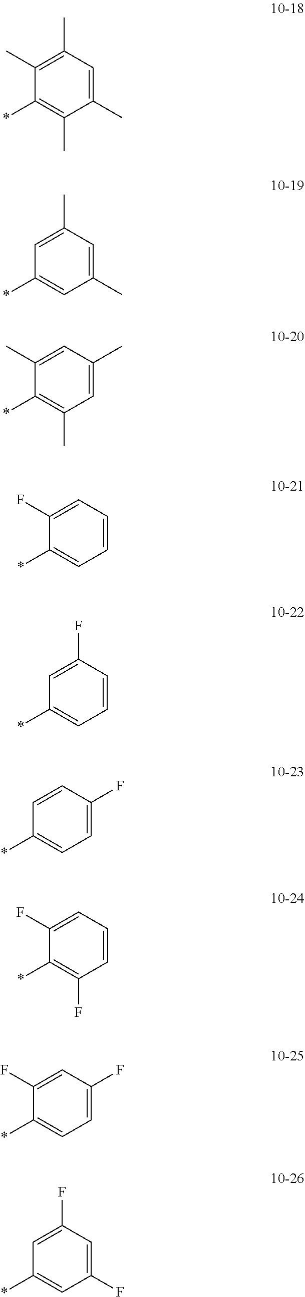

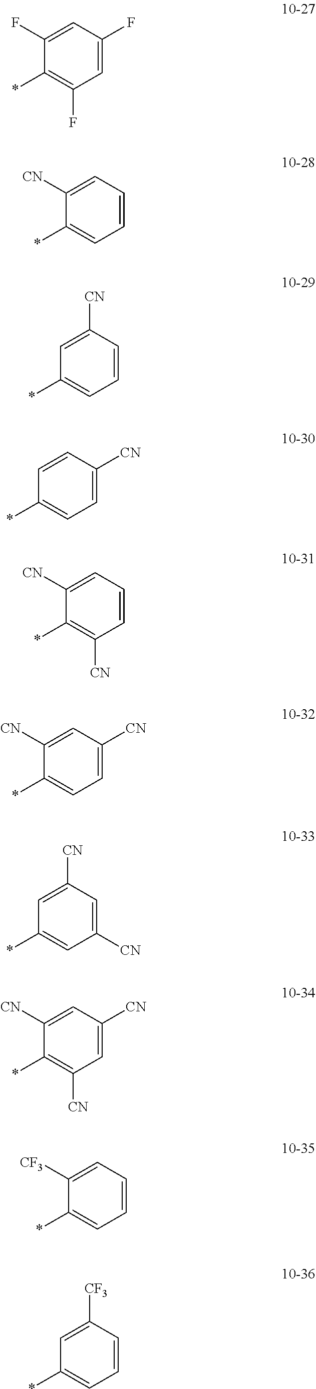

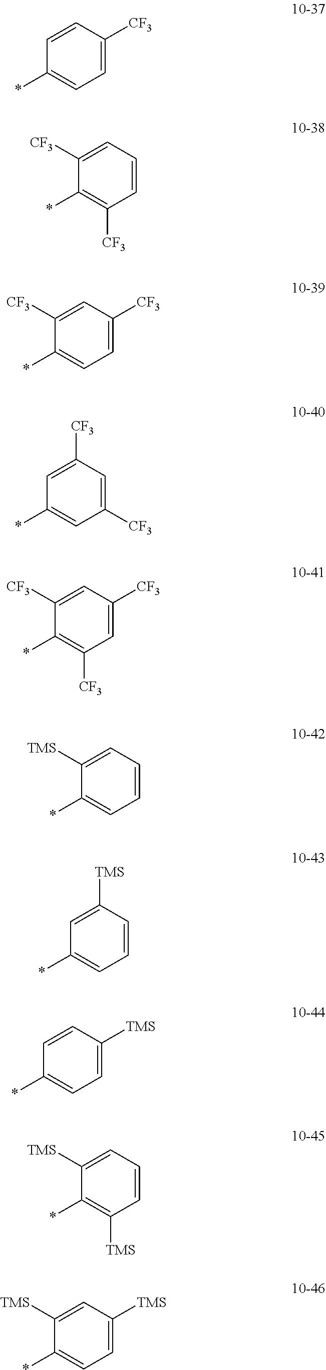

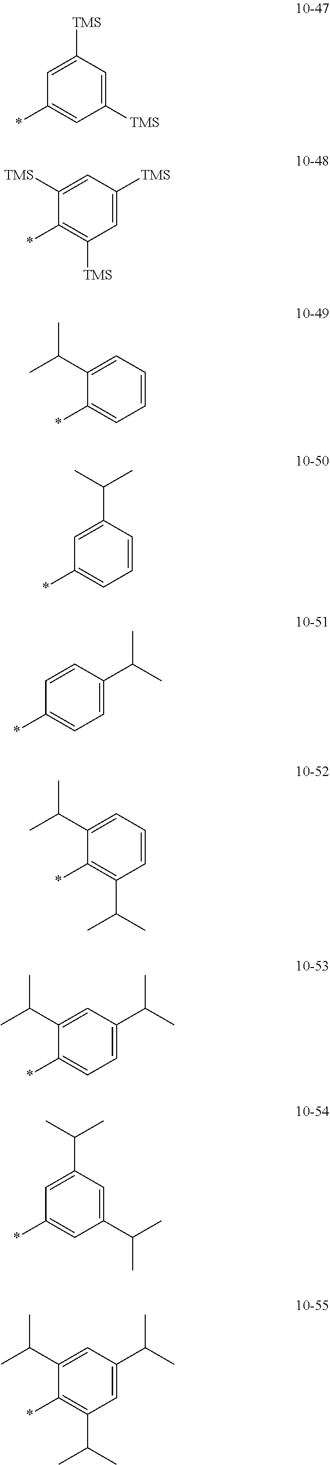

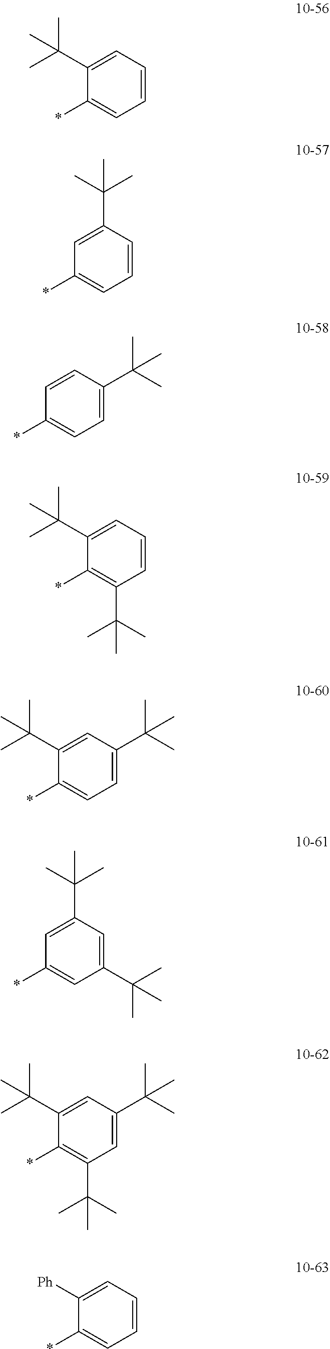

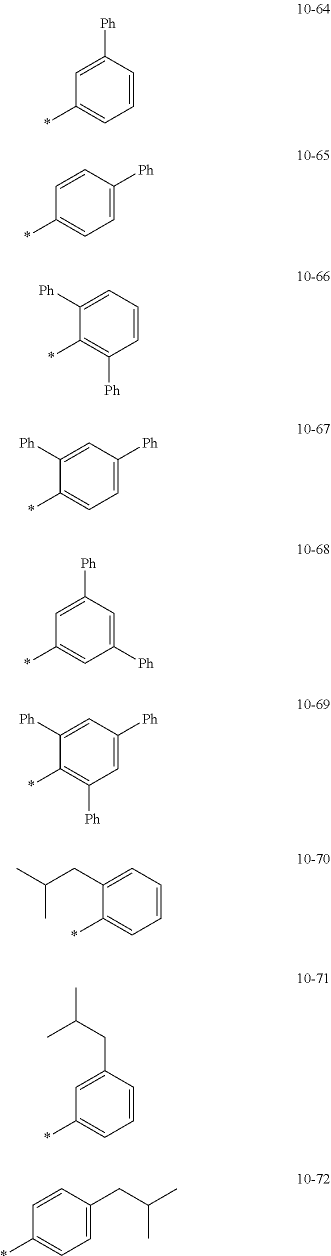

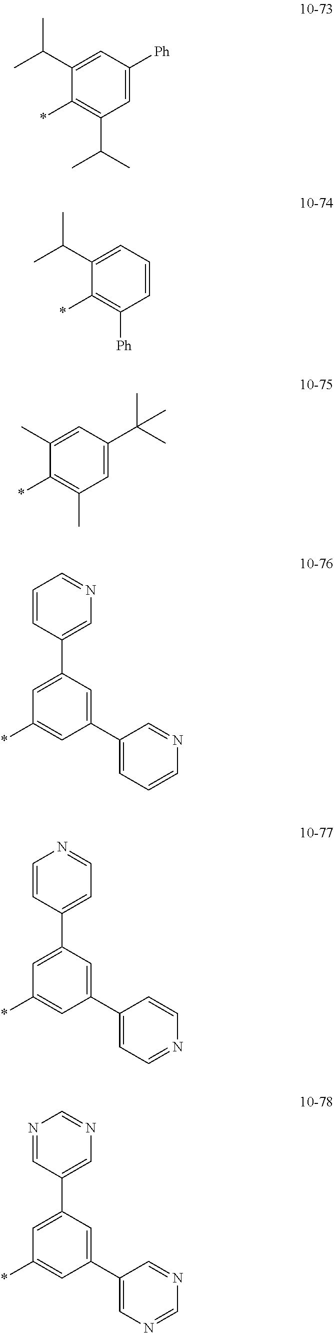

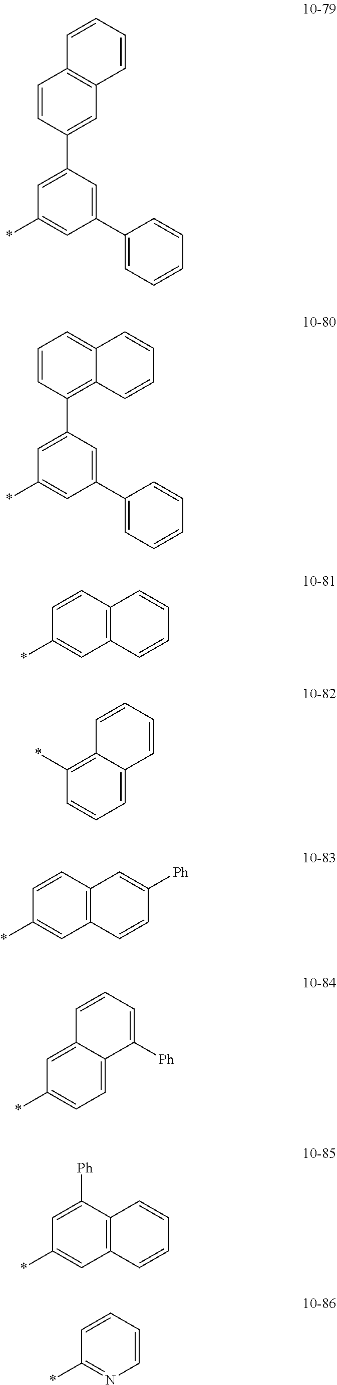

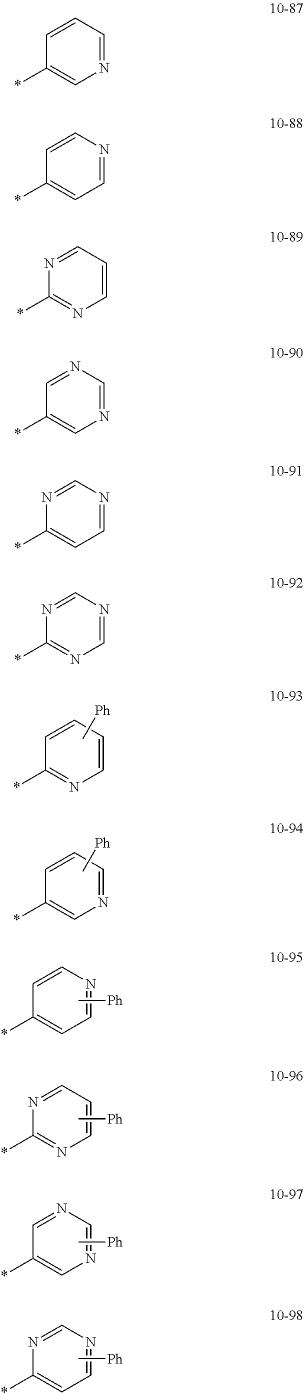

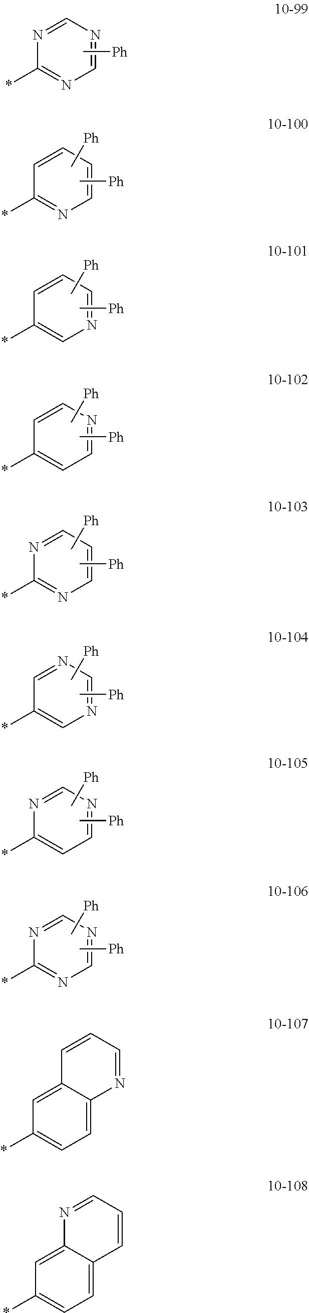

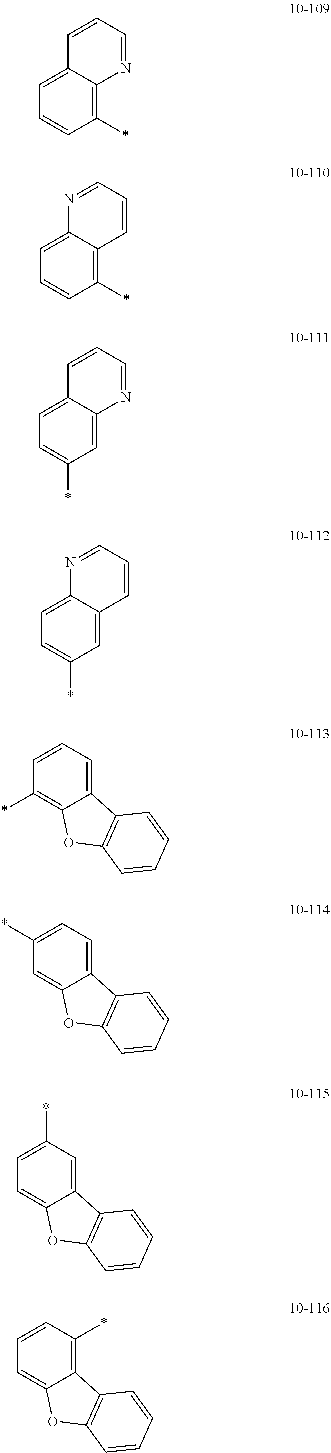

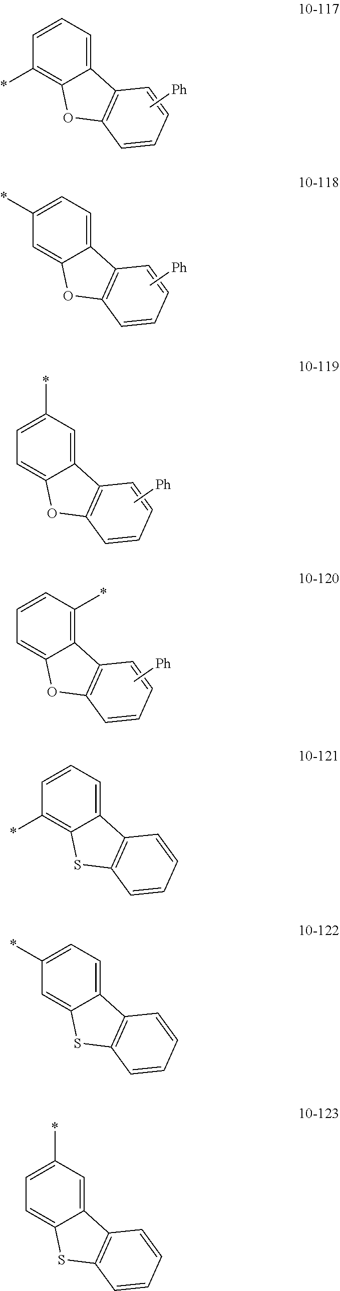

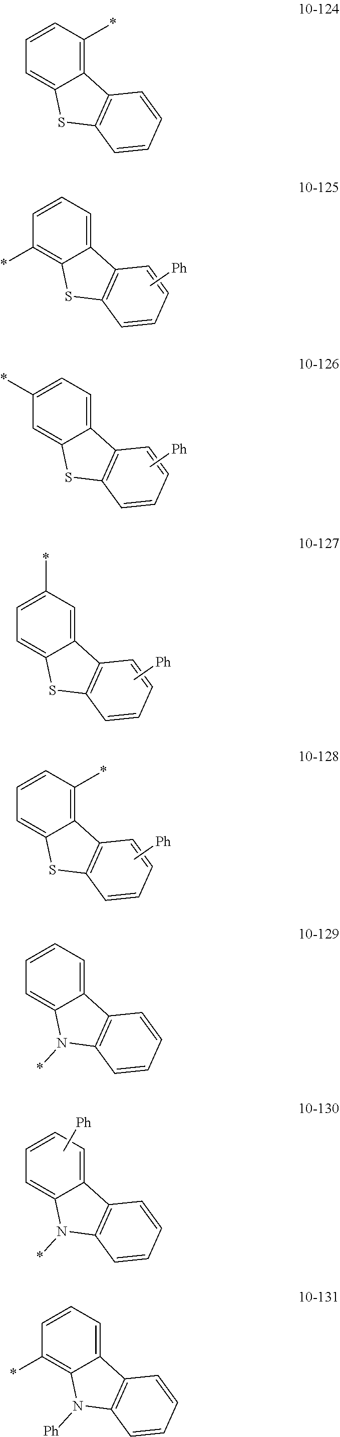

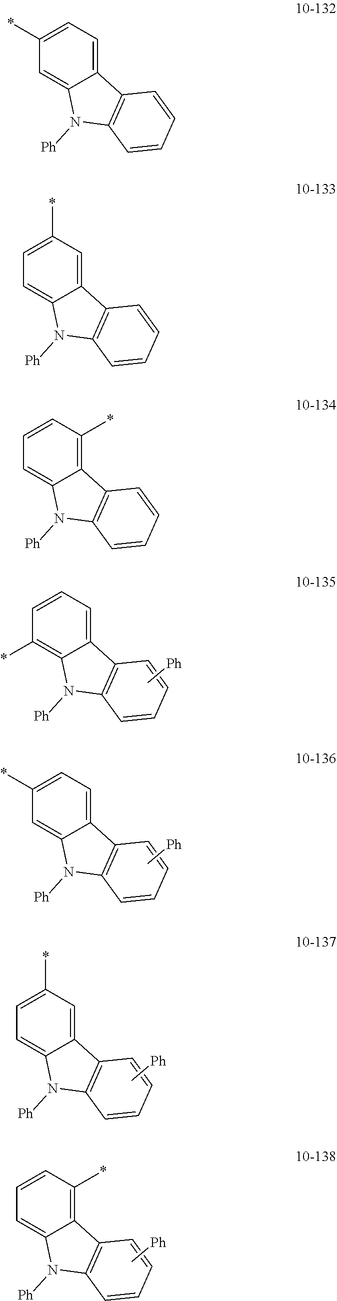

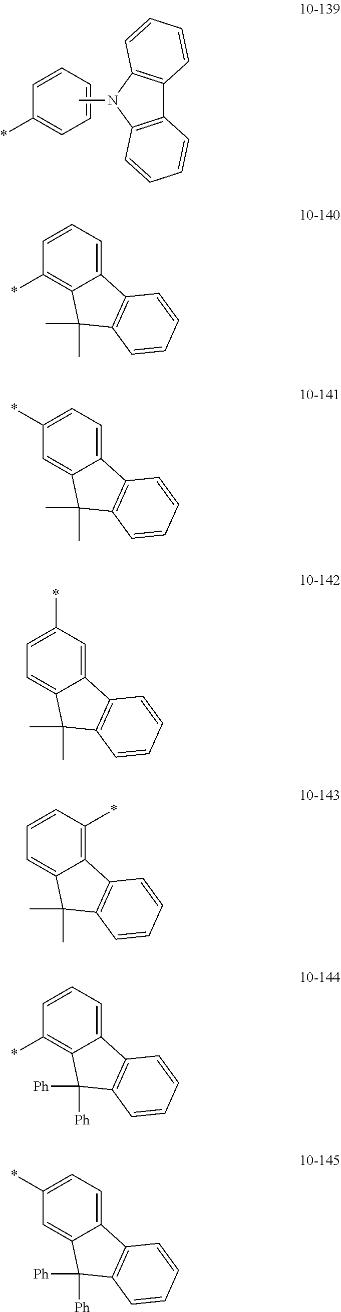

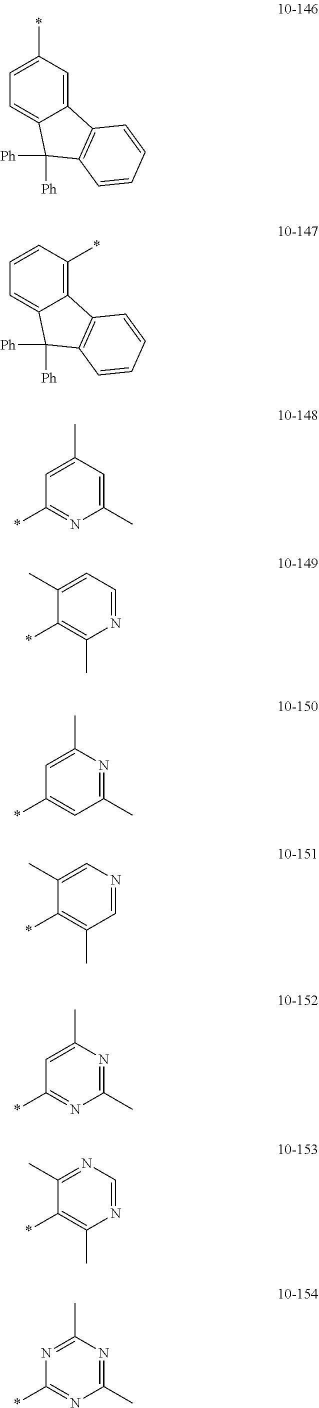

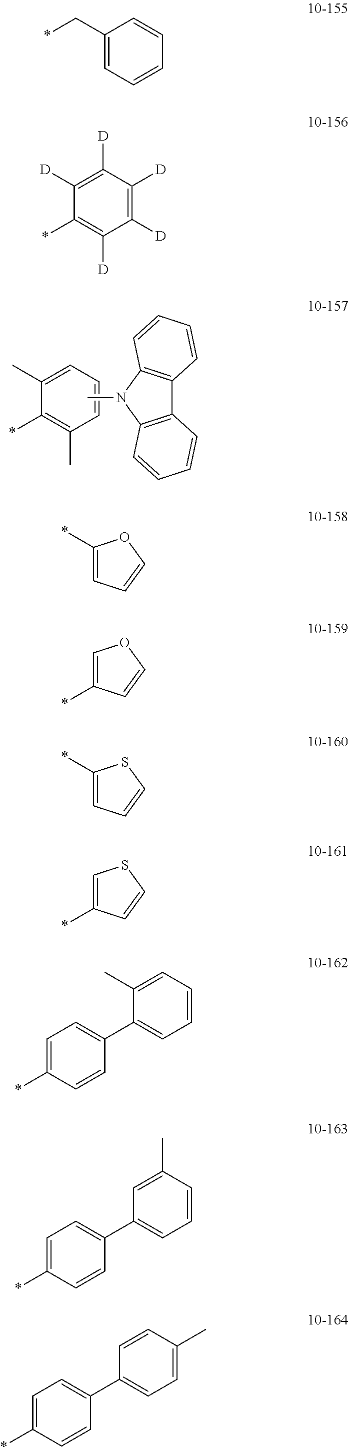

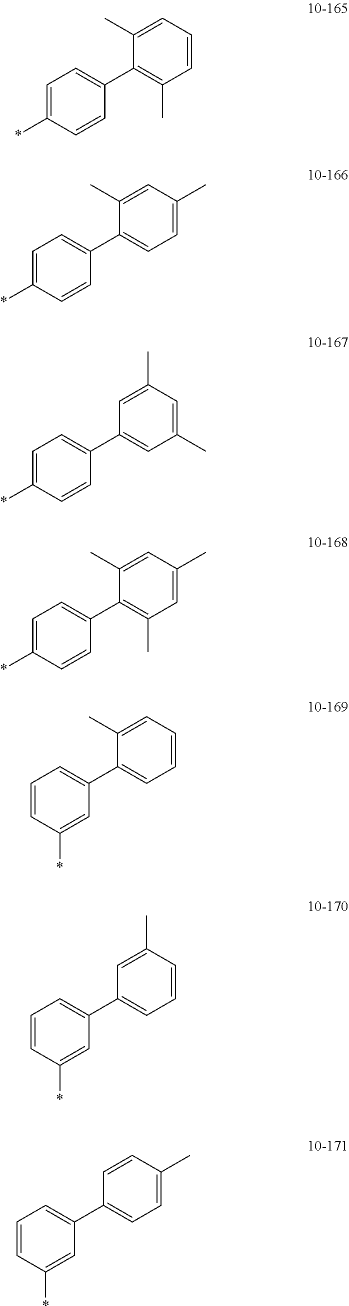

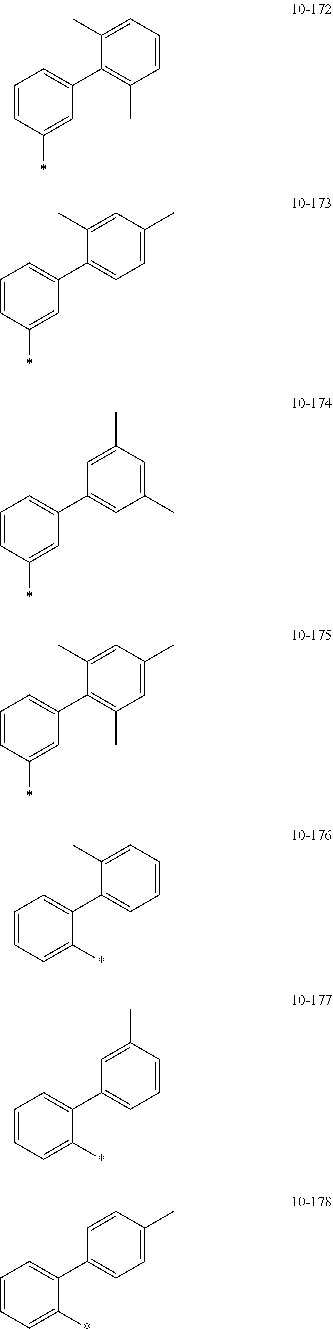

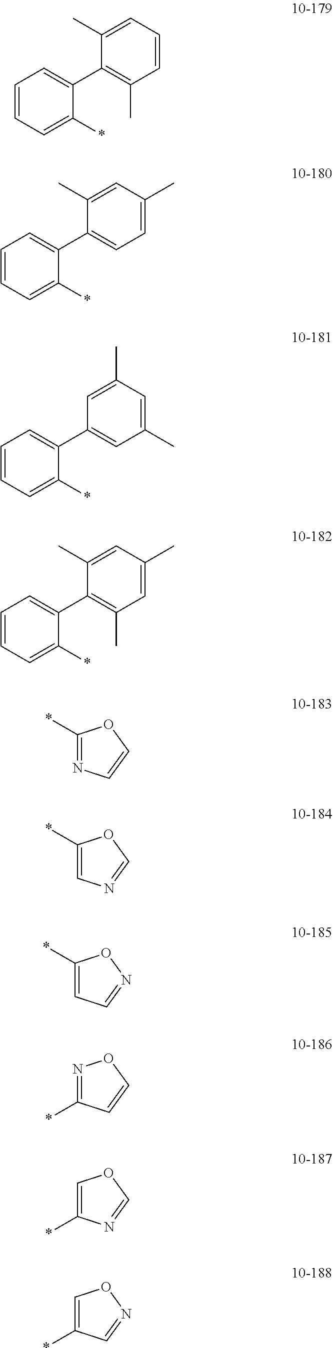

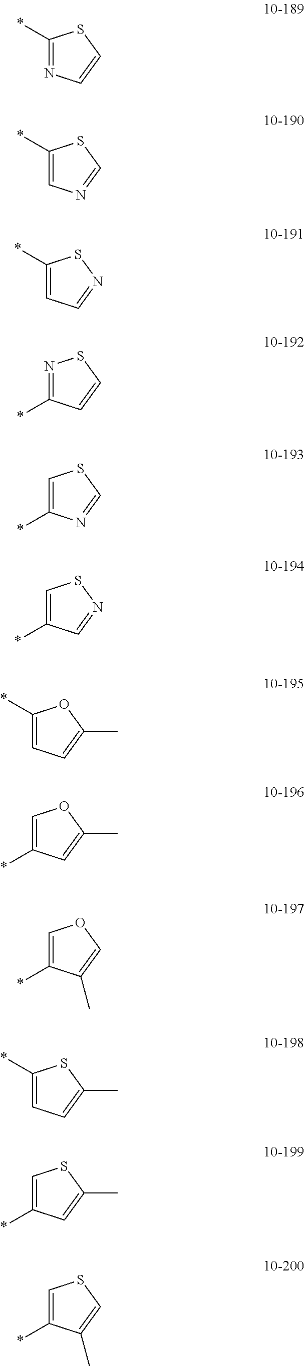

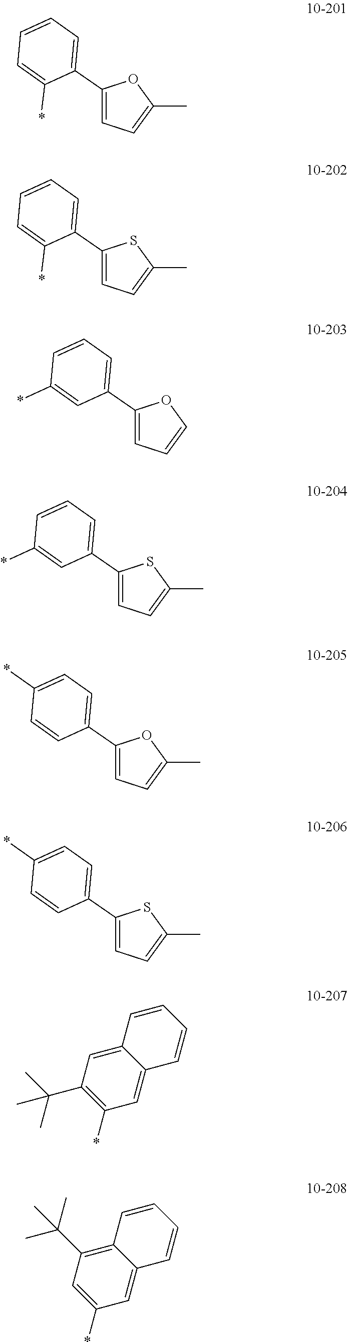

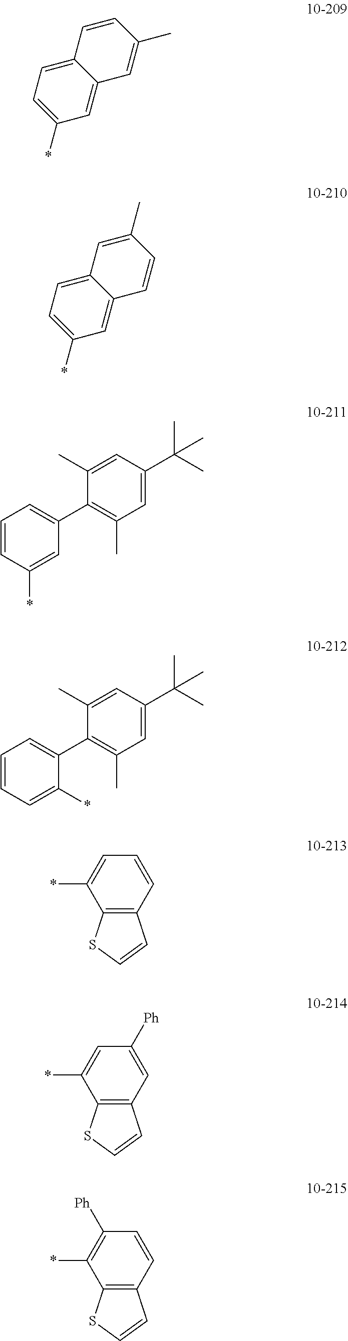

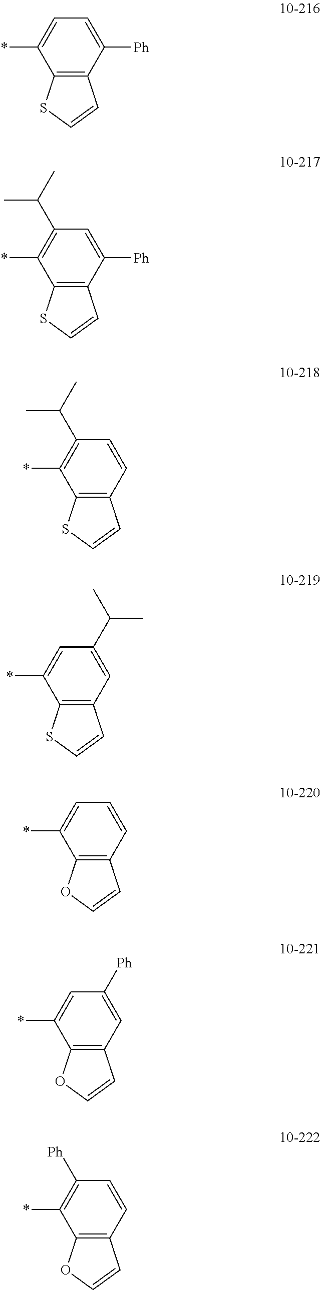

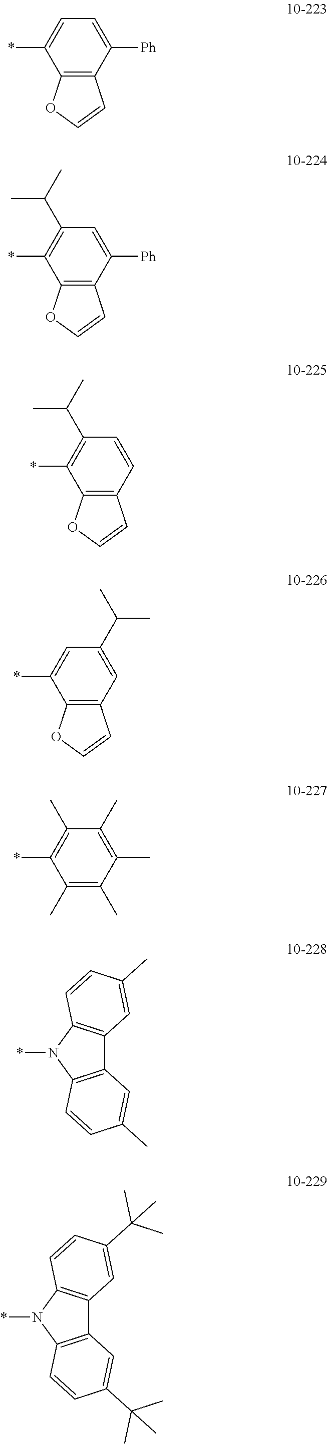

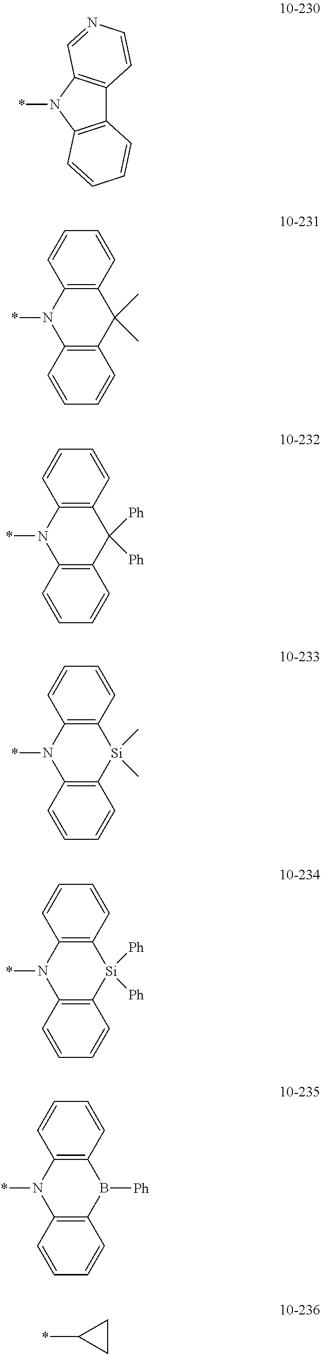

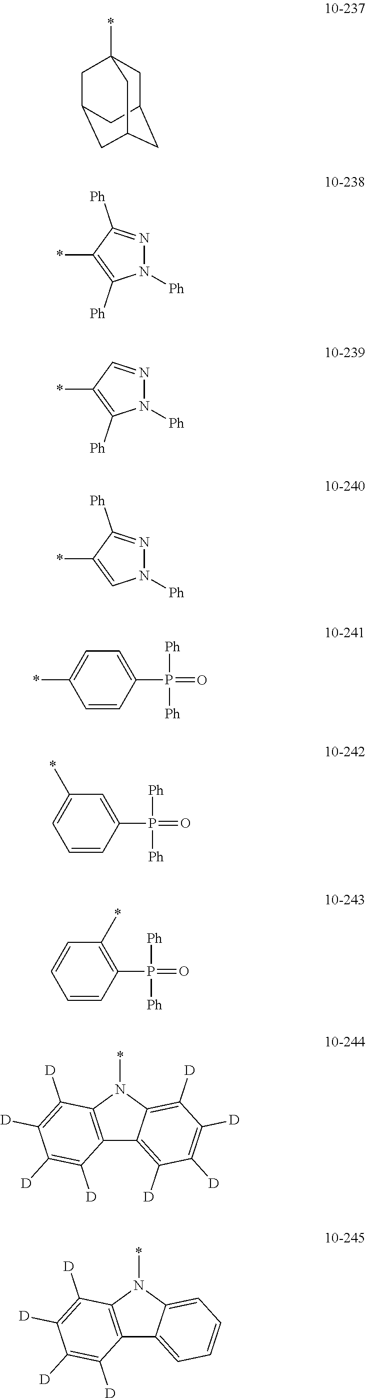

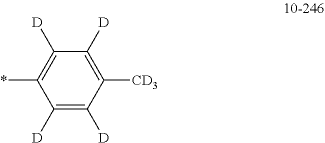 [SMILES: *c1c([2H])c([2H])c(C([2H])([2H])[2H])c([2H])c1[2H]]

wherein in Formulae 9-1 to 9-19 and 10-1 to 10-246, * indicates a binding site to an adjacent atom, “Ph” represents a phenyl group, “D” represents a deuterium atom, and “TMS” represents a trimethylsilyl group.

### Examples of Compounds

In one or more embodiments, the p-dopant may be one (e.g., any one) selected from among Compounds C56, C68, C70, S1, and S44:

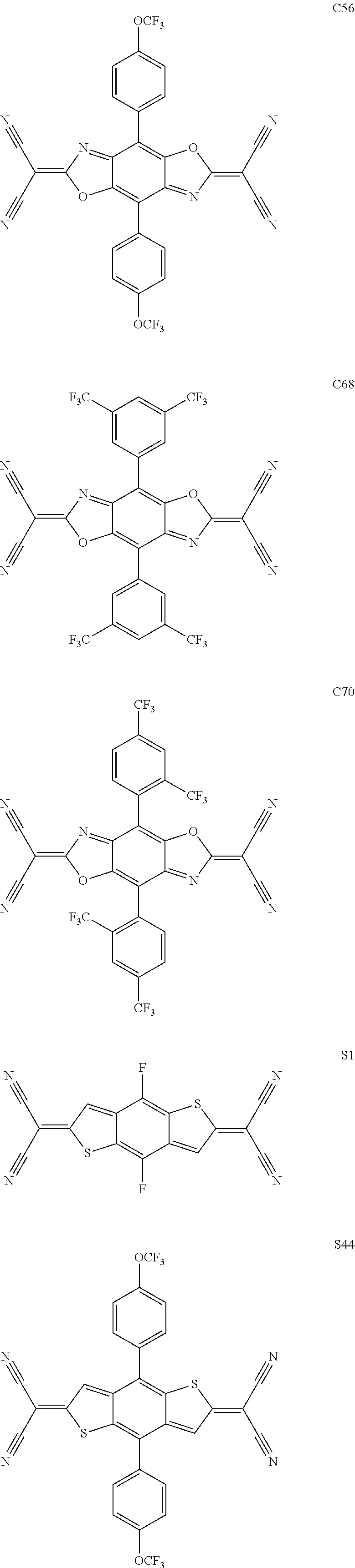 [SMILES: N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3cc(C(F)(F)F)cc(C(F)(F)F)c3)c3oc(=C(C#N)C#N)nc3c(-c3cc(C(F)(F)F)cc(C(F)(F)F)c3)c2o1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1cc2c(F)c3sc(=C(C#N)C#N)cc3c(F)c2s1 ; N#CC(C#N)=c1cc2c(-c3ccc(OC(F)(F)F)cc3)c3sc(=C(C#N)C#N)cc3c(-c3ccc(OC(F)(F)F)cc3)c2s1]

In one or more embodiments, the second hole transport material may be one (e.g., any one) selected from among Compounds HT(2)1 to HT(2)9:

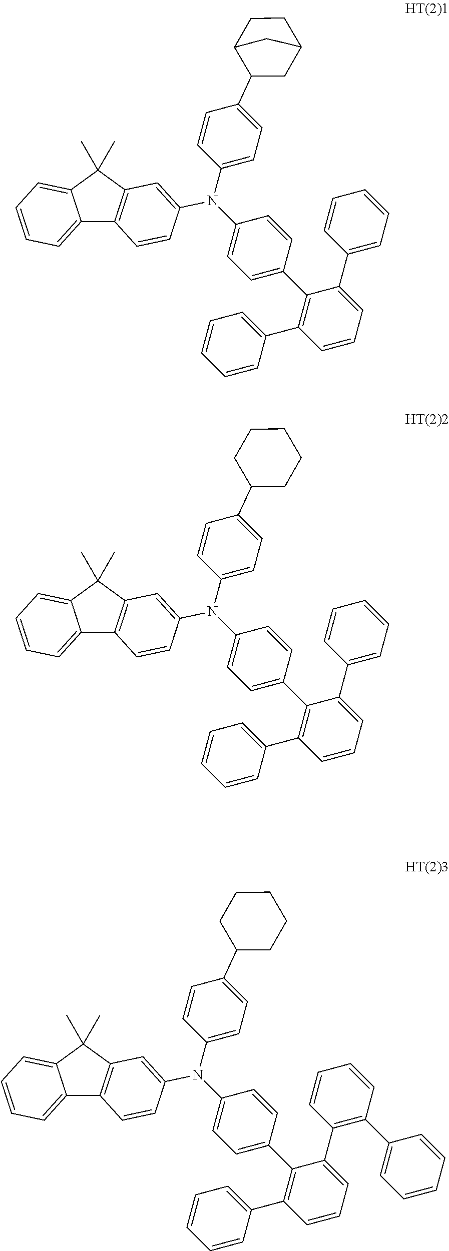 [SMILES: CC1(C)c2ccccc2-c2ccc(N(c3ccc(-c4c(-c5ccccc5)cccc4-c4ccccc4)cc3)c3ccc(C4CC5CCC4C5)cc3)cc21 ; CC1(C)c2ccccc2-c2ccc(N(c3ccc(-c4c(-c5ccccc5)cccc4-c4ccccc4)cc3)c3ccc(C4CCCCC4)cc3)cc21 ; CC1(C)c2ccccc2-c2ccc(N(c3ccc(-c4c(-c5ccccc5)cccc4-c4ccccc4-c4ccccc4)cc3)c3ccc(C4CCCCC4)cc3)cc21]

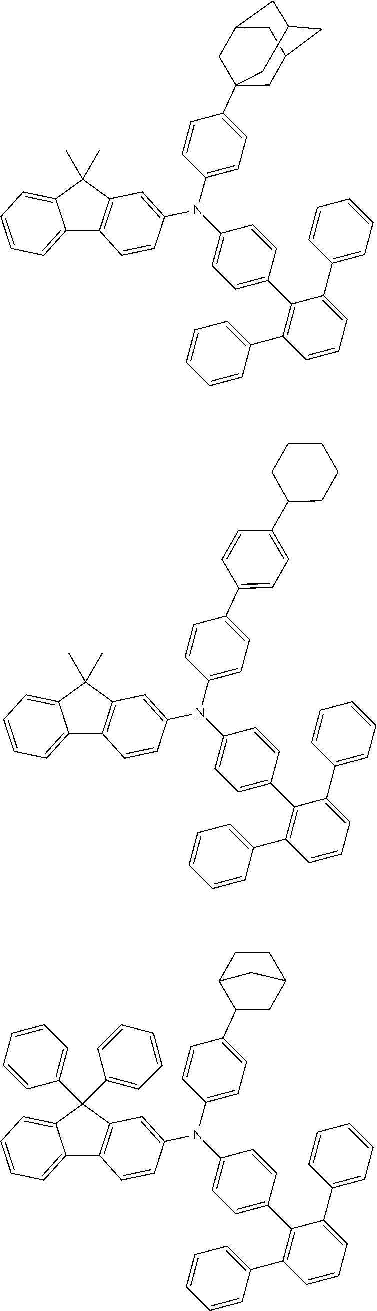 [SMILES: CC1(C)c2ccccc2-c2ccc(N(c3ccc(-c4c(-c5ccccc5)cccc4-c4ccccc4)cc3)c3ccc(C45CC6CC(CC(C6)C4)C5)cc3)cc21 ; CC1(C)c2ccccc2-c2ccc(N(c3ccc(-c4ccc(C5CCCCC5)cc4)cc3)c3ccc(-c4c(-c5ccccc5)cccc4-c4ccccc4)cc3)cc21 ; c1ccc(-c2cccc(-c3ccccc3)c2-c2ccc(N(c3ccc(C4CC5CCC4C5)cc3)c3ccc4c(c3)C(c3ccccc3)(c3ccccc3)c3ccccc3-4)cc2)cc1]

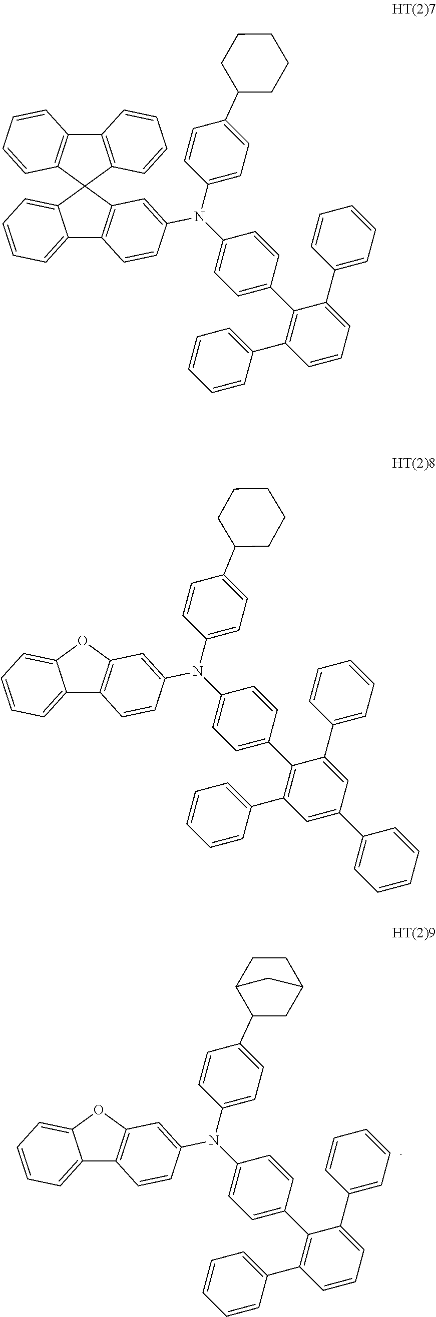 [SMILES: c1ccc(-c2cccc(-c3ccccc3)c2-c2ccc(N(c3ccc(C4CCCCC4)cc3)c3ccc4c(c3)C3(c5ccccc5-c5ccccc53)c3ccccc3-4)cc2)cc1 ; c1ccc(-c2cc(-c3ccccc3)c(-c3ccc(N(c4ccc(C5CCCCC5)cc4)c4ccc5c(c4)oc4ccccc45)cc3)c(-c3ccccc3)c2)cc1 ; c1ccc(-c2cccc(-c3ccccc3)c2-c2ccc(N(c3ccc(C4CC5CCC4C5)cc3)c3ccc4c(c3)oc3ccccc34)cc2)cc1]

In one or more embodiments, the first capping material may be one (e.g., any one) selected from among Compounds CPL1 to CPL4:

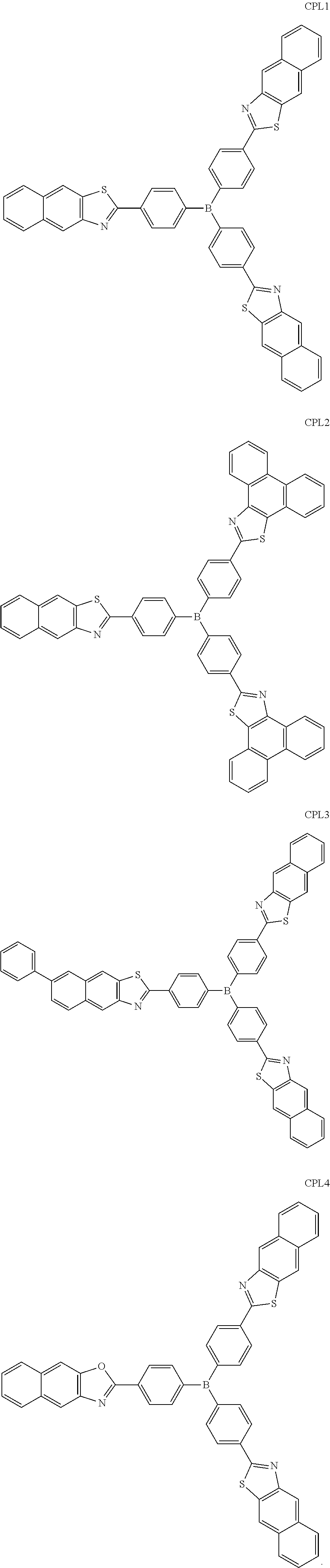 [SMILES: c1ccc2cc3sc(-c4ccc(B(c5ccc(-c6nc7cc8ccccc8cc7s6)cc5)c5ccc(-c6nc7cc8ccccc8cc7s6)cc5)cc4)nc3cc2c1 ; c1ccc2cc3sc(-c4ccc(B(c5ccc(-c6nc7c8ccccc8c8ccccc8c7s6)cc5)c5ccc(-c6nc7c8ccccc8c8ccccc8c7s6)cc5)cc4)nc3cc2c1 ; c1ccc(-c2ccc3cc4nc(-c5ccc(B(c6ccc(-c7nc8cc9ccccc9cc8s7)cc6)c6ccc(-c7nc8cc9ccccc9cc8s7)cc6)cc5)sc4cc3c2)cc1 ; c1ccc2cc3oc(-c4ccc(B(c5ccc(-c6nc7cc8ccccc8cc7s6)cc5)c5ccc(-c6nc7cc8ccccc8cc7s6)cc5)cc4)nc3cc2c1]

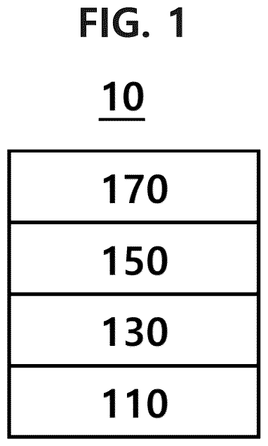

### Description of FIG. 1

FIG. 1 is a schematic cross-sectional view of a light-emitting device 10 according to one or more embodiments. The light-emitting device 10 includes a first electrode 110, an interlayer 130, a second electrode 150, and a second capping layer 170.

Hereinafter, the structure of the light-emitting device 10 according to one or more embodiments and a method of manufacturing the light-emitting device 10 will be described in more detail with reference to FIG. 1.

### First Electrode 110

Referring to FIG. 1, a substrate may be additionally located under the first electrode 110 or above the second capping layer 170. As the substrate, a glass substrate or a plastic substrate may be utilized. In one or more embodiments, the substrate may be a flexible substrate, and may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, if (e.g., when) the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layered structure including a single layer or a multi-layered structure including a plurality of layers. For example, the first electrode 110 may have a three-layered structure of ITO/Ag/ITO.

### Interlayer 130

The interlayer 130 may be located on the first electrode 110. The interlayer 130 may include an emission layer.

The interlayer 130 may further include a hole transport region located between the first electrode 110 and the emission layer, and an electron transport region located between the emission layer and the second electrode 150.

The interlayer 130 may further include, in addition to one or more suitable organic materials, a metal-containing compound such as an organometallic compound, an inorganic material such as quantum dots, and/or the like.

In one or more embodiments, the interlayer 130 may include i) two or more emitting units sequentially stacked between the first electrode 110 and the second electrode 150, and ii) a charge generation layer located between two neighboring emitting units. When the interlayer 130 includes emitting units and a charge generation layer as described above, the light-emitting device 10 may be a tandem light-emitting device.

### Hole Transport Region in Interlayer 130

The hole transport region may have: i) a single-layered structure including a single layer including a single material, ii) a single-layered structure including a single layer including a plurality of different materials, or iii) a multi-layered structure including a plurality of layers including different materials.

The hole transport region may include a first layer and a second layer as described herein. Moreover, the hole transport region may further include, in addition to the first layer and the second layer, a hole injection layer, a hole transport layer, an emission auxiliary layer, an electron blocking layer, or any combination thereof, if (e.g., when) necessary.

For example, the hole transport region may have a multi-layered structure of first layer/second layer, first layer/second layer/emission auxiliary layer, or first layer/second layer/electron blocking layer, which are sequentially stacked in this stated order from the first electrode 110.

The hole transport region may include a compound represented by Formula 201, a compound represented by Formula 202, or any combination thereof:

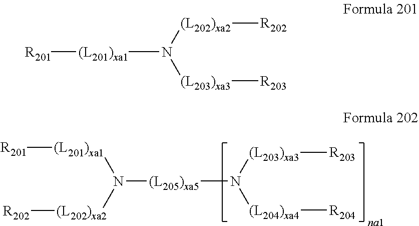

wherein in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be **′ *-*′ *N(Q₂₀₁)-*, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (for example, a carbazole group and/or the like) unsubstituted or substituted with at least one R₁₀ₐ (for example, see Compound HT16),
R₂₀₃ and R₂₀₄ may optionally be linked to each other, via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

For example, each of Formulae 201 and 202 may include at least one (or may be any one) selected from among groups represented by Formulae CY201 to CY217:

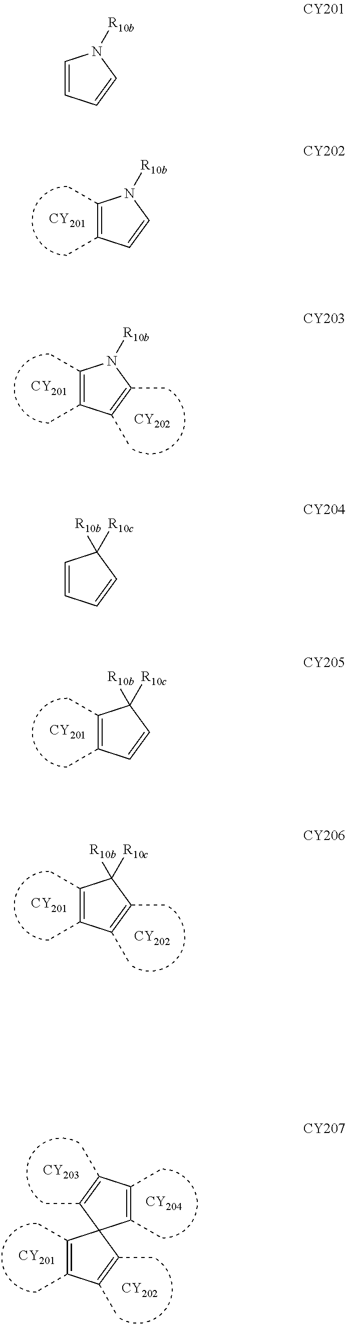

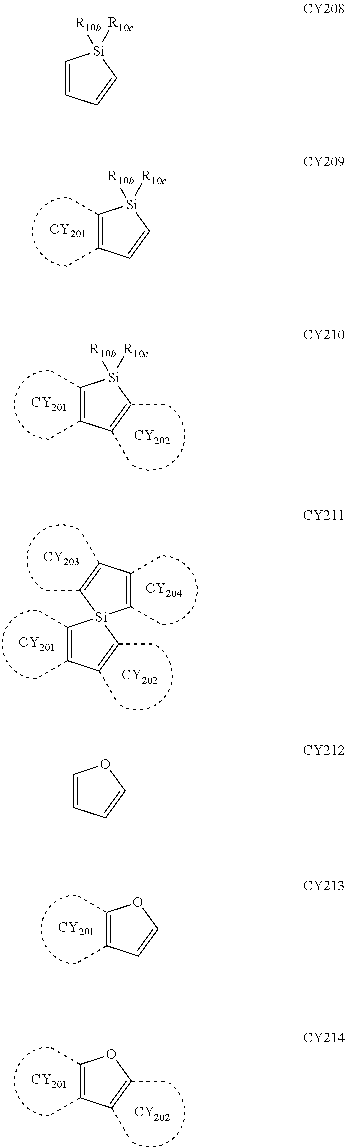

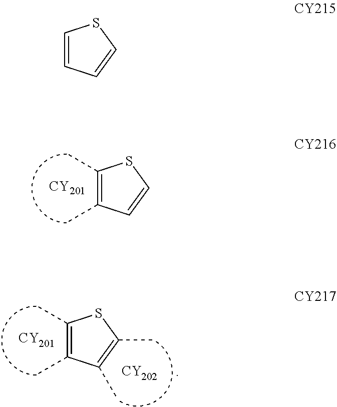

R_{10b} and R_{10c} in Formulae CY₂₀₁ to CY₂₁₇ may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one selected from among groups represented by Formulae CY201 to CY203.

In one or more embodiments, Formula 201 may include at least one selected from among the groups represented by Formulae CY201 to CY203 and at least one selected from among the groups represented by Formulae CY204 to CY217.

In one or more embodiments, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

In one or more embodiments, each of Formulae 201 and 202 may not include (e.g., may exclude) a group represented by one selected from among Formulae CY201 to CY203.

In one or more embodiments, each of Formulae 201 and 202 may not include (e.g., may exclude) a group represented by one selected from among Formulae CY201 to CY203, and may include at least one selected from among the groups represented by Formulae CY204 to CY217.

In one or more embodiments, each of Formulae 201 and 202 may not include (e.g., may exclude) a group represented by one selected from among Formulae CY201 to CY217.

For example, the hole transport region may include at least one selected from among Compounds HT1 to HT46 (Compound HT45 is the same as Compound 203 described herein), m-MTDATA (the same as Compound 202 descried herein), TDATA, 2-TNATA, NPB(NPD) (the same as Compound 201 described herein), p-NPB, TPD, Spiro-TPD, Spiro-NPB, methylated-NPB, TAPC, HMTPD, 4,4′, 4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

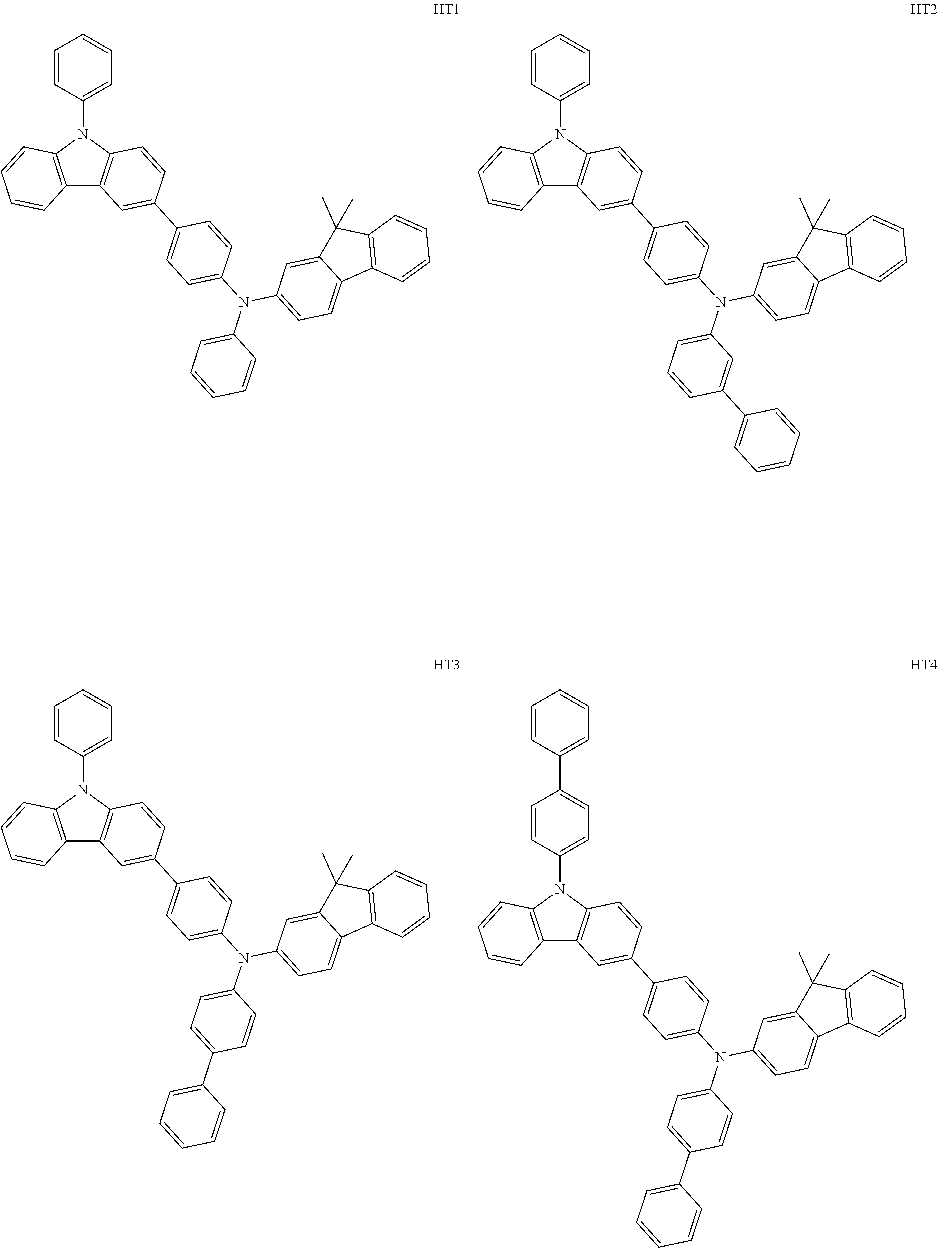 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc(-c4ccc5c(c4)c4ccccc4n5-c4ccc(-c5ccccc5)cc4)cc3)cc21]

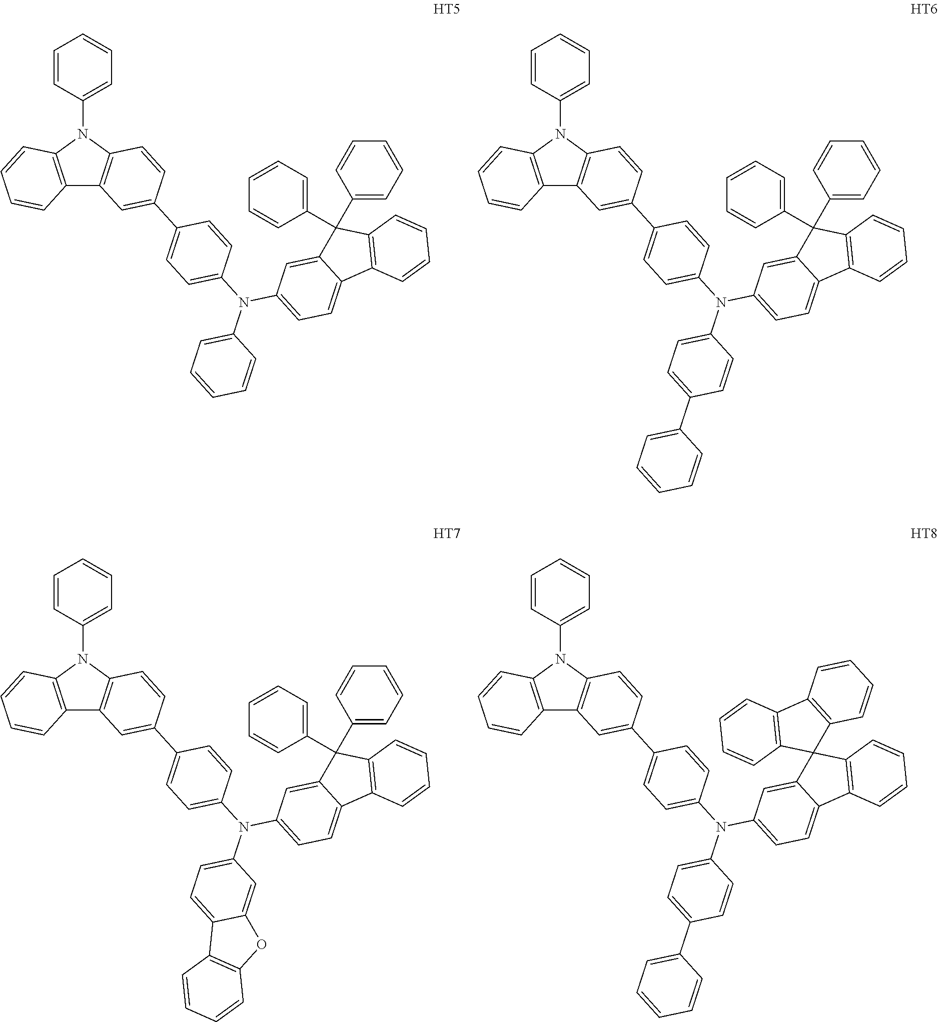 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

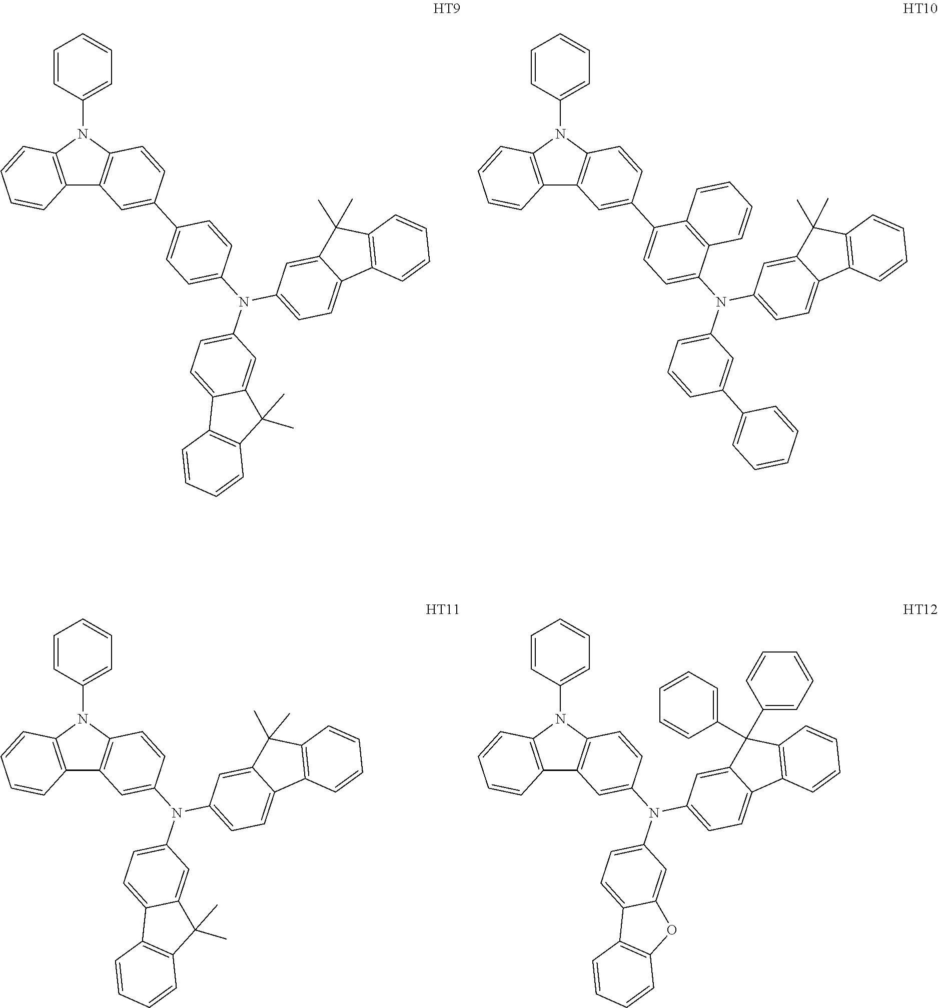 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

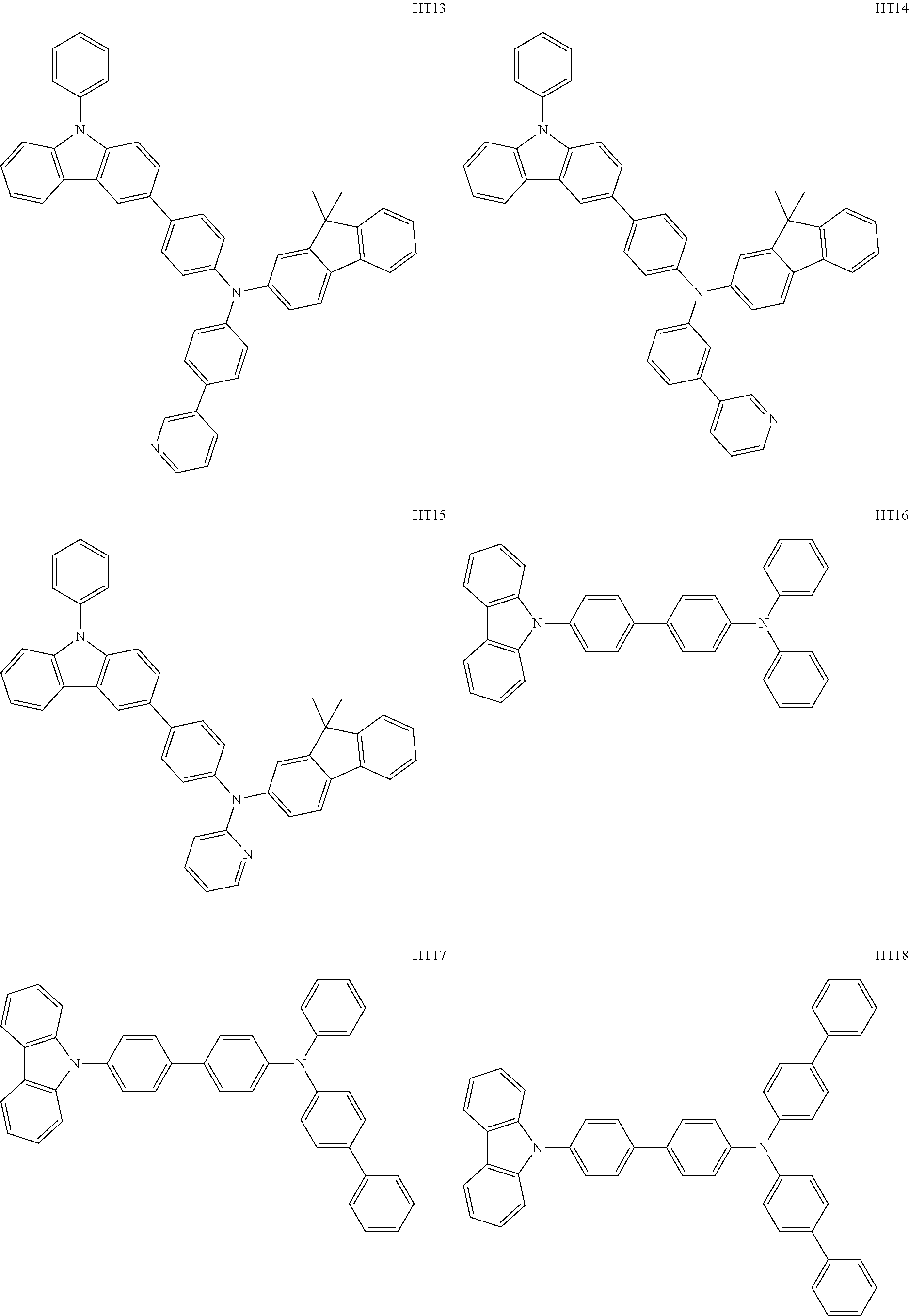 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

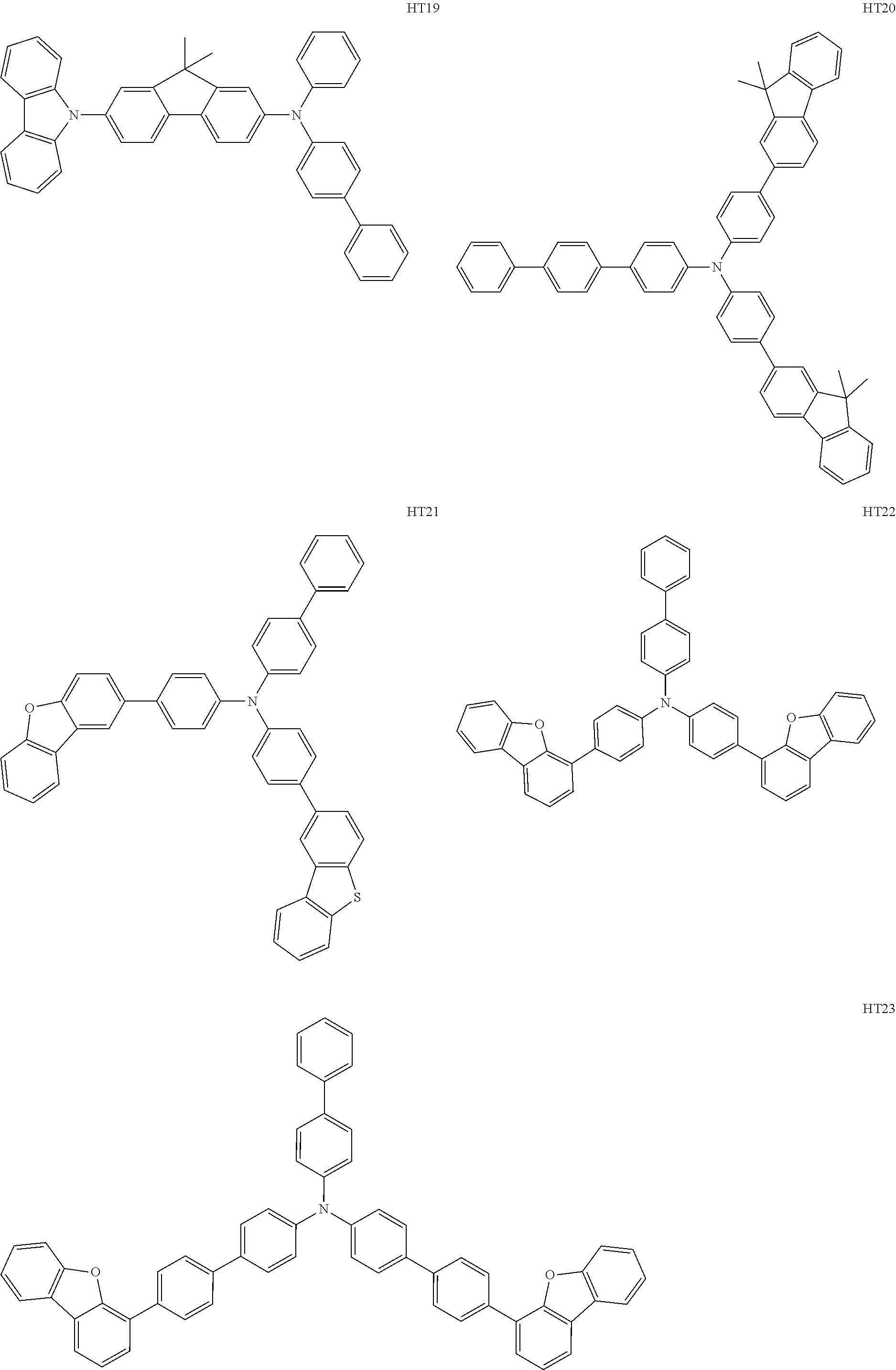 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

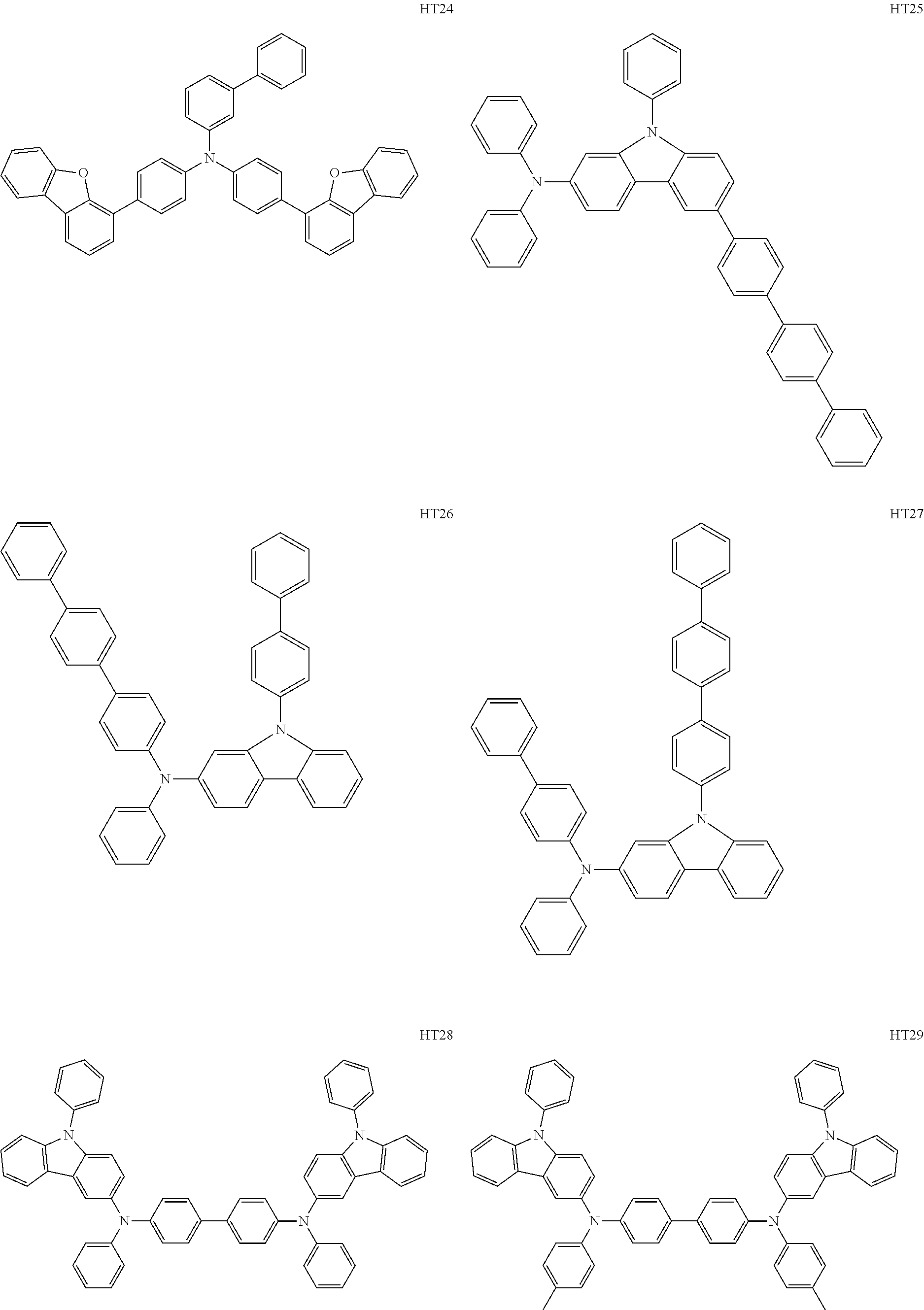

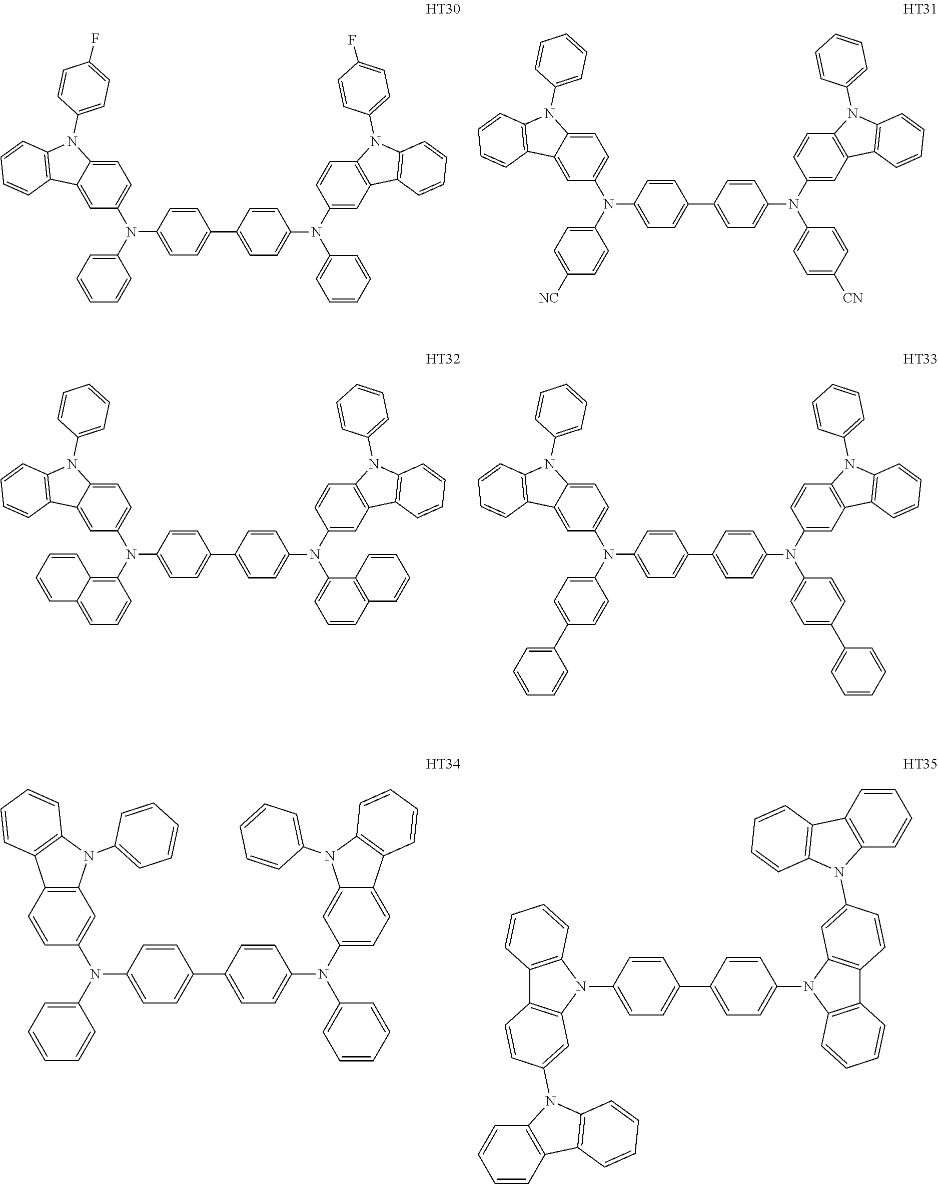

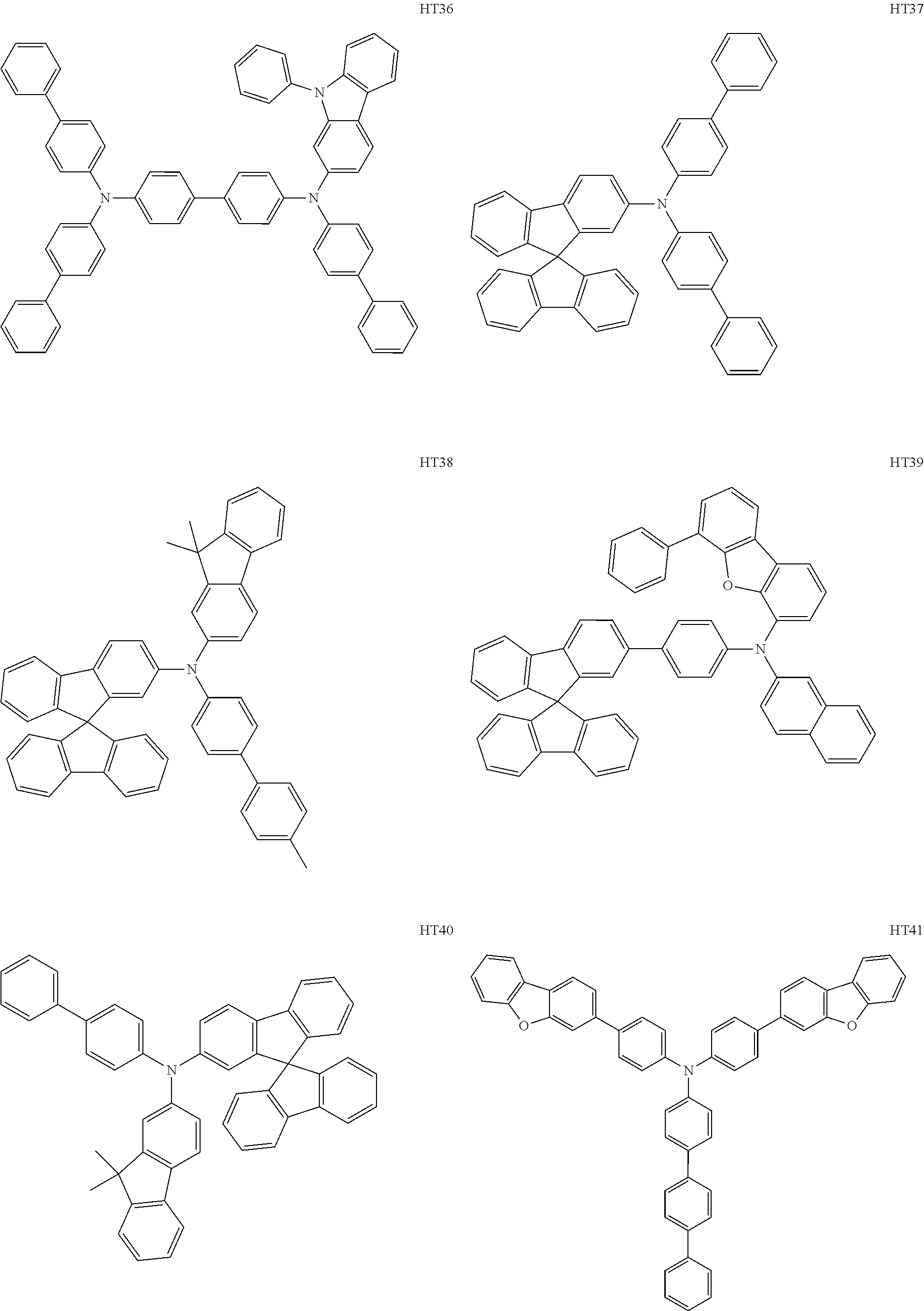

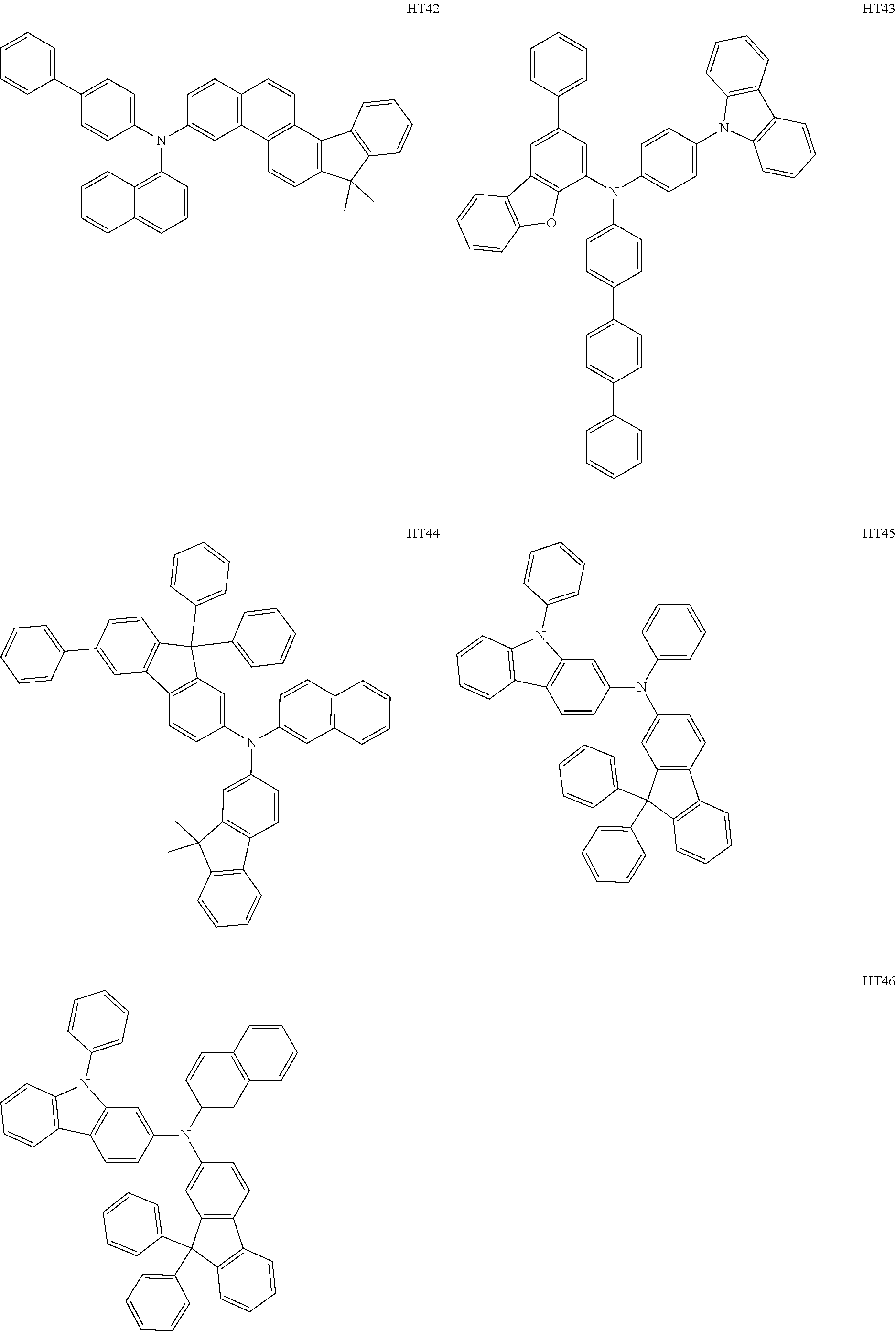 [SMILES: CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1]

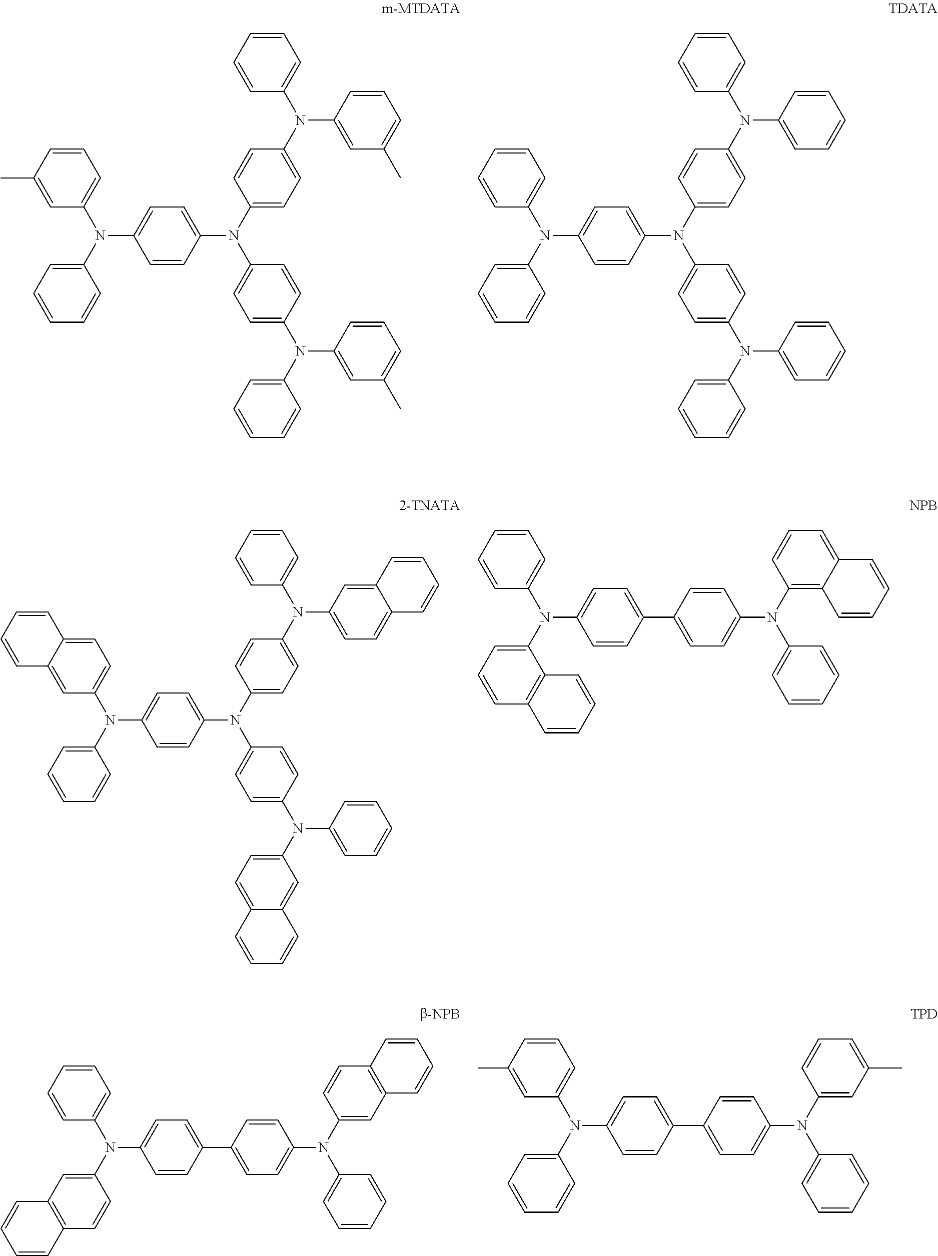

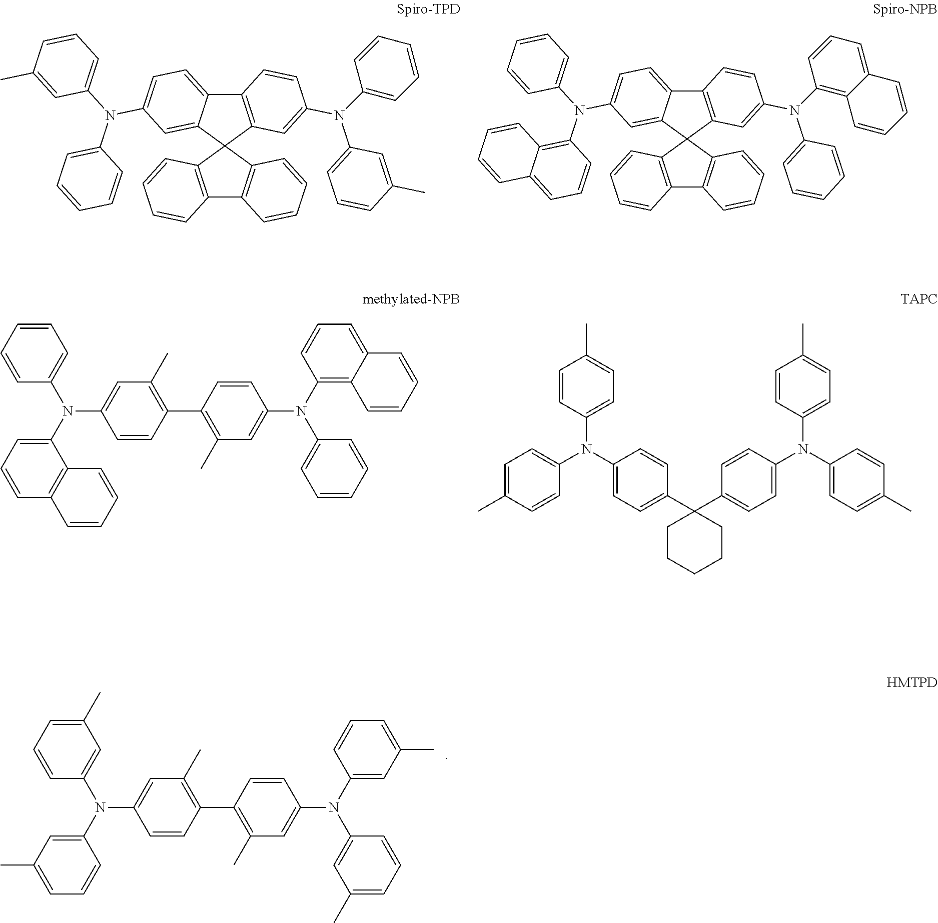

A thickness of the hole transport region may be in a range of about 50 Å to about 10,000 Å, for example, about 100 Å to about 4,000 Å. When the hole transport region includes a first layer, a second layer, a hole injection layer, a hole transport layer, or any combination thereof, a thickness of each of the first layer and the hole injection layer may be in a range of about 50 Å to about 9,000 Å, for example, about 100 Å to about 1,000 Å, and a thickness of each of the second layer and the hole transport layer may be in a range of about 50 Å to about 2,000 Å, for example, about 100 Å to about 1,500 Å. When the thicknesses of the hole transport region, the first layer, the second layer, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by an emission layer, and the electron-blocking layer may block or reduce the leakage of electrons from an emission layer to a hole transport region. Materials that may be included in the hole transport region may be included in the emission auxiliary layer and the electron-blocking layer.

p-Dopant

The hole transport region may include the first layer, and the first layer may include the p-dopant as described herein. The p-dopant may generate charges to improve conductivity.

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers of a red emission layer, a green emission layer, and a blue emission layer, in which the two or more layers contact each other or are separated from each other to emit white light. In one or more embodiments, the emission layer may include two or more materials of a red light-emitting material, a green light-emitting material, and a blue light-emitting material, in which the two or more materials are mixed with each other in a single layer to emit white light.

In one or more embodiments, the emission layer may include a host and a dopant (or emitter). In one or more embodiments, the emission layer may further include an auxiliary dopant that promotes energy transfer to a dopant (or emitter), in addition to the host and the dopant (or emitter). When the emission layer includes the dopant (or emitter) and the auxiliary dopant, the dopant (or emitter) and the auxiliary dopant are different from each other.

When the emission layer includes the host and the dopant, an amount of the dopant (weight) may be about 0.01 to about 15 parts by weight based on 100 parts by weight of the host.

A thickness of the emission layer may be in a range of about 100 Å to about 1,000 Å, for example, about 200 Å to about 600 Å. When the thickness of the emission layer is within these ranges, excellent or suitable light-emission characteristics may be obtained without a substantial increase in driving voltage.

### Host

In one or more embodiments, the host may include a compound represented by Formula 301:

[Ar₃₀₁]_{xb11}-[(L₃₀₁)_{xb1}- R₃₀₁]_{xb21} Formula 301
wherein in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to 0303 are each the same as described herein with respect to Q₁.

For example, if (e.g., when) xb11 in Formula 301 is 2 or more, two or more of Ar₃₀₁ may be linked to each other via a single bond.

In one or more embodiments, the host may include a compound represented by Formula 301-1, a compound represented by Formula 301-2, or any combination thereof:

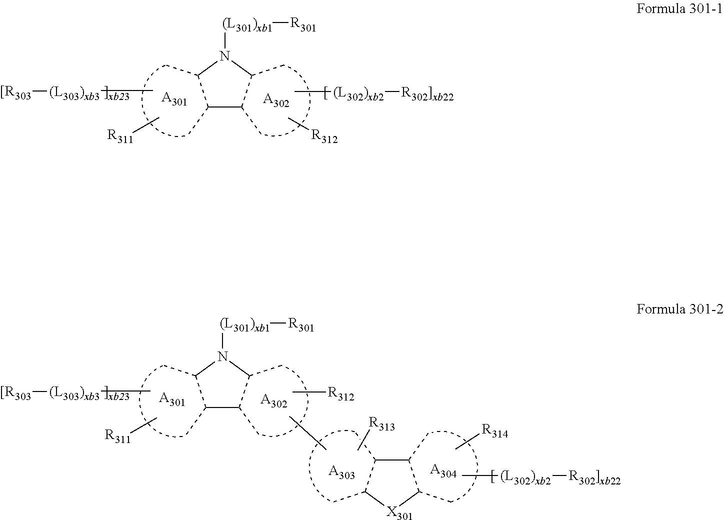

wherein in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described herein with respect to with L₃₀₁,
xb2 to xb4 may each independently be the same as described herein with respect to xb1, and
R₃₀₂ to R₃₀₅ and R₃₁₁ to R₃₁₄ may each be the same as described herein with respect to R₃₀₁.

In one or more embodiments, the host may include an alkaline earth metal complex, a post-transition metal complex, or any combination thereof. For example, the host may include a Be complex (for example, Compound H55), an Mg complex, a Zn complex, or any combination thereof.

In one or more embodiments, the host may include one (e.g., any one) selected from among Compounds H1 to H130, 9,10-di(2-naphthyl)anthracene (ADN), 2-methyl-9,10-bis(naphthalen-2-yl)anthracene (MADN), 9,10-di(2-naphthyl)-2-t-butyl-anthracene (TBADN), 4,4′-bis(N-carbazolyl)-1,1′-biphenyl (CBP), 1,3-di(carbazol-9-yl)benzene (mCP), 1,3,5-tri(carbazol-9-yl)benzene (TCP), or any combination thereof:

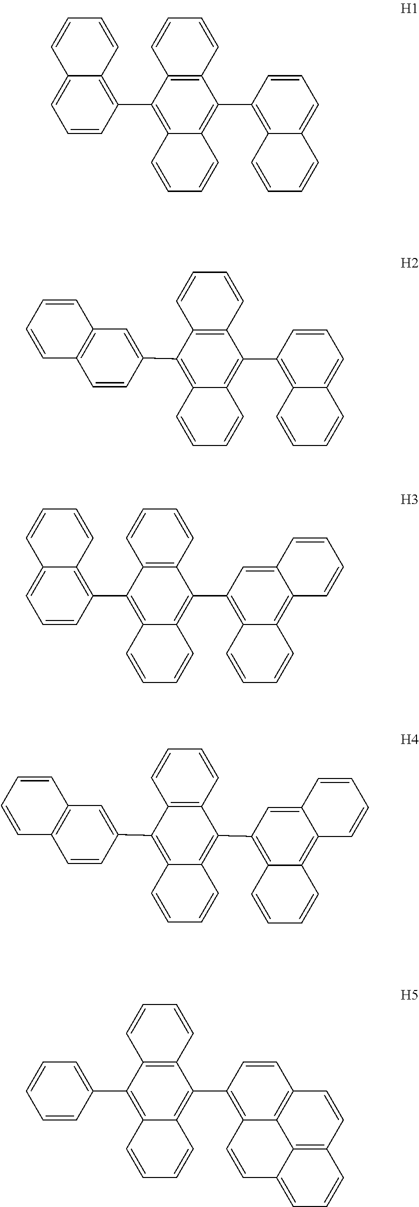

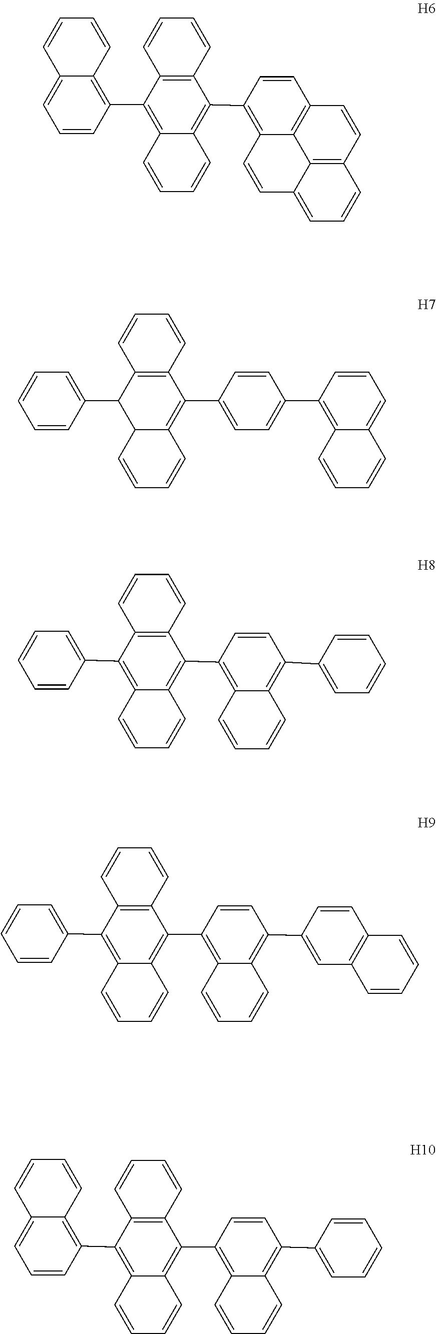

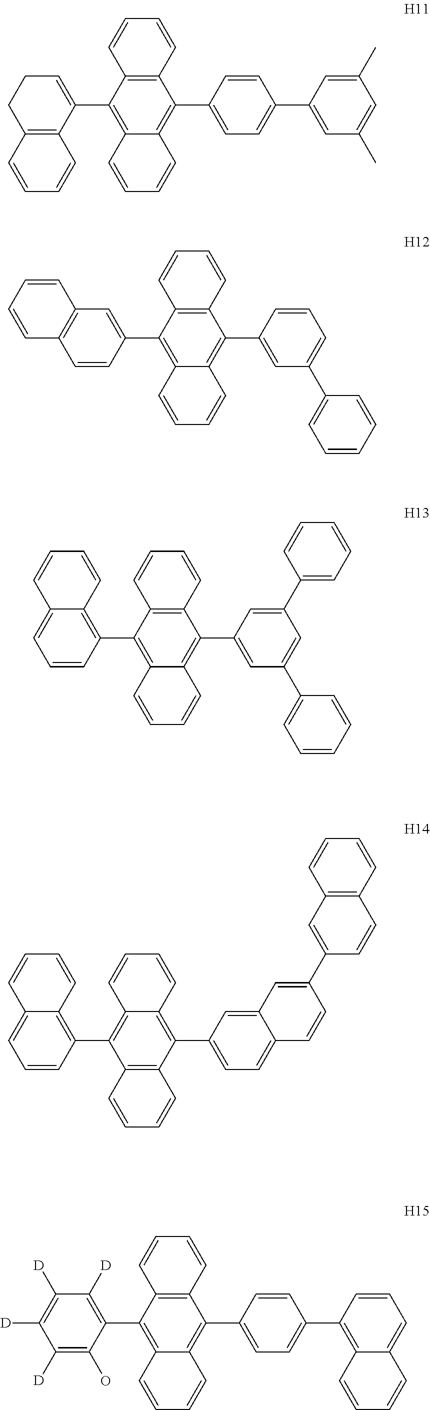

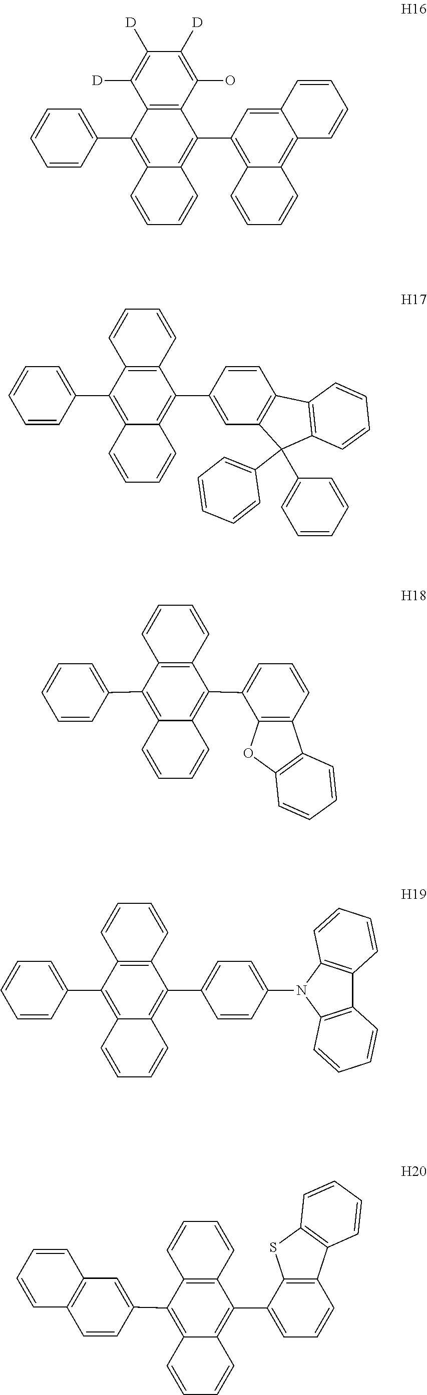

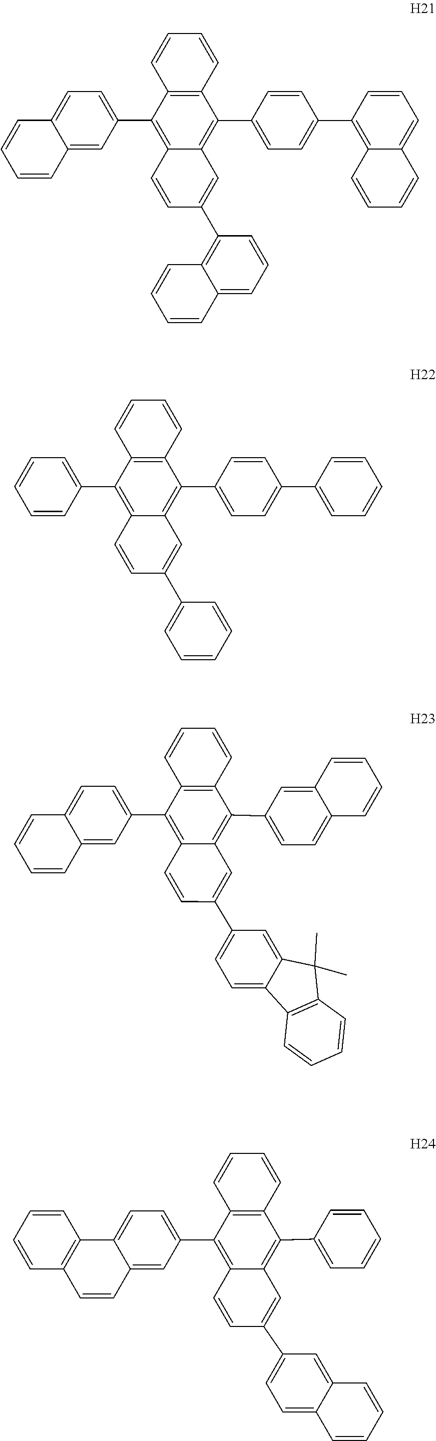

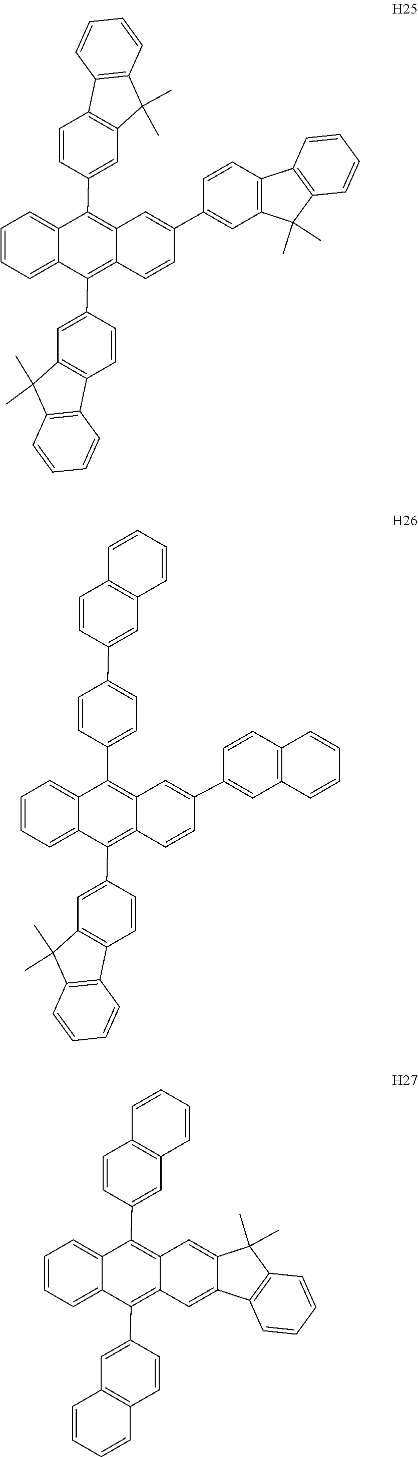

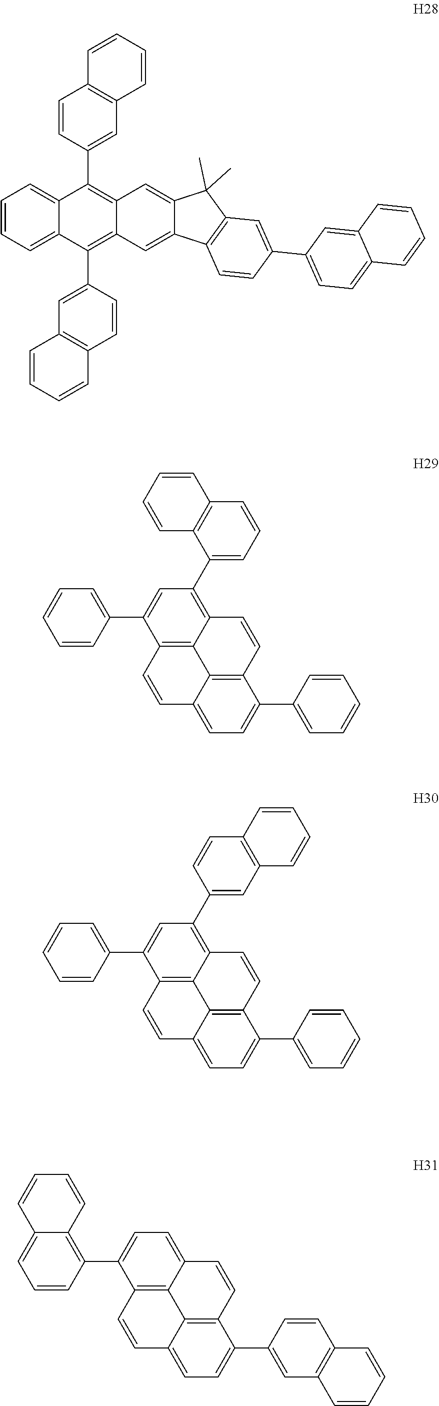

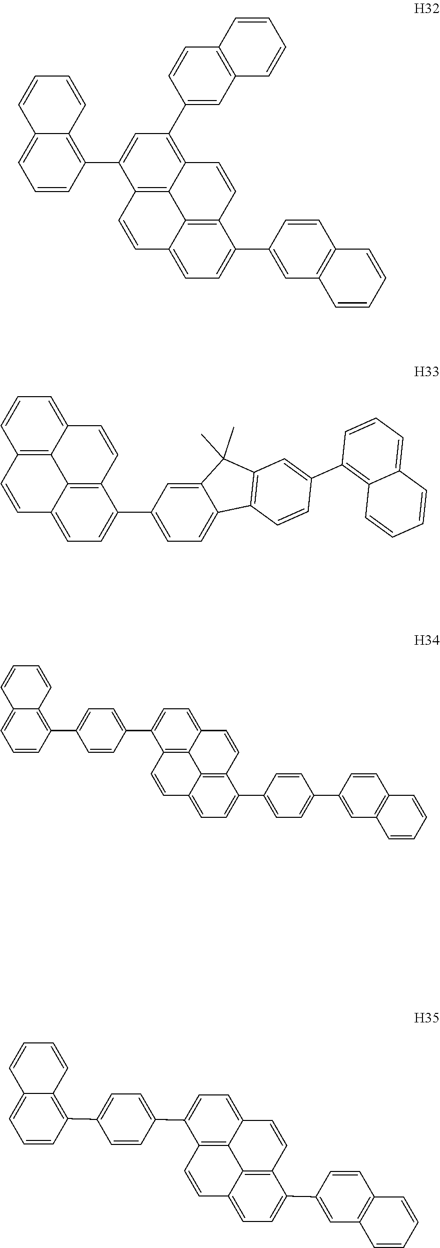

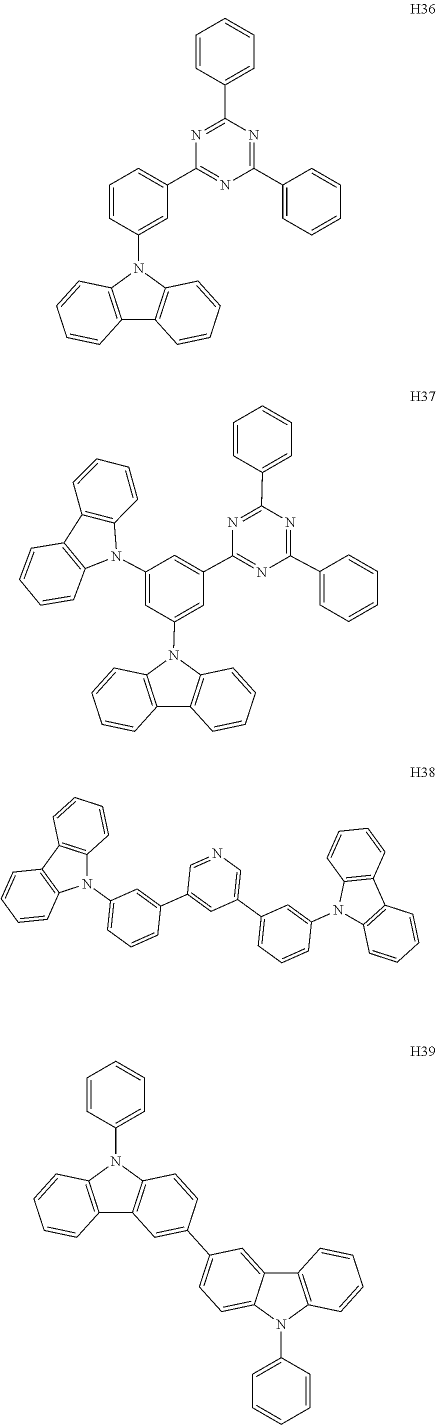 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

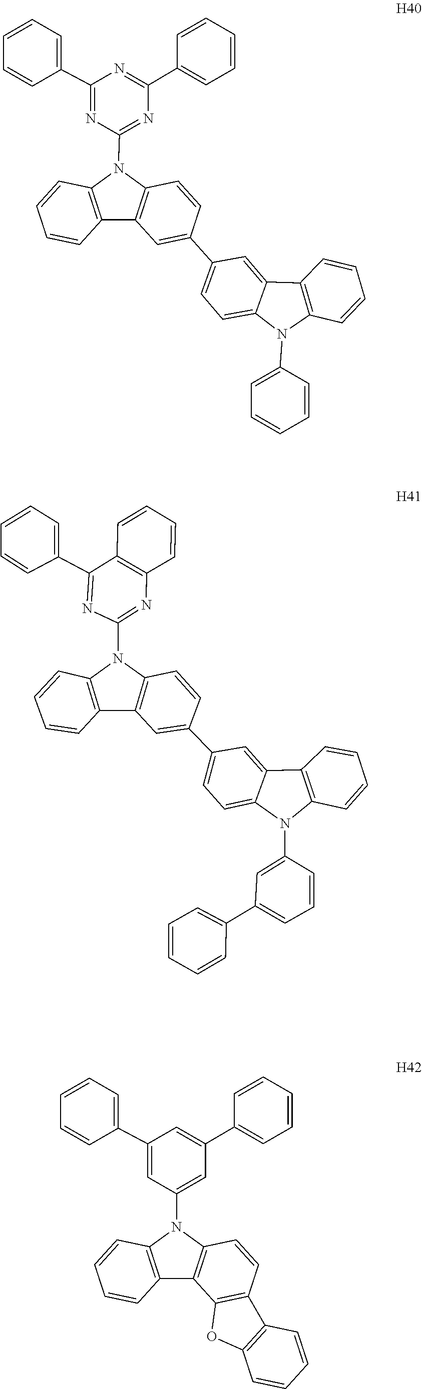 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

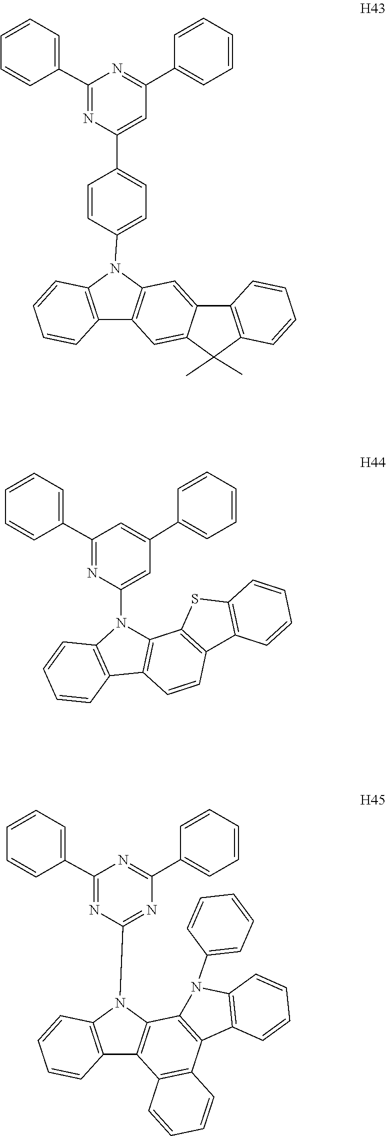 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1]

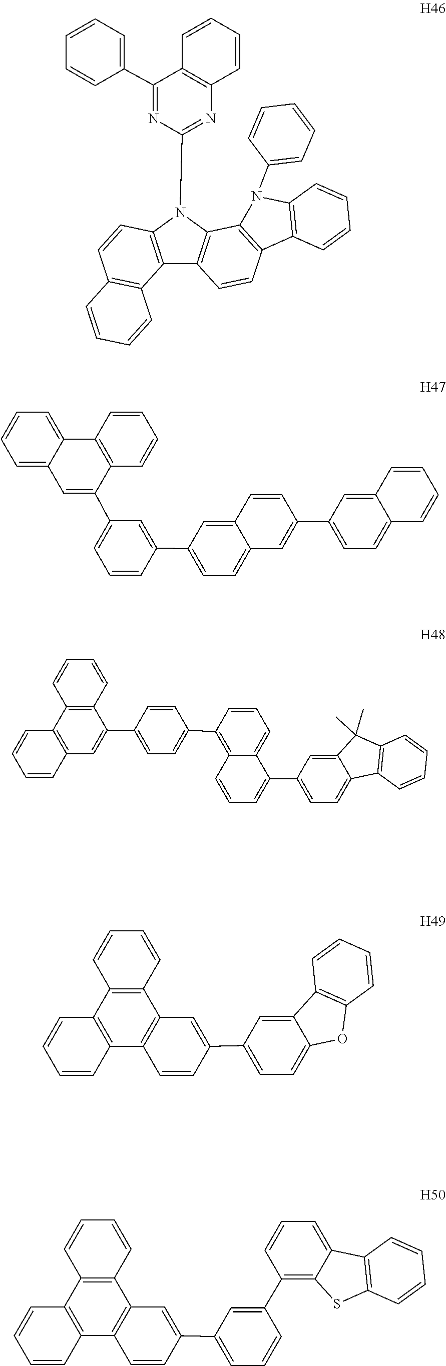

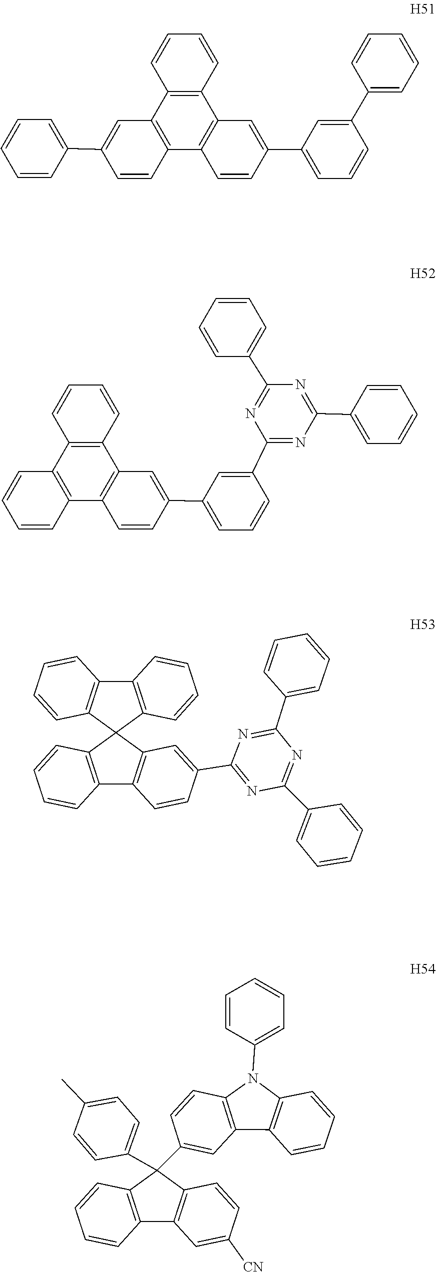

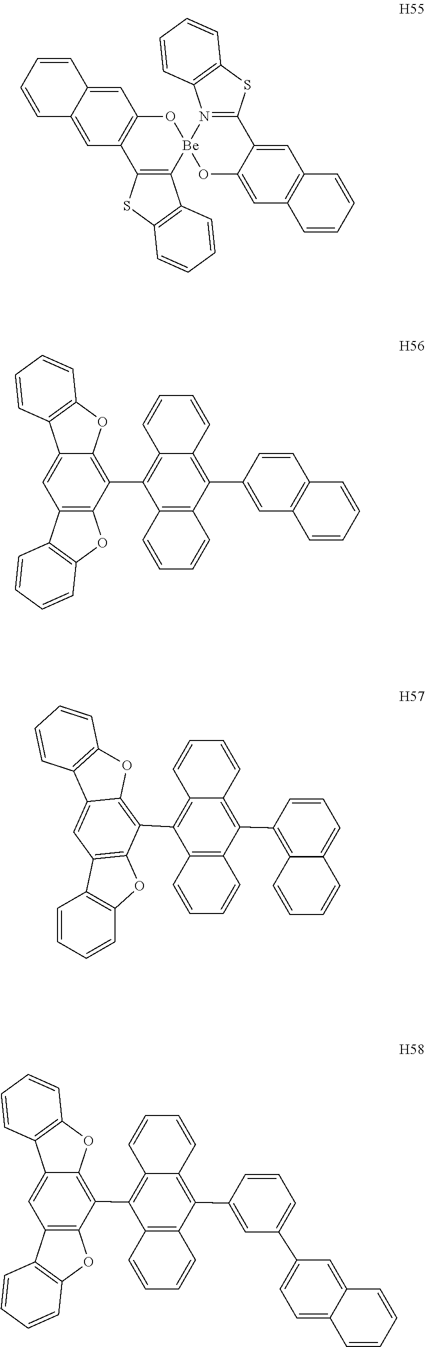

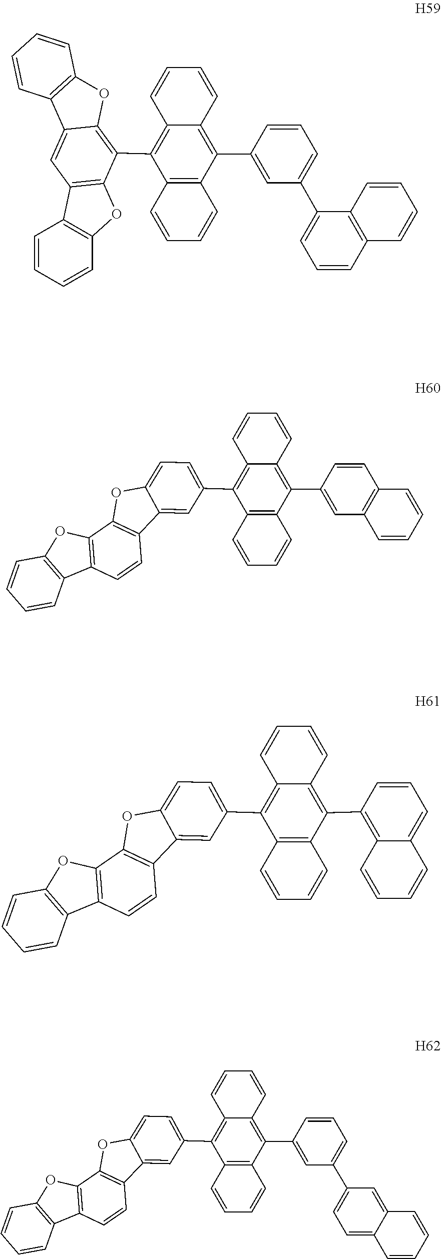 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1]

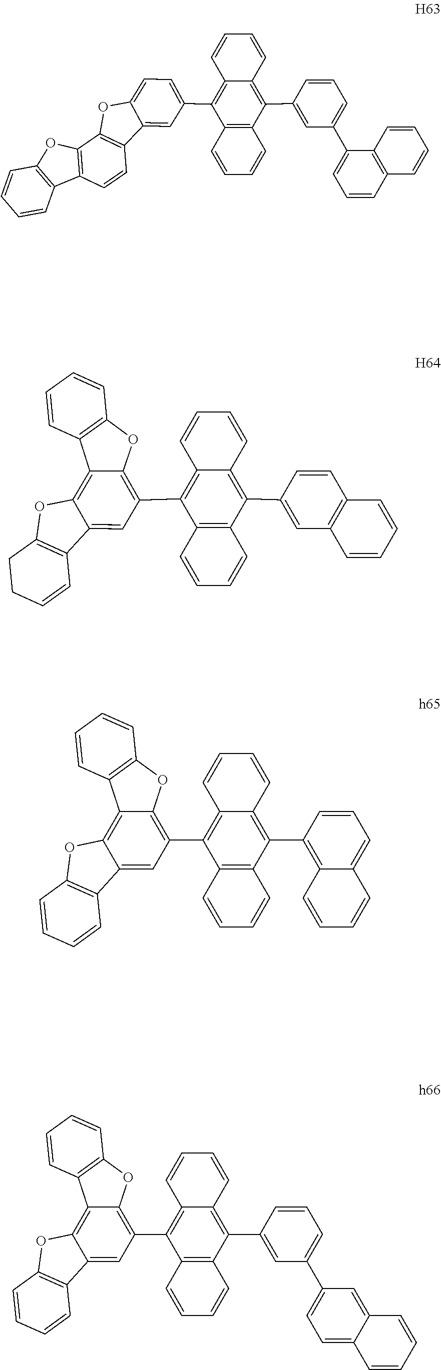 [SMILES: c1cc(-c2cccc3ccccc23)cc(-c2c3ccccc3c(-c3ccc4oc5c(ccc6c7ccccc7oc65)c4c3)c3ccccc23)c1 ; C1=Cc2c(oc3c2cc(-c2c4ccccc4c(-c4ccc5ccccc5c4)c4ccccc24)c2oc4ccccc4c23)CC1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1]

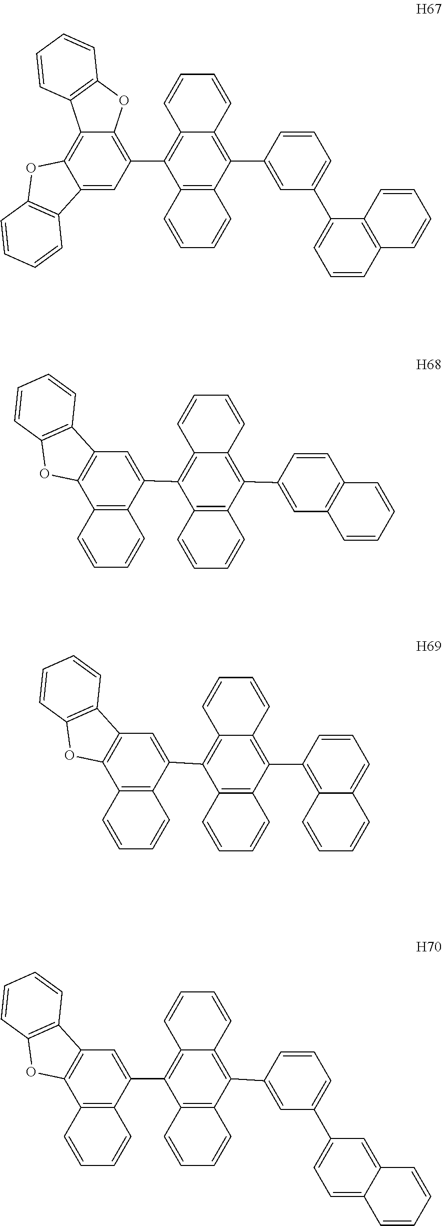 [SMILES: c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1]

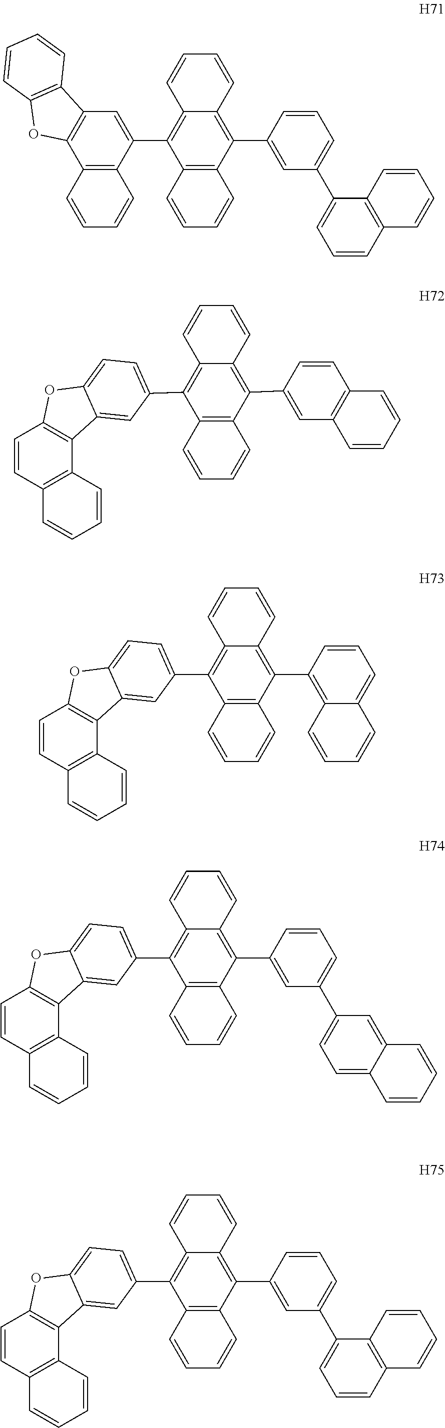 [SMILES: c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1]

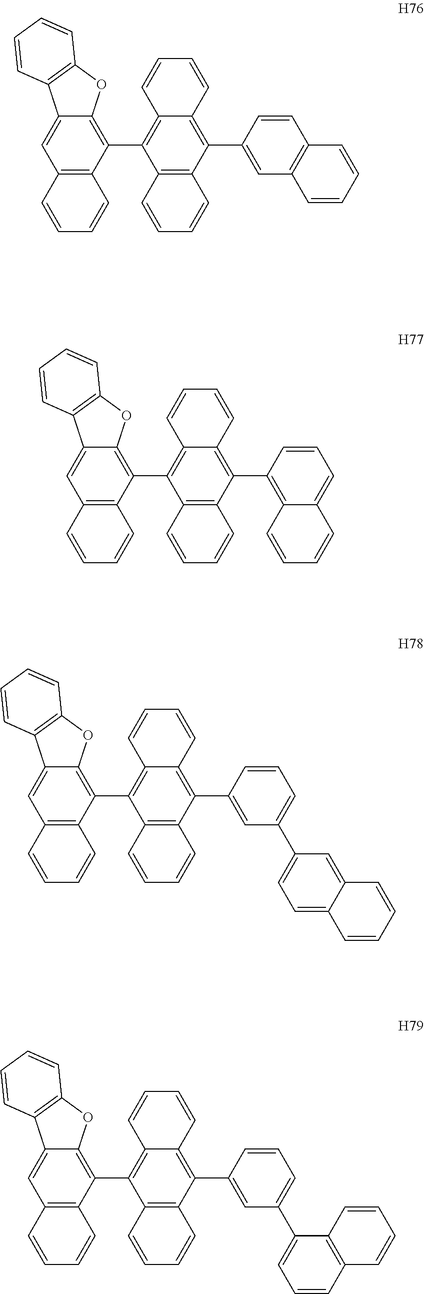 [SMILES: c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

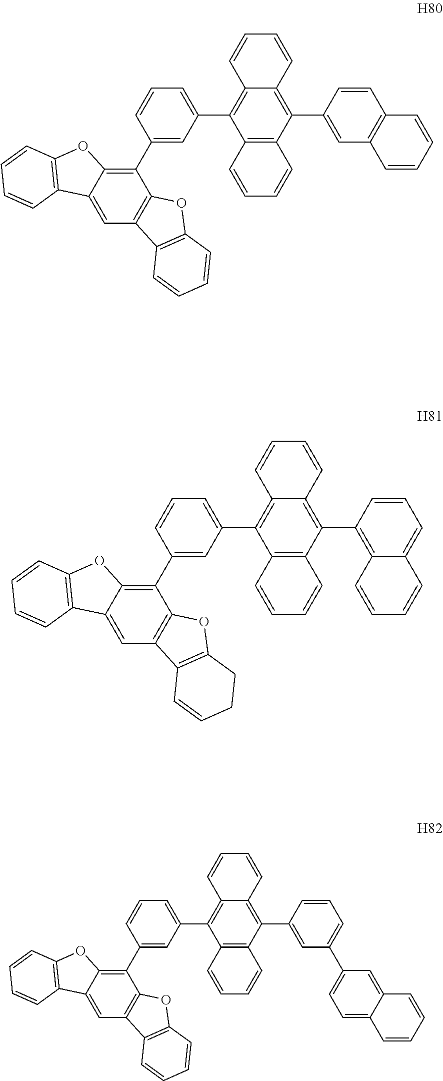 [SMILES: c1cc(-c2c3ccccc3c(-c3ccc4ccccc4c3)c3ccccc23)cc(-c2c3oc4ccccc4c3cc3c2oc2ccccc23)c1 ; C1=Cc2c(oc3c(-c4cccc(-c5c6ccccc6c(-c6cccc7ccccc67)c6ccccc56)c4)c4oc5ccccc5c4cc23)CC1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

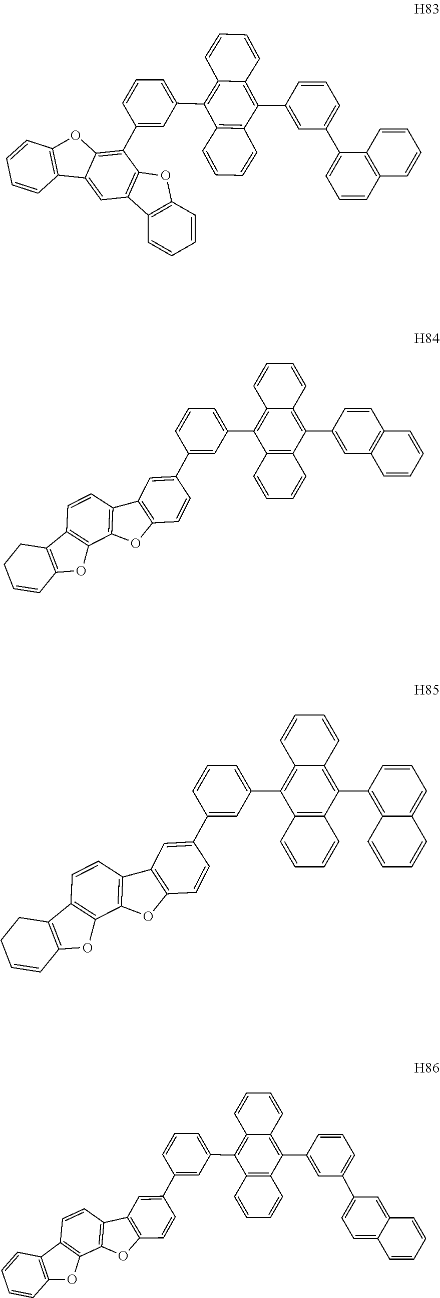 [SMILES: c1cc(-c2cccc3ccccc23)cc(-c2c3ccccc3c(-c3cccc(-c4c5oc6ccccc6c5cc5c4oc4ccccc45)c3)c3ccccc23)c1 ; C1=Cc2oc3c(ccc4c5cc(-c6cccc(-c7c8ccccc8c(-c8ccc9ccccc9c8)c8ccccc78)c6)ccc5oc43)c2CC1 ; C1=Cc2oc3c(ccc4c5cc(-c6cccc(-c7c8ccccc8c(-c8cccc9ccccc89)c8ccccc78)c6)ccc5oc43)c2CC1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1]

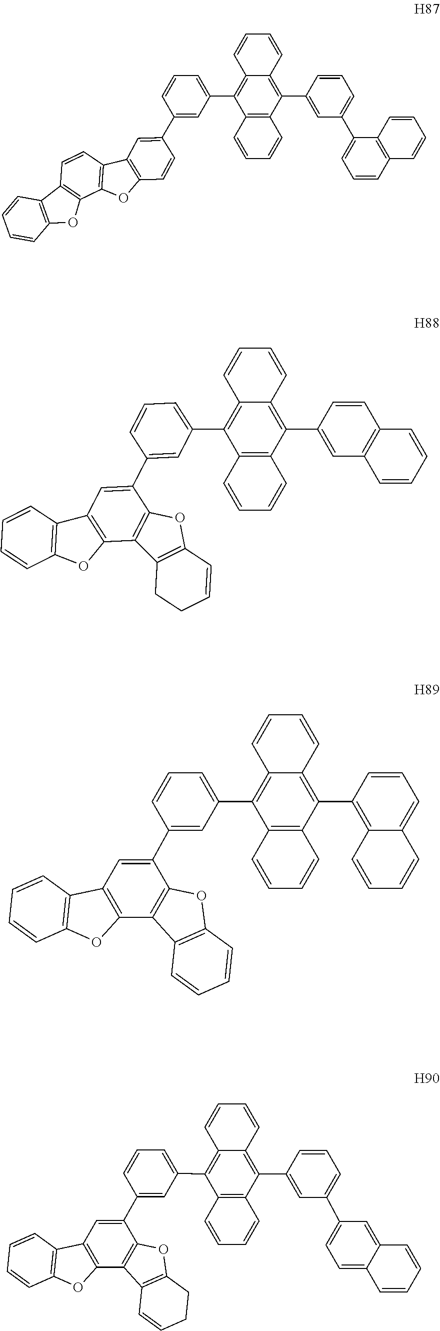 [SMILES: c1cc(-c2ccc3oc4c(ccc5c6ccccc6oc54)c3c2)cc(-c2c3ccccc3c(-c3cccc(-c4cccc5ccccc45)c3)c3ccccc23)c1 ; C1=Cc2oc3c(-c4cccc(-c5c6ccccc6c(-c6ccc7ccccc7c6)c6ccccc56)c4)cc4c5ccccc5oc4c3c2CC1 ; c1cc(-c2c3ccccc3c(-c3cccc4ccccc34)c3ccccc23)cc(-c2cc3c4ccccc4oc3c3c2oc2ccccc23)c1 ; C1=Cc2c(oc3c(-c4cccc(-c5c6ccccc6c(-c6cccc(-c7ccc8ccccc8c7)c6)c6ccccc56)c4)cc4c5ccccc5oc4c23)CC1]

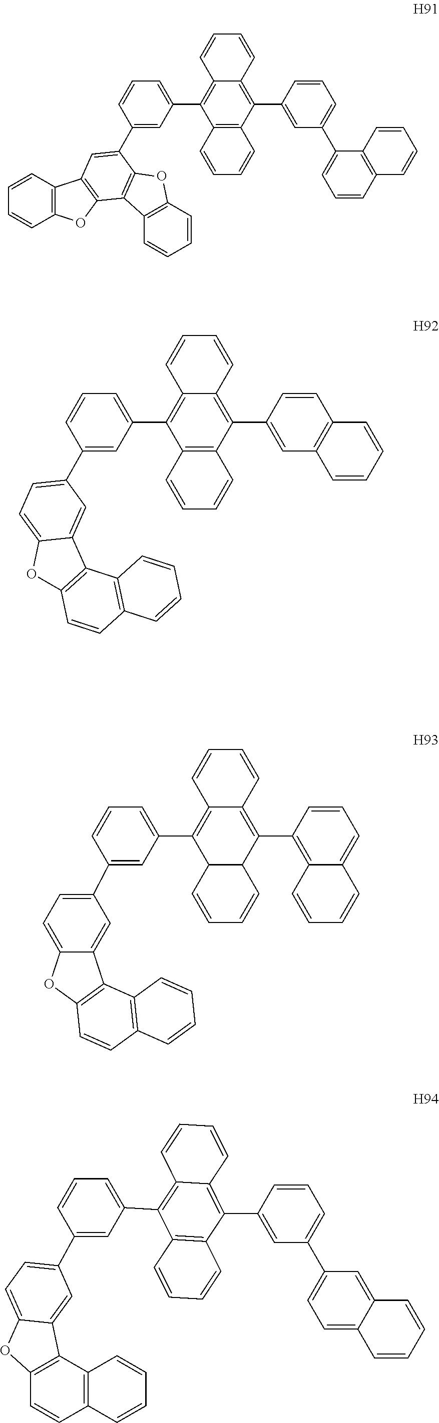 [SMILES: c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; C1=CC2C(c3cccc(-c4ccc5oc6ccc7ccccc7c6c5c4)c3)=c3ccccc3=C(c3cccc4ccccc34)C2C=C1 ; c1cc(-c2ccc3ccccc3c2)cc(-c2c3ccccc3c(-c3cccc(-c4ccc5oc6ccc7ccccc7c6c5c4)c3)c3ccccc23)c1]

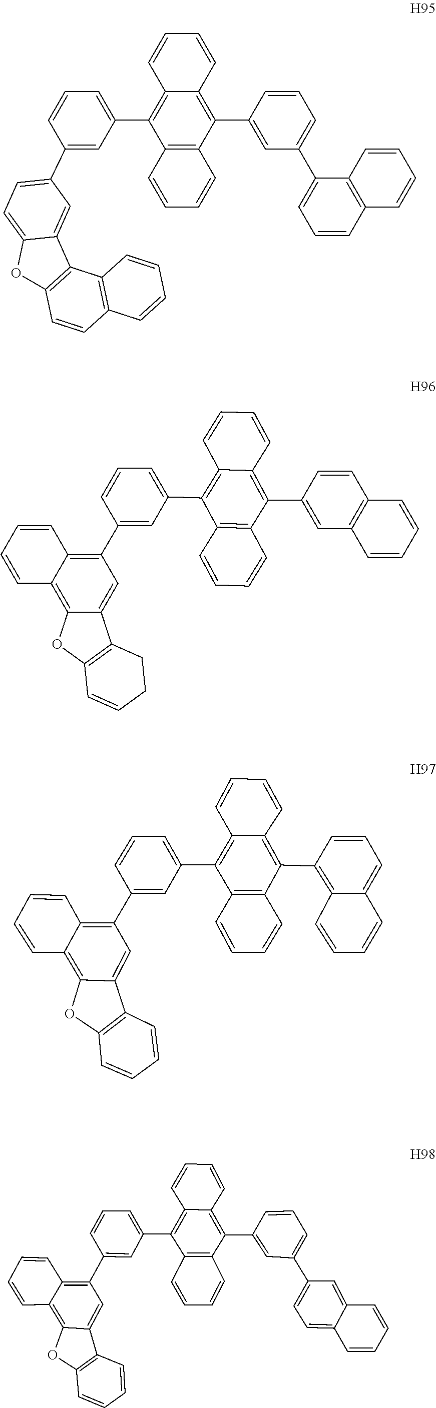 [SMILES: c1cc(-c2ccc3oc4ccc5ccccc5c4c3c2)cc(-c2c3ccccc3c(-c3cccc(-c4cccc5ccccc45)c3)c3ccccc23)c1 ; C1=Cc2oc3c(cc(-c4cccc(-c5c6ccccc6c(-c6ccc7ccccc7c6)c6ccccc56)c4)c4ccccc43)c2CC1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1]

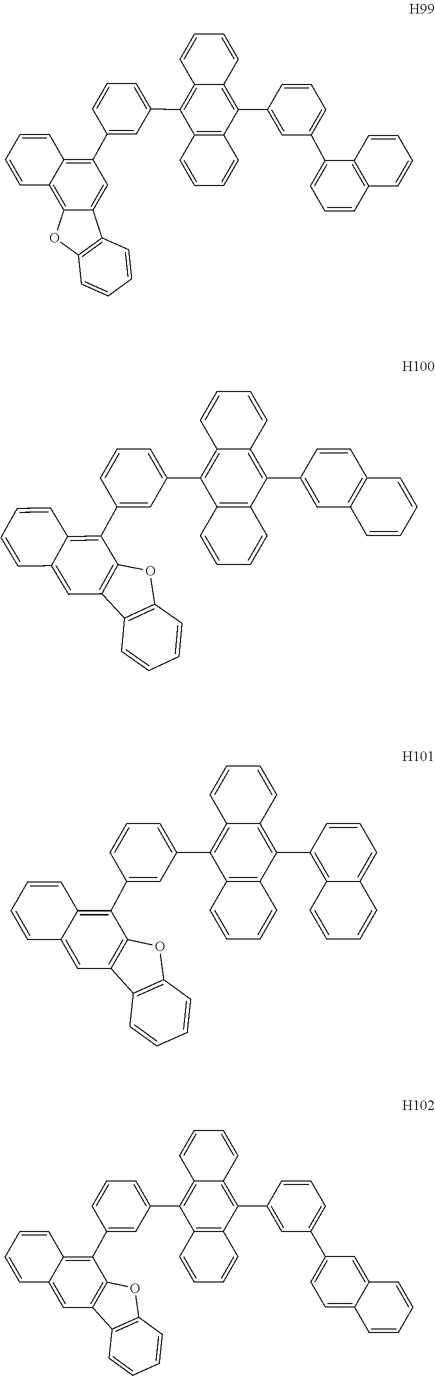 [SMILES: c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1]

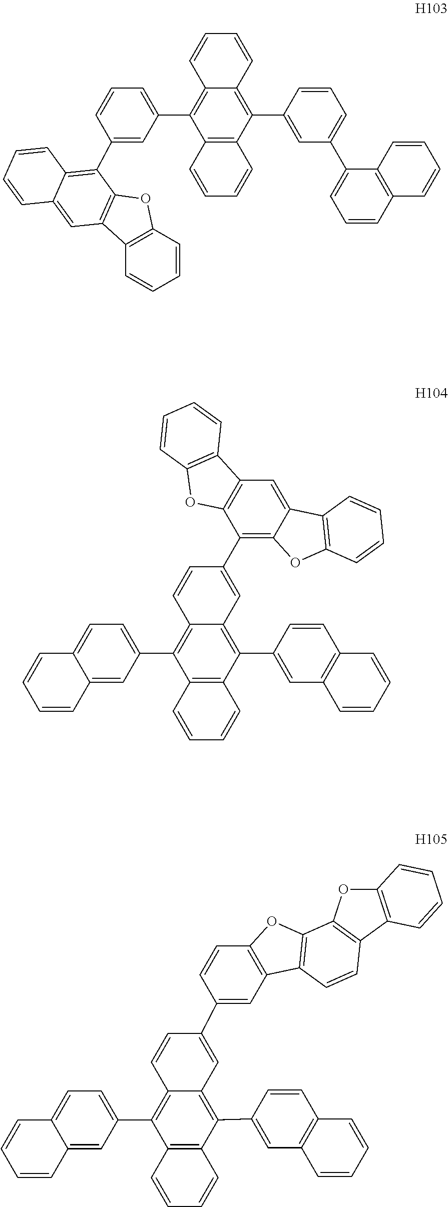 [SMILES: c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1]

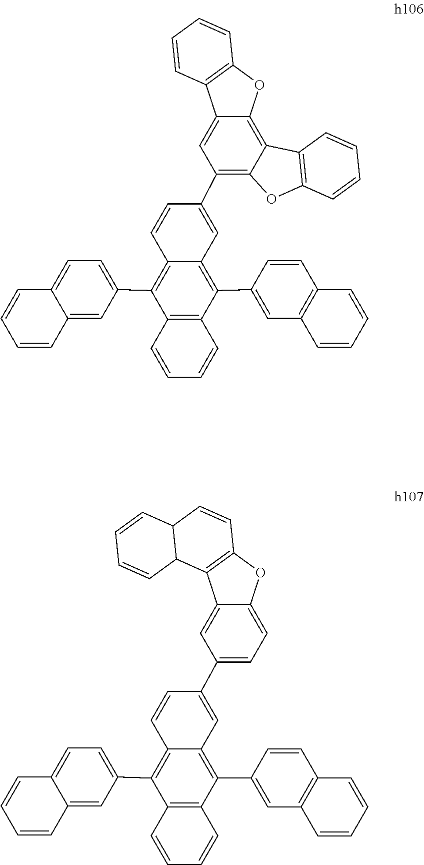 [SMILES: c1ccc2cc(-c3c4ccccc4c(-c4ccc5ccccc5c4)c4cc(-c5cc6c7ccccc7oc6c6c5oc5ccccc56)ccc34)ccc2c1 ; C1=CC2C=Cc3oc4ccc(-c5ccc6c(-c7ccc8ccccc8c7)c7ccccc7c(-c7ccc8ccccc8c7)c6c5)cc4c3C2C=C1]

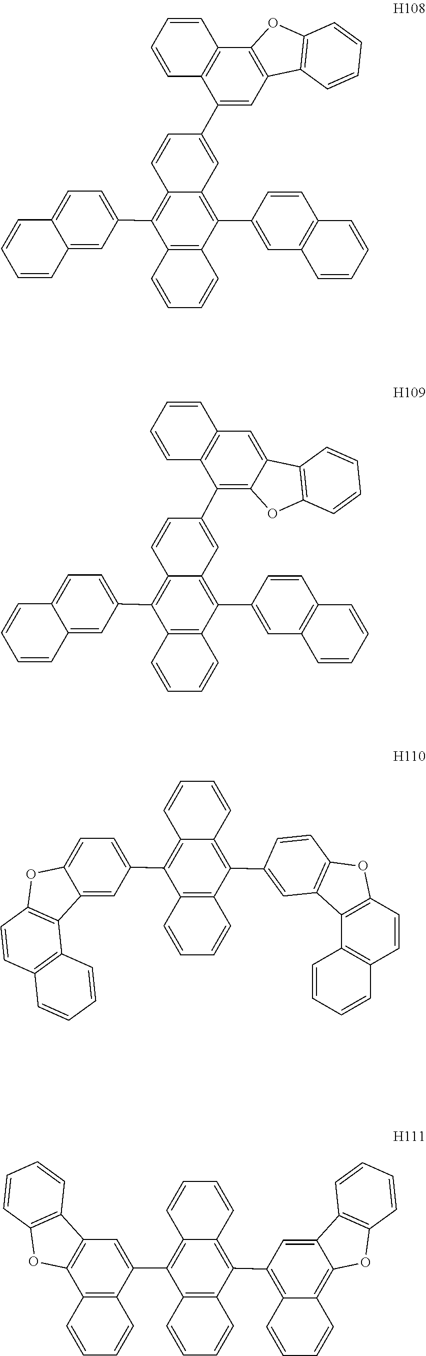 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

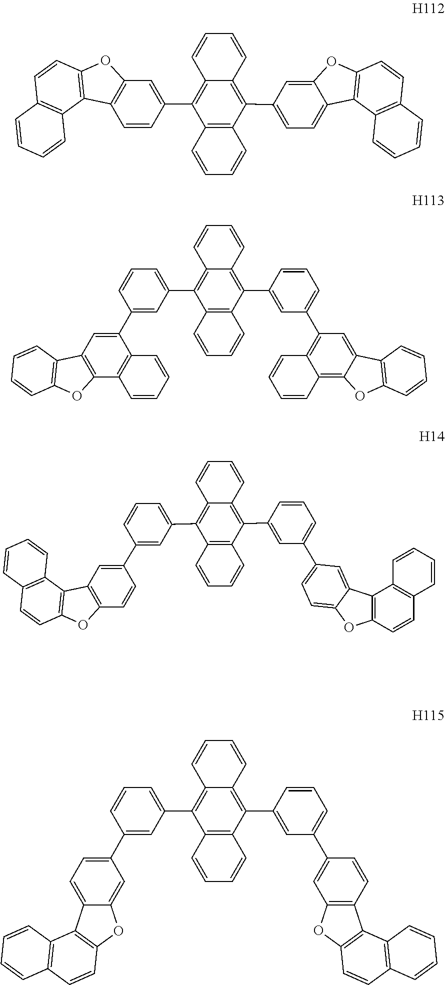 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1]

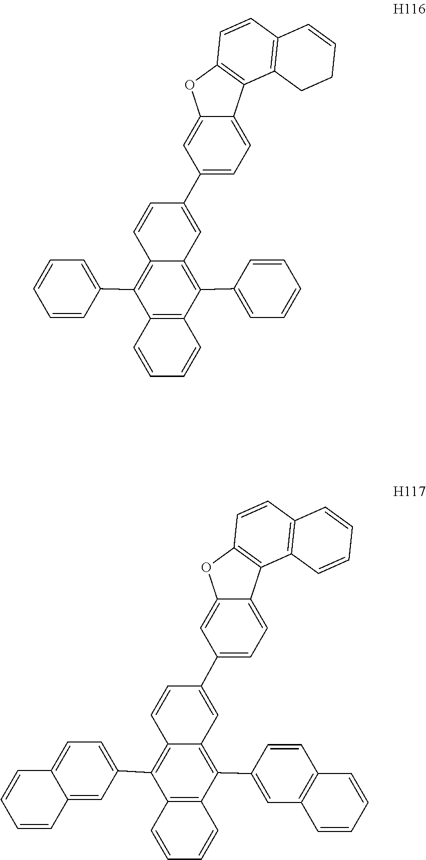 [SMILES: C1=Cc2ccc3oc4cc(-c5ccc6c(-c7ccccc7)c7ccccc7c(-c7ccccc7)c6c5)ccc4c3c2CC1 ; c1ccc2cc(-c3c4ccccc4c(-c4ccc5ccccc5c4)c4cc(-c5ccc6c(c5)oc5ccc7ccccc7c56)ccc34)ccc2c1]

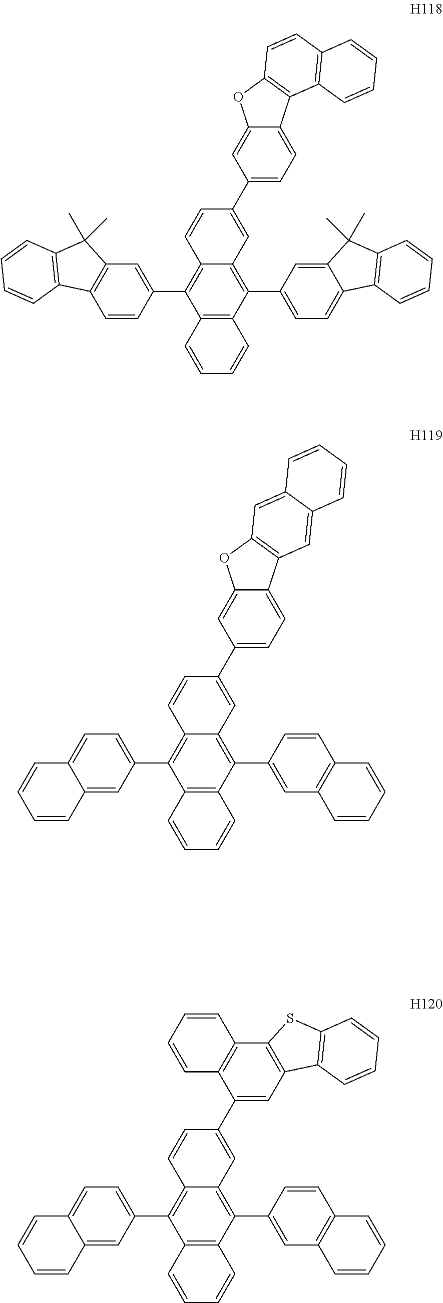 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

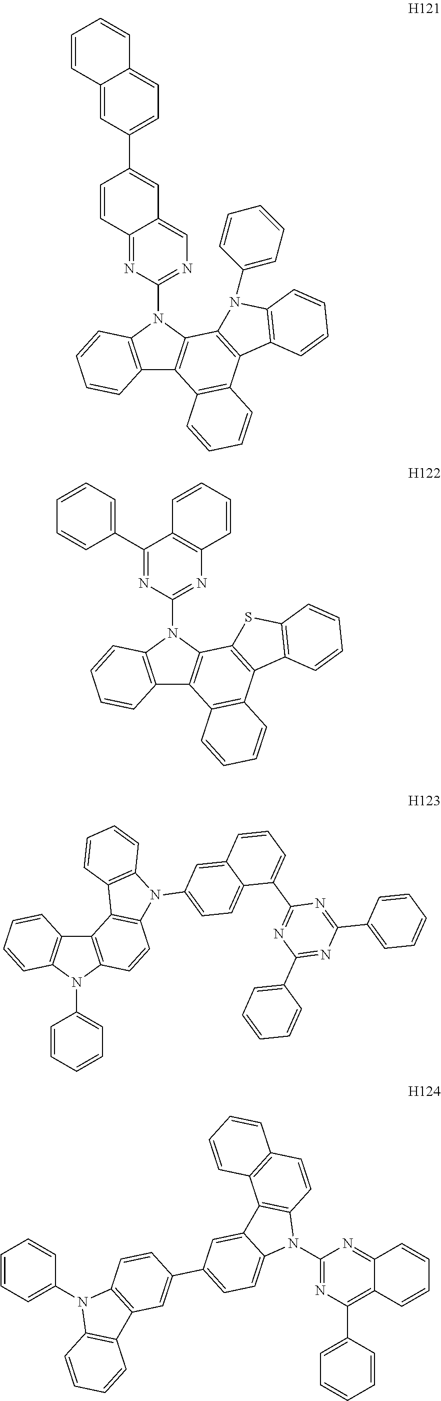

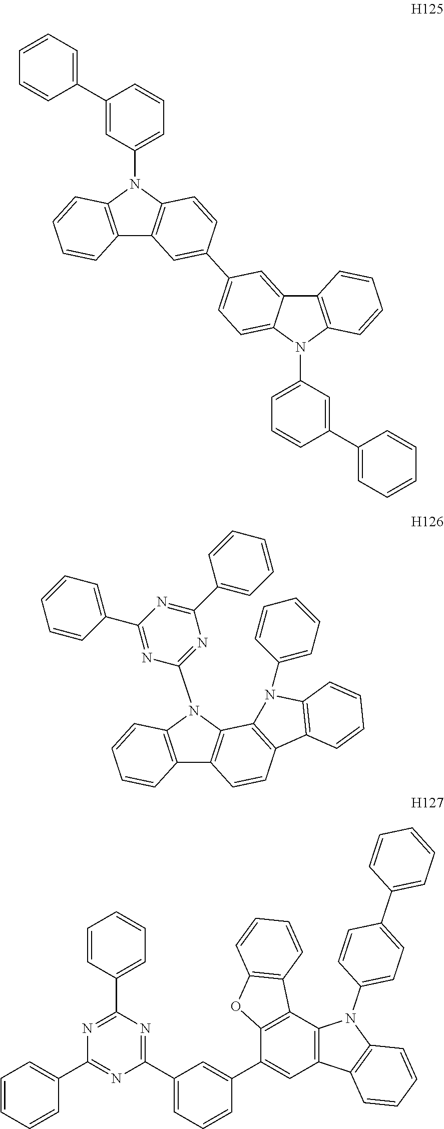 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2nc(-c3ccccc3)nc(-n3c4ccccc4c4ccc5c6ccccc6n(-c6ccccc6)c5c43)n2)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

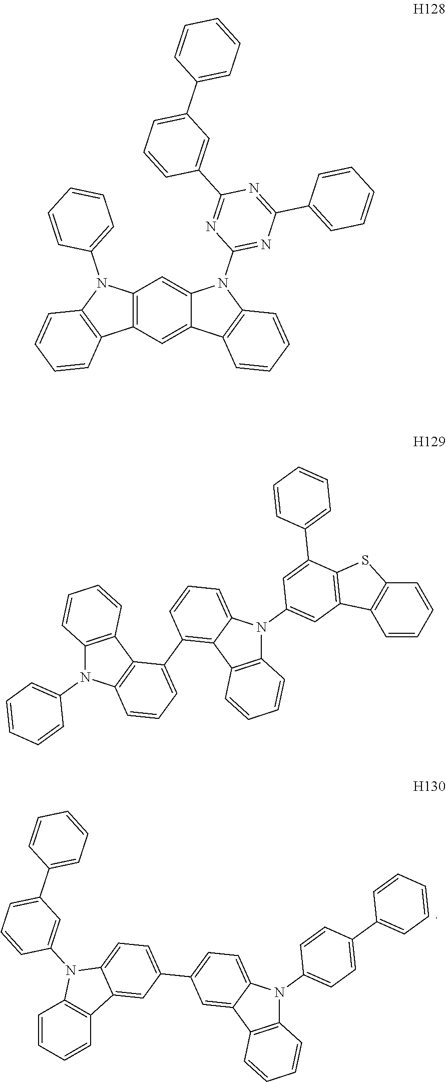 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

In one or more embodiments, the host may include a silicon-containing compound, a phosphine oxide-containing compound, or any combination thereof.

The host may have one or more suitable modifications. For example, the host may include only one kind of compound, or may include two or more kinds of different compounds.

### Phosphorescent Dopant

The emission layer may include as a phosphorescent dopant an organometallic compound represented by Formula 401:

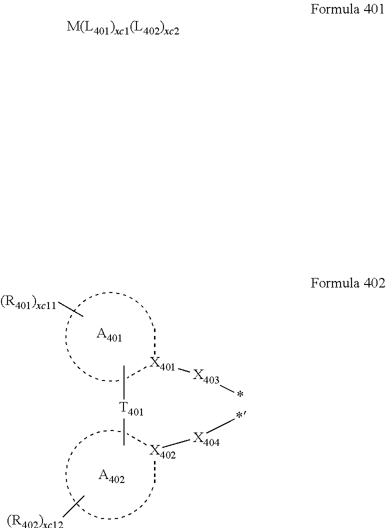

wherein in Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein if (e.g., when) xc1 is two or more, two or more of L₄₀₁ may be substantially identical to or different from each other,
L₄₀₂ may be an organic ligand, and xc2 may be 0, 1, 2, 3, or 4, and if (e.g., when) xc2 is 2 or more, two or more of L₄₀₂ may be substantially identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)*′, *—C(Q₄₁₁)(Q₄₁₂)-*′, *—C(Q₄₁₁)=C(Q₄₁₂)-*′, *—C(Q₄₁₁)=*′, or *═C(Q₄₁₁)*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be the same as described herein with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be the same as described herein with respect to Q₁,
xc11 and xc12 may each independently be an integer from 0 to 10, and
* and *′ in Formula 402 each indicate a binding site to M in Formula 401.

For example, in Formula 402, i) X₄₀₁ may be nitrogen, and X₄₀₂ may be carbon, or ii) each of X₄₀₁ and X₄₀₂ may be nitrogen.

In one or more embodiments, if (e.g., when) xc1 in Formula 401 is 2 or more, two ring A₄₀₁ in two or more L₄₀₁ may optionally be linked to each other via T₄₀₂, which is a linking group, or two ring A₄₀₂ in two or more L₄₀₁ may optionally be linked to each other via T₄₀₃, which is a linking group. T₄₀₂ and T₄₀₃ may each be the same as described herein with respect to T₄₀₁.
L₄₀₂ in Formula 401 may be an organic ligand. For example, L₄₀₂ may include a halogen group, a diketone group (for example, an acetylacetonate group), a carboxylic acid group (for example, a picolinate group), —C(═O), an isonitrile group, —CN group, a phosphorus-containing group (for example, a phosphine group, a phosphite group, and/or the like), or any combination thereof.

The phosphorescent dopant of the emission layer may be a platinum-containing organometallic compound.

The platinum-containing organometallic compound may further include, in addition to the platinum, a first ligand bonded to the platinum.

For example, the platinum-containing organometallic compound may satisfy at least one selected from among Conditions A to C:

### Condition A

the first ligand is a tetradentate ligand, and
the number of cyclometallated rings formed by a chemical bond between the platinum and the first ligand is three;

### Condition B

each of carbon, nitrogen and oxygen of the first ligand is chemically bonded to the platinum; and

### Condition C

the first ligand includes an imidazole group, a benzimidazole group, a naphthoimidazole group, or any combination thereof.

In one or more embodiments, the platinum-containing organometallic compound may satisfy all of Conditions A to C.

In one or more embodiments, the platinum-containing organometallic compound may be, for example, an organometallic compound represented by Formula 10:

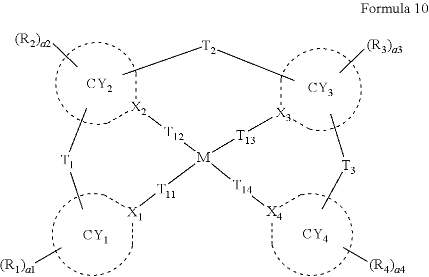

wherein in Formula 10,
M may be Pt,
X₁ to X₄ may each independently be N or C,
T₁₁ to T₁₄ may each independently be a chemical bond, O, S, B(R′), N(R′), P(R′), C(R′)(R″), Si(R′)(R″), Ge(R′)(R″), C(═O), B(R′)(R″), N(R′)(R″), or P(R′)(R″),

When T₁₁ is a chemical bond, X₁ and M may be directly bonded to each other, if (e.g., when) T₁₂ is a chemical bond, X₂ and M may be directly bond to each other, if (e.g., when) T₁₃ is a chemical bond, X₃ and M may be directly bond to each other, if (e.g., when) T₁₄ is a chemical bond, X₄ and M may be directly bond to each other.

Two of the bonds selected from among a bond between X₁ or T₁₁ and M, a bond between X₂ or T₁₂ and M, a bond between X₃ or T₁₃ and M, and a bond between X₄ or T₁₄ and M may be coordinate bonds, and the other two bonds may be covalent bonds,
T₁ may be a single bond, a double bond, *—N(R₅)—*′, *—B(R₅)—*′, *—P(R₅)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*′, *—C(R₅)=*′, *=C(R₅)—*′, *—C(R₅ₐ)═C(R_{5b})—*′, *—C(═S)—*′, or *—C≡C—*′,
T₂ may be a single bond, a double bond, *—N(R₆)—*′, *—B(R₆)—*′, *—P(R₆)—*′, *—C(R₆ₐ)(R_{6b})—*′, *—Si(R₆ₐ)(R_{6b})—*′, *—Ge(R₆ₐ)(R_{6b})—*′, *—S—*′, *—Se—*′, *O—*′, *—C(═O)—*′, *—S(=O)—*′, *—S(═O)₂—*′, *—C(R₆)=*′, *=C(R₆)—*′, *—C(R₆ₐ)═C(R_{6b})—*′, *—C(═S)—*′, or *—C≡C—*′,
T₃ may be a single bond, a double bond, *—N(R₇)—*′, *—B(R₇)—*′, *—P(R₇)—*′, *—C(R₇ₐ)(R_{7b})—*′, *—Si(R₇ₐ)(R_{7b})—*′, *—Ge(R₇ₐ)(R_{7b})—*′, *—S—*′, *—Se—*′, *—O—*′, *—C(═O)—*′, *—S(=O)—*′, *—S(═O)₂—*′, *—C(R₇)=*′, *=C(R₇)—*′, *—C(R₇ₐ)═C(R_{7b})—*′, *—C(═S)—*′, or *—C≡C—*′,
ring CY₁ to ring CY₄ may each independently be a C₃-C₆₀ carbocyclic group or a C₁-C₆₀ heterocyclic group,
R₁ to R₇, R₅ₐ, R_{5b}, R₆ₐ, R_{6b}, R₇ₐ, R_{7b}, R′, and R″ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a4 may each independently be one (e.g., any one) selected from among an integer from 0 to 20,
* and *′ each indicate a binding site to an adjacent atom,
each of i) two groups of R₁ in the number of a1, ii) two groups of R₂ in the number of a2, iii) two groups of R₃ in the number of a3, iv) two groups of R₄ in the number of a4, v) R₅ₐ and R_{5b}, vi) R₆ₐ and R_{6b}, and vii) R₇ₐ and R_{7b}, may optionally be bonded to each other via a single bond, a double bond, or a first linking group to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

In one or more embodiments, in Formula 10,
i) X₁ and X₃ may be C, and X₂ and X₄ may be N,
ii) X₁ and X₄ may be C, and X₂ and X₃ may be N, or
iii) X₁, X₂, and X₃ may be C, and X₄ may be N.

In one or more embodiments, in Formula 10,
T₁₁ may be O or S, and
T₁₂to T₁₄ may each be a chemical bond.

In one or more embodiments, in Formula 10,
T₁₁ may be O or S,
T₁₂to T₁₄ may each be a chemical bond, and
i) a bond between T₁₁ and M and a bond between X₃ and M may each be a covalent bond, and a bond between X₂ and M and a bond between X₄ and M may each be a coordinate bond, or ii) a bond between T₁₁ and M and a bond between X₄ and M may each be a covalent bond, and a bond between X₂ and M and a bond between X₃ and M may each be a coordinate bond.
T₁ to T₃ in Formula 10 may each be a single bond,
ring CY₁ in Formula 10 may be a benzene group, a naphthalene group, a dibenzofuran group, a dibenzothiophene group, a carbazole group, a fluorene group, or a dibenzosilole group,
ring CY₂ in Formula 10 may be an imidazole group, a benzimidazole group, a naphthoimidazole group, a pyridine group, a pyrimidine group, a pyrazine group, a pyridazine group, a quinoline group, an isoquinoline group, or a quinoxaline group,
ring CY₃ in Formula 10 may be a benzene group, a naphthalene group, a dibenzofuran group, a dibenzothiophene group, a carbazole group, a fluorene group, a dibenzosilole group, a pyridine group, a pyrimidine group, a pyrazine group, a pyridazine group, a quinoline group, an isoquinoline group, a quinoxaline group, an azadibenzofuran group, an azadibenzothiophene group, an azacarbazole group, an azafluorene group, or an azadibenzosilole group,
ring CY₄ in Formula 10 may be a benzene group, a naphthalene group, a dibenzofuran group, a dibenzothiophene group, a carbazole group, a fluorene group, a dibenzosilole group, a pyridine group, a pyrimidine group, a pyrazine group, a pyridazine group, a quinoline group, an isoquinoline group, a quinoxaline group, an azadibenzofuran group, an azadibenzothiophene group, an azacarbazole group, an azafluorene group, an azadibenzosilole group, an imidazole group, a benzimidazole group, or a naphthoimidazole group.

At least one of ring CY₂ or ring CY₄ of Formula 10 may be an imidazole group, a benzimidazole group, or a naphthoimidazole group.

R₁ to R₇, R₅ₐ, R_{5b}, R₆ₐ, R_{6b}, R₇ₐ, R_{7b}, R′, and R″ in Formula 10 may each independently be:
hydrogen, deuterium, —F, or a cyano group;
a C₁-C₂₀ alkyl group or a C₃-C₁₀ cycloalkyl group, each unsubstituted or substituted with deuterium, —F, cyano group, or any combination thereof; or
a phenyl group, a biphenyl group, a naphthyl group, a dibenzofuranyl group, or a dibenzothiophenyl group (or a thienyl group), each unsubstituted or substituted with deuterium, —F, cyano group, a C₁-C₂₀ alkyl group, adeuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀alkyl)biphenyl group, or any combination thereof.
a1 to a4 in Formula 10 respectively indicate the numbers of R₁ to R₄, and for example, may each independently be 0, 1, 2, 3, 4, 5, or 6.

For example, a group represented by

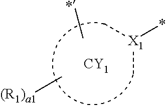

in Formula 10 may be a group represented by one (e.g., any one) selected from among Formulae CY1(1) to CY1(16):

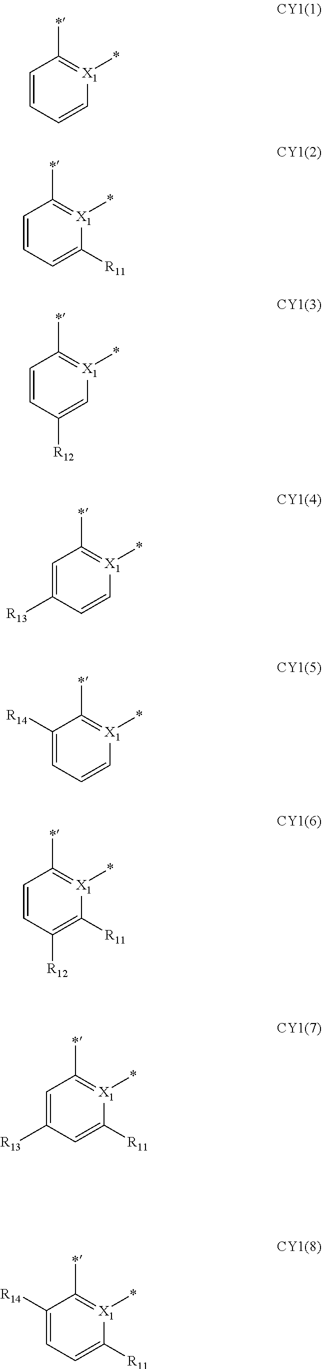

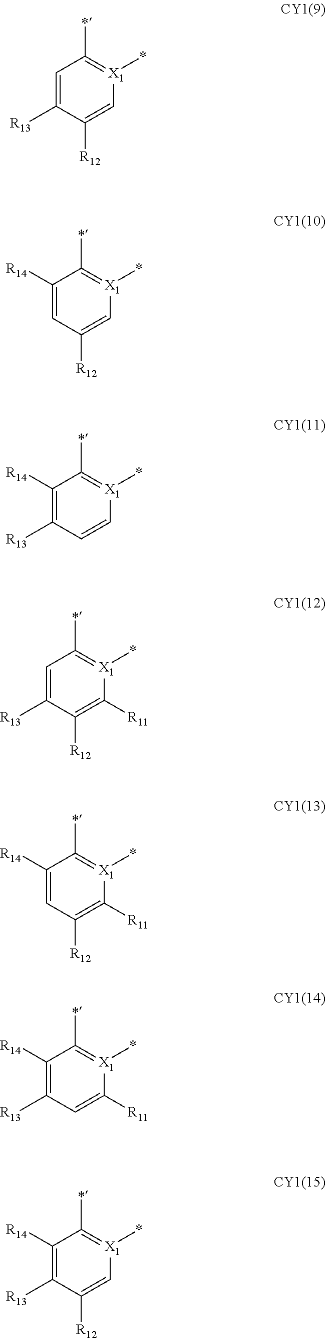

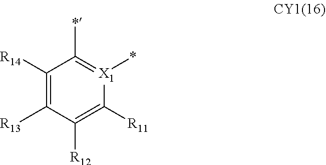

wherein in Formulae CY1(1) to CY1(16),
X₁ is the same as described above,
R₁₁ to R₁₄ are each the same as described in connection with R₁ in the specification, wherein R₁₁ to R₁₄ are each not hydrogen,
* indicates a binding site to T₁₁ in Formula 10, and
*′ indicates a binding site to T₁ in Formula 10.

In one or more embodiments, a group represented by

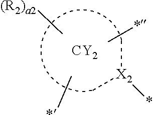

in Formula 10 may be a group represented by one (e.g., any one) selected from among Formulae CY2(1) to CY2(21):

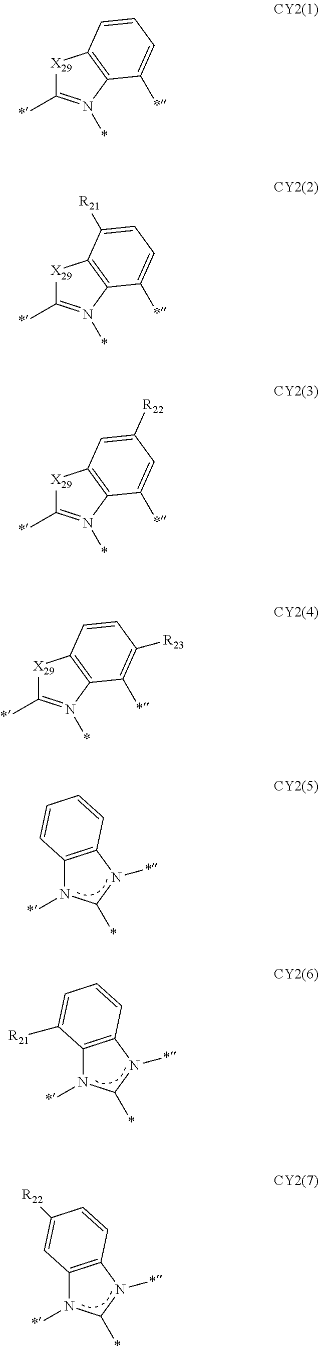

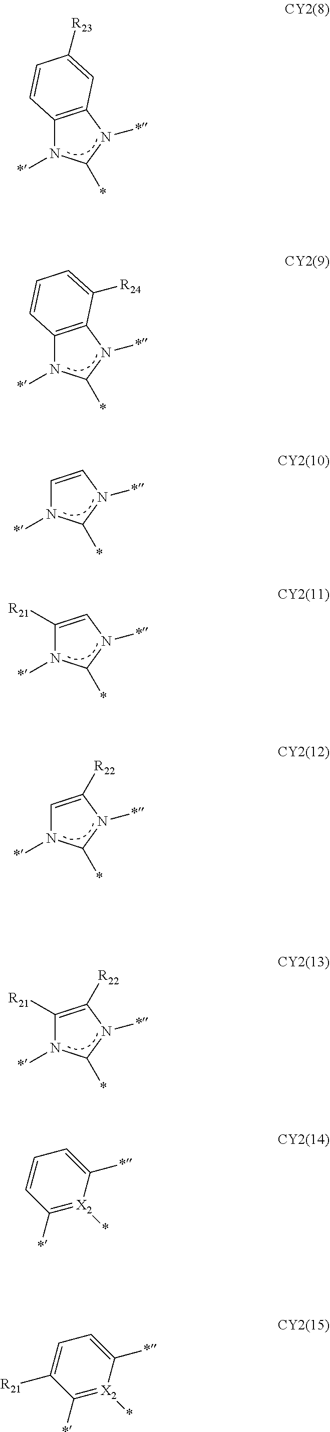

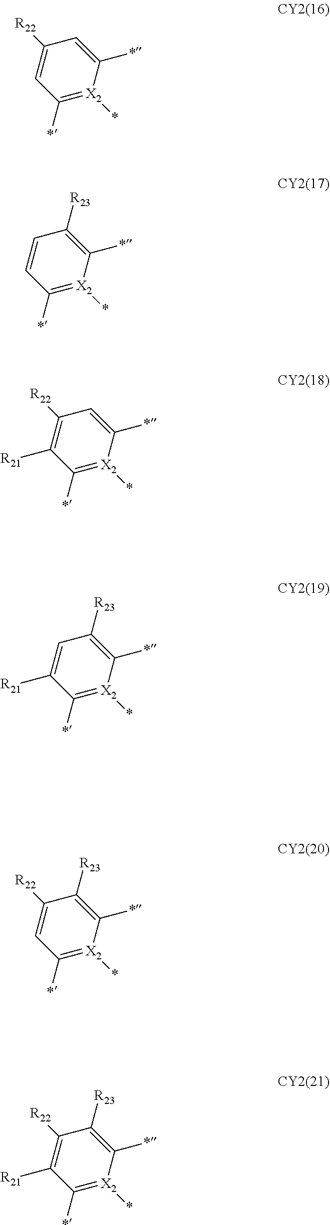

wherein in Formulae CY₂(1) to CY₂(21),
X₂ is the same as described in the specification,
X₂₉ may be O, S, N(R₂₉), C(R₂₉ₐ)(R_{29b}), or Si(R₂₉ₐ)(R_{29b}),
R₂₁ to R₂₄, R₂₉, R₂₉ₐ, and R_{29b} are each the same as described in connection with R₂ in the specification, wherein R₂₁ to R₂₄ are each not hydrogen,
* indicates a binding site to T₁₂ in Formula 10,
*′ indicates a binding site to T₁ in Formula 10, and
*″ indicates a binding site to T₂ in Formula 10.

Formulae CY2(1) to CY2(4) belong to a group represented by

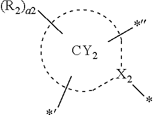

where X₂ is nitrogen, and Formulae CY2(5) to CY2(13) belong to a group represented by

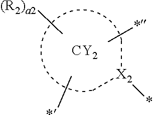

where X₂ is carbon (for example, carbon of a carbene moiety).

In one or more embodiments, a group represented by

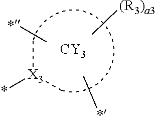

in Formula 10 may be a group represented by one (e.g., any one) selected from among Formulae CY3(1) to CY3(12):

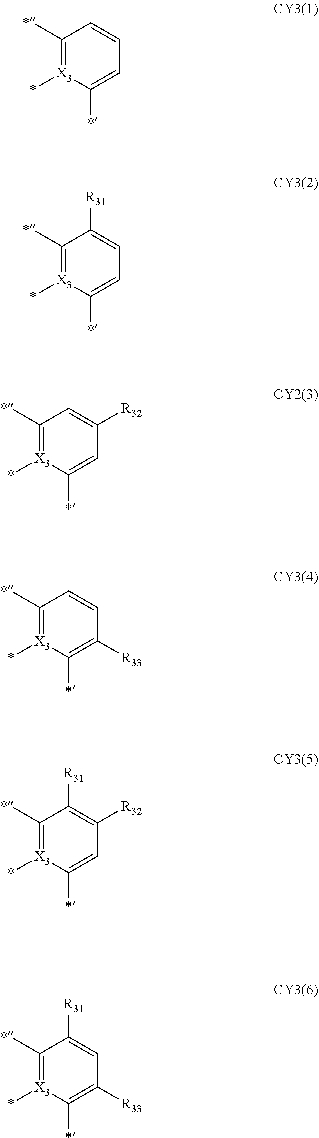

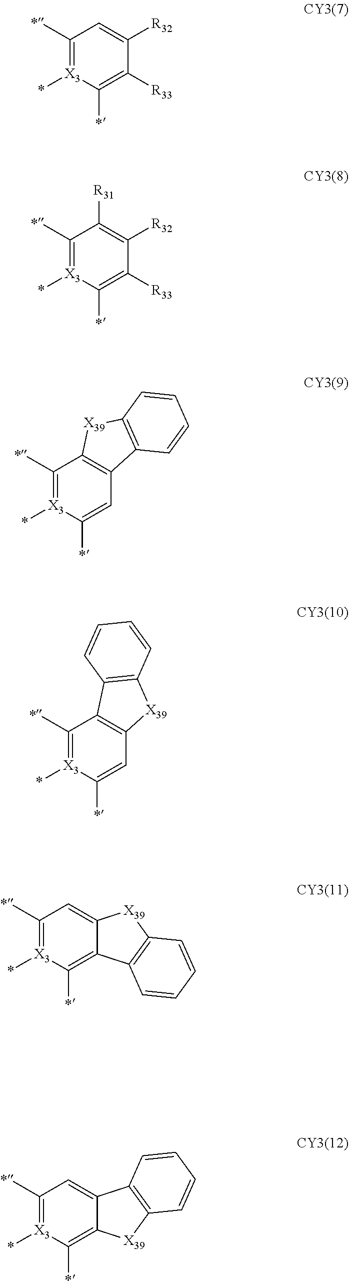

wherein in Formulae CY₃(1) to CY₃(12),
X₃ is the same as described in the specification,
X₃₉ may be O, S, N(R₃₉), C(R₃₉ₐ)(R_{39b}), or Si(R₃₉ₐ)(R_{39b}),
R₃₁ to R₃₃, R₃₉, R₃₉ₐ, and R_{39b} are each the same as described in connection with R₃ in the specification, wherein R₃₁ to R₃₃ are each not hydrogen,
* indicates a binding site to T₁₃ in Formula 10,
*′ indicates a binding site to T₃ in Formula 10, and
*″ indicates a binding site to T₂ in Formula 10.

In one or more embodiments, a group represented by

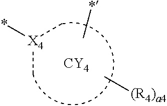

in Formula 10 may be a group represented by one (e.g., any one) selected from among Formulae CY4(1) to CY4(27):

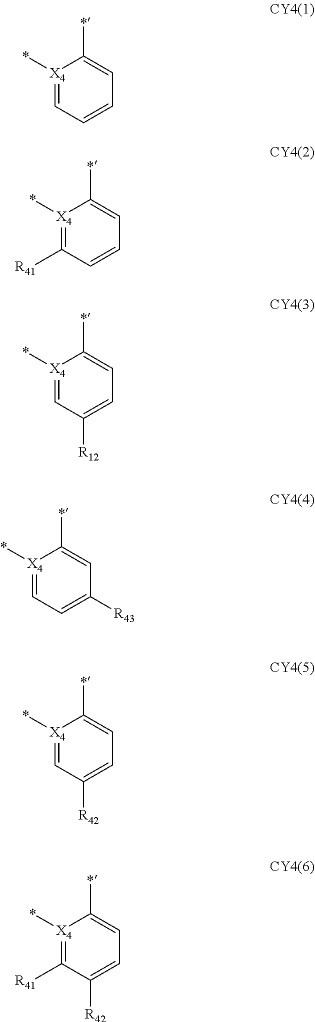

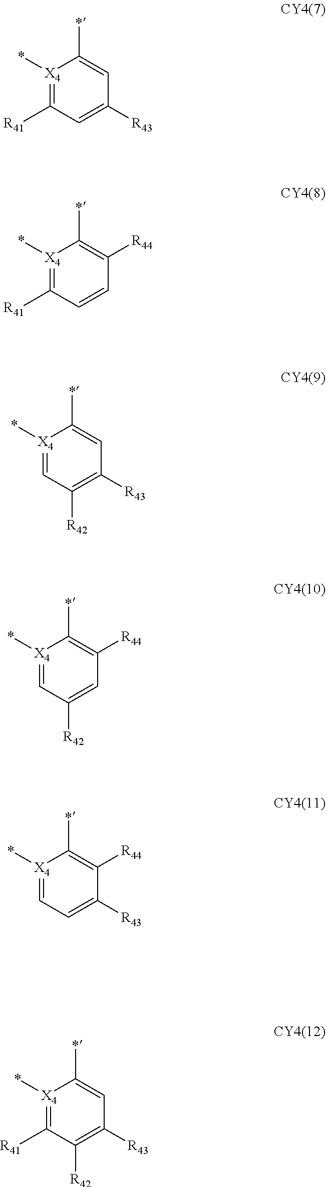

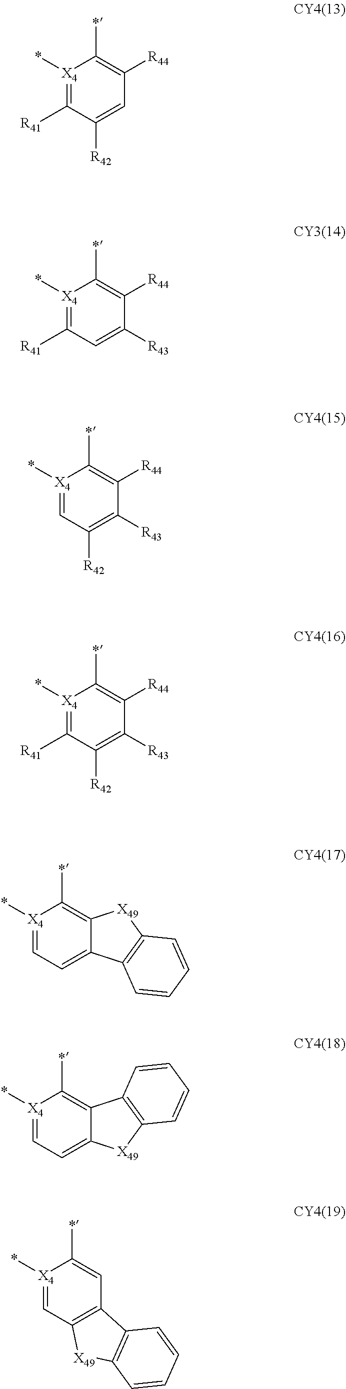

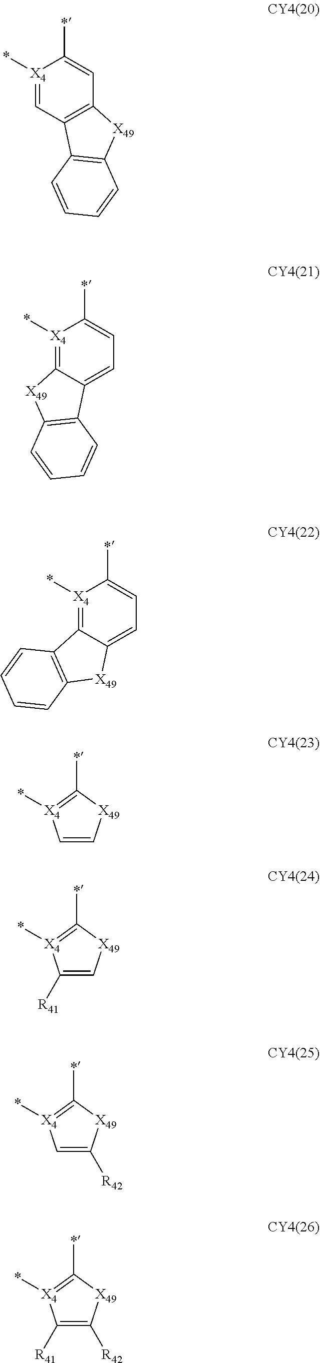

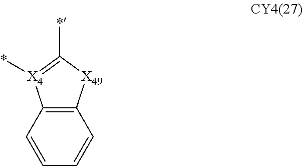

wherein in Formulae CY4(1) to CY4(27),
X₄ is the same as described in the specification,
X₄₉ may be O, S, N(R₄₉), C(R₄₉ₐ)(R_{49b}), or Si(R₄₉ₐ)(R_{49b}),
R₄₁ to R₄₄, R₄₉, R₄₉ₐ and R_{49b} are each the same as described in connection with R₄, and R₄₁ to R₄₄ are each not hydrogen,
* indicates a binding site to T₁₄ in Formula 10, and
* indicates a binding site to T₃ in Formula 10.

Or, the dopant of the emission layer may be an iridium-containing organometallic compound.

For example, the iridium-containing organometallic compound may include a first ligand bonded to the iridium, a second ligand, and a third ligand. In this regard, the first ligand may be a bidentate ligand including Y₁-containing ring B₁ and Y₂-containing ring B₂, the second ligand may be a bidentate ligand including Y₃-containing ring B₃ and Y₄-containing ring B₄, the third ligand may be a bidentate ligand including Y₅-containing ring B₅ and Y₆-containing ring B₆, Y₁, Y₃, and Y₅ may each be nitrogen (N), and Y₂, Y₄, and Y₆ may each be carbon (C).

For example, the Y₂-containing ring B₂ and the Y₄-containing ring B₄ may be different from each other.

In one or more embodiments, the Y₂-containing ring B₂ may be a polycyclic group. For example, the Y₂-containing ring B₂ may be a polycyclic group in which three or more monocyclic groups (for example, 3 to 15 monocyclic groups) are condensed with each other. The monocyclic group may be, for example, a furan group, a thiophene group, a selenophene group, a pyrrole group, a cyclopentadiene group, a silole group, a benzene group, a pyridine group, a pyrimidine group, a pyrazine group, or a pyridazine group. Or, the Y₂-containing ring B₂ may be a monocyclic group as described above.

In one or more embodiments, the Y₂-containing ring B₂ may be a polycyclic group in which one 5-membered monocyclic group (for example, a furan group, a thiophene group, a selenophene group, a pyrrole group, a cyclopentadiene group, a silole group, and/or the like) is condensed with at least two 6-membered monocyclic groups (for example, a benzene group, a pyridine group, a pyrimidine group, a pyrazine group, a pyridazine group, and/or the like).

In one or more embodiments, the Y₄-containing ring B₄ may be a monocyclic group. For example, the Y₄-containing ring B₄ may be a 6-membered monocyclic group 1 (for example, a benzene group, a pyridine group, a pyrimidine group, a pyrazine group, a pyridazine group, a triazine group, and/or the like).

In one or more embodiments, the Y₄-containing ring B₄ may be a naphthalene group, a phenanthrene group, or an anthracene group.

The iridium-containing organometallic compound may be a homoleptic complex. For example, the first ligand, the second ligand, and the third ligand may be substantially identical to each other.

Or, the iridium-containing organometallic compound may be a heteroleptic complex.

For example, the third ligand may be substantially identical to the second ligand.

In one or more embodiments, the third ligand may be substantially identical to the first ligand.

In one or more embodiments, the third ligand may be different from each of the first ligand and the second ligand.

For example, the phosphorescent dopant may be one (e.g., any one) selected from among Compounds GD01 to GD25 or R01:

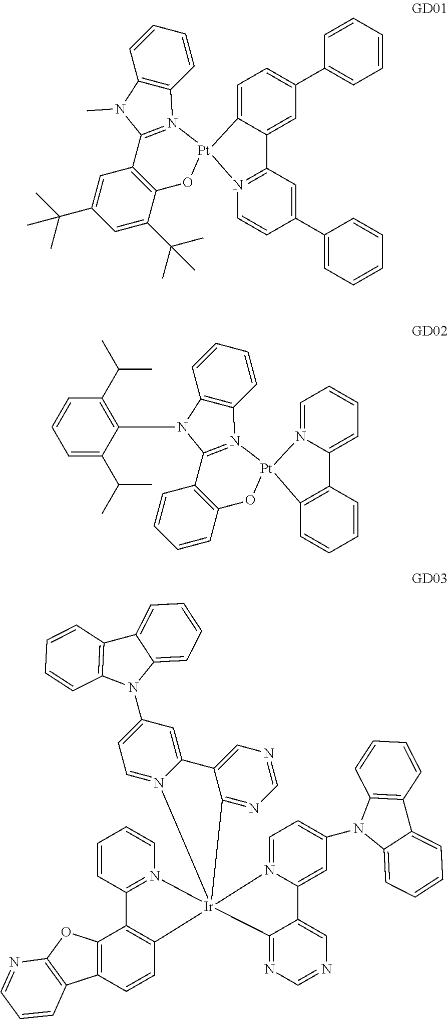

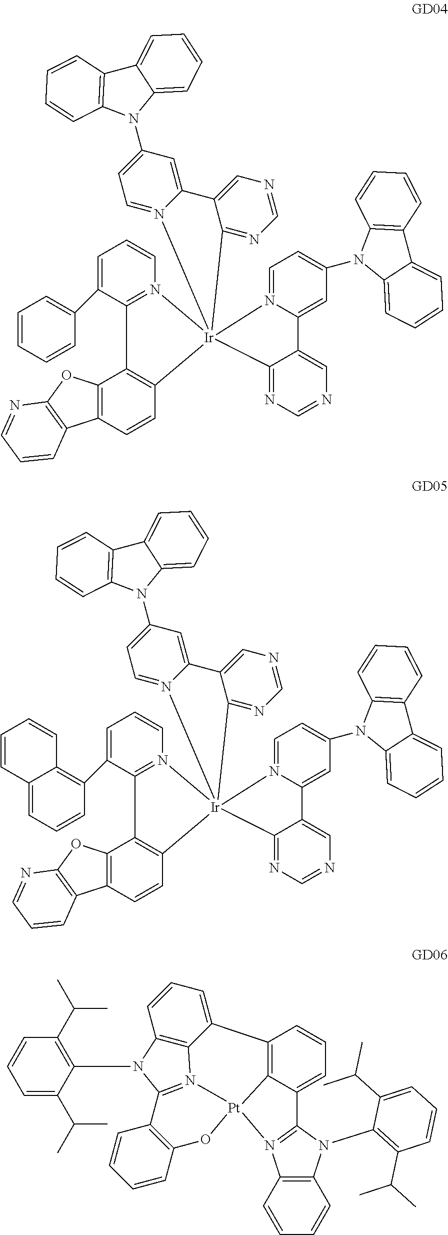

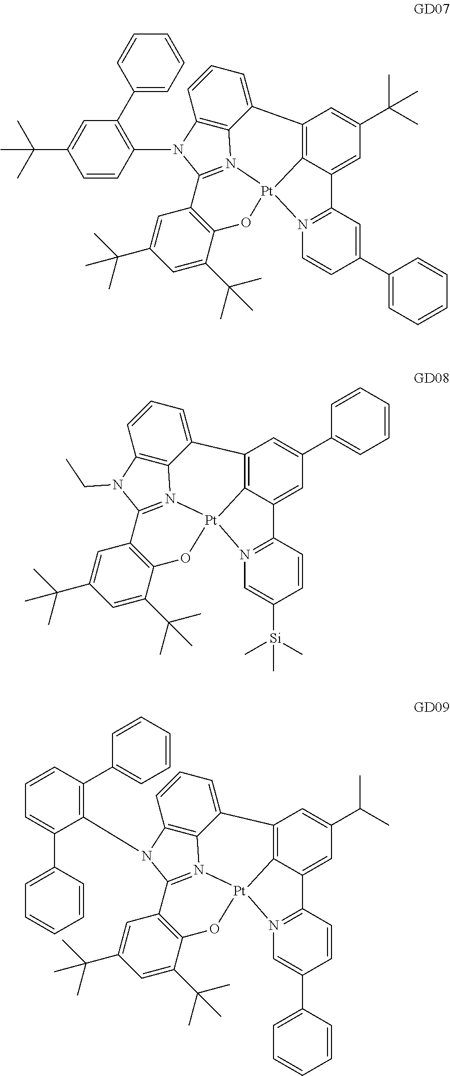

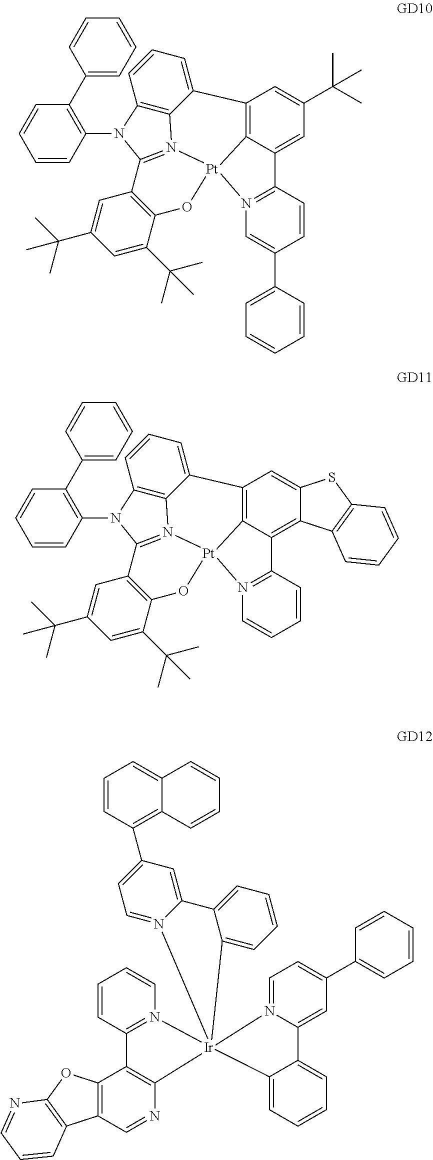

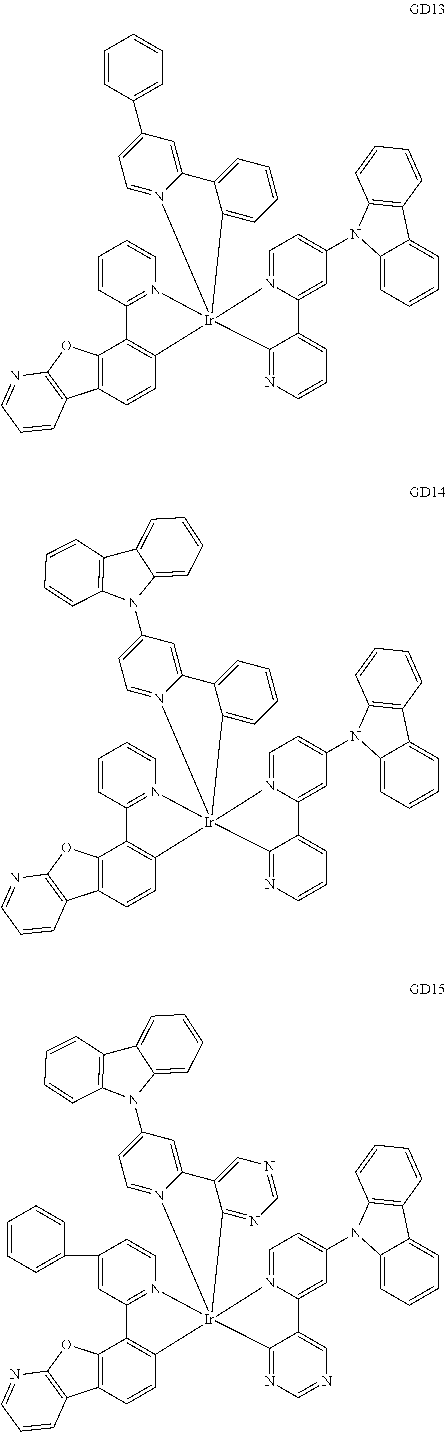

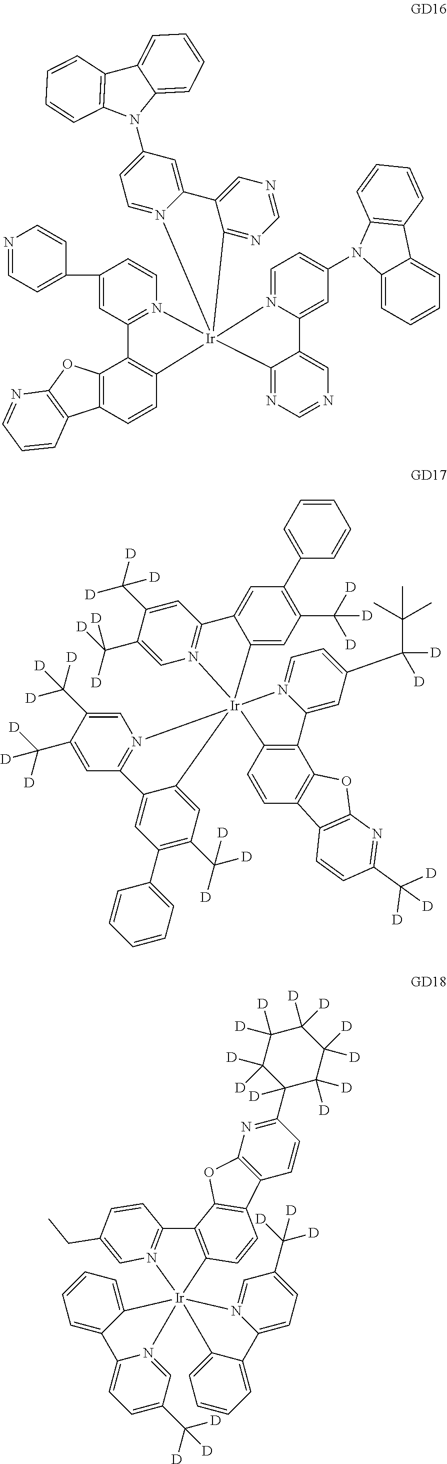

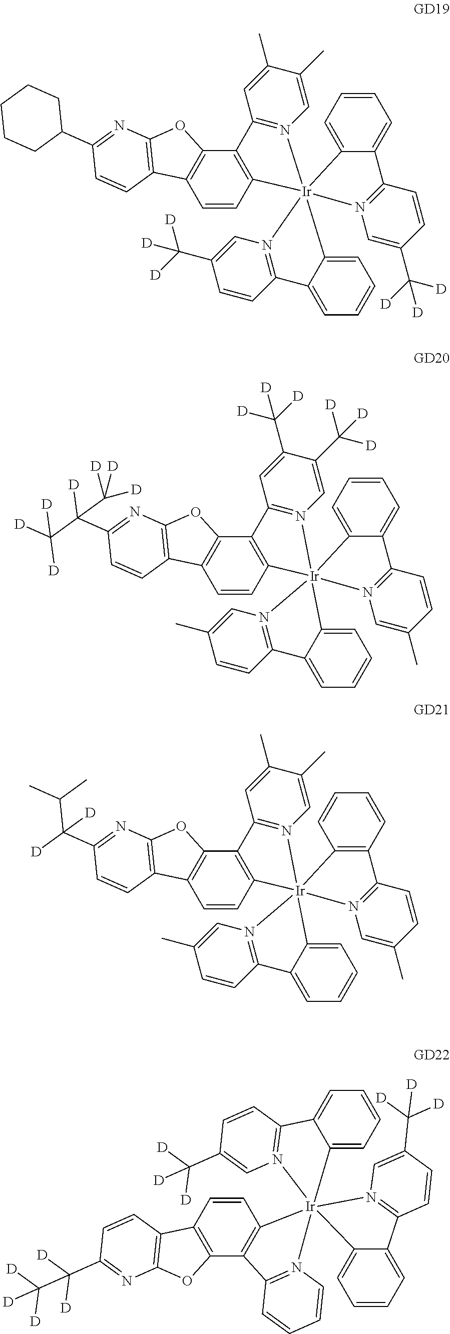

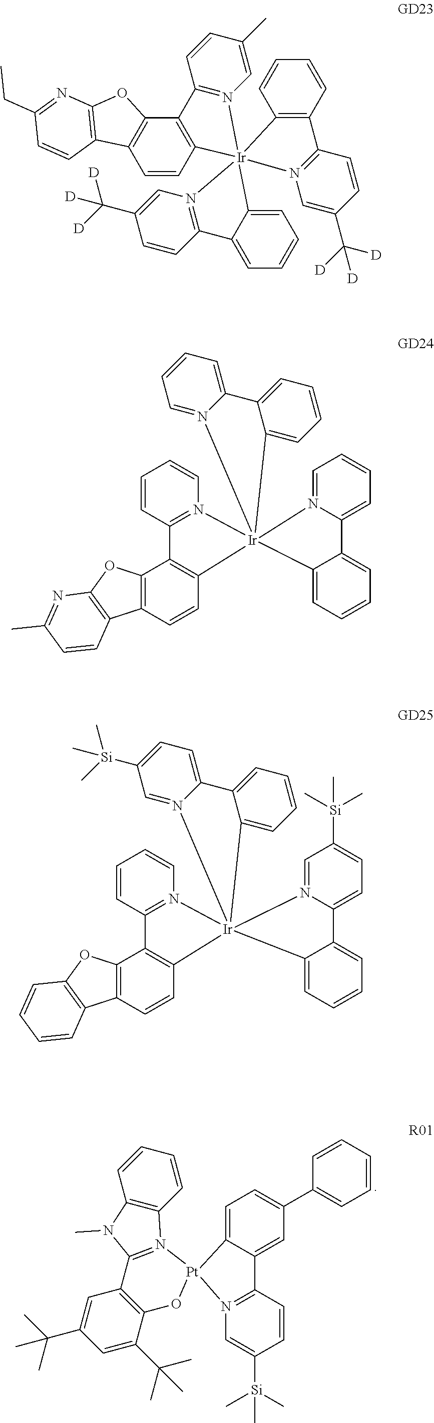

### Fluorescent Dopant

The emission layer may include a fluorescent dopant.

The fluorescent dopant may include an arylamine compound, a styrylamine compound, a boron-containing compound, or any combination thereof.

For example, the fluorescent dopant may include a compound represented by Formula 501:

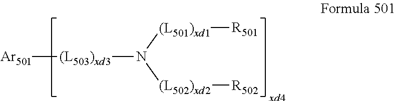

wherein in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, Ar₅₀₁ in Formula 501 may be a condensed cyclic group (for example, an anthracene group, a chrysene group, or a pyrene group) in which three or more monocyclic groups are condensed together.

In one or more embodiments, xd4 in Formula 501 may be 2.

For example, the fluorescent dopant may include: at least one (or be any one) selected from among Compounds FD1 to FD36; DPVBi; DPAVBi; or any combination thereof:

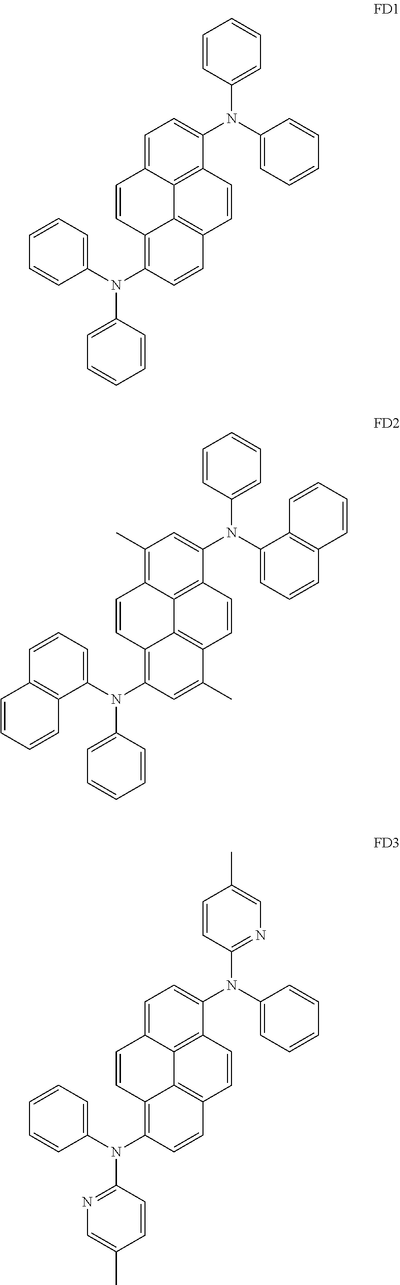 [SMILES: c1ccc(N(c2ccccc2)c2ccc3ccc4c(N(c5ccccc5)c5ccccc5)ccc5ccc2c3c54)cc1 ; Cc1cc(N(c2ccccc2)c2cccc3ccccc23)c2ccc3c(C)cc(N(c4ccccc4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

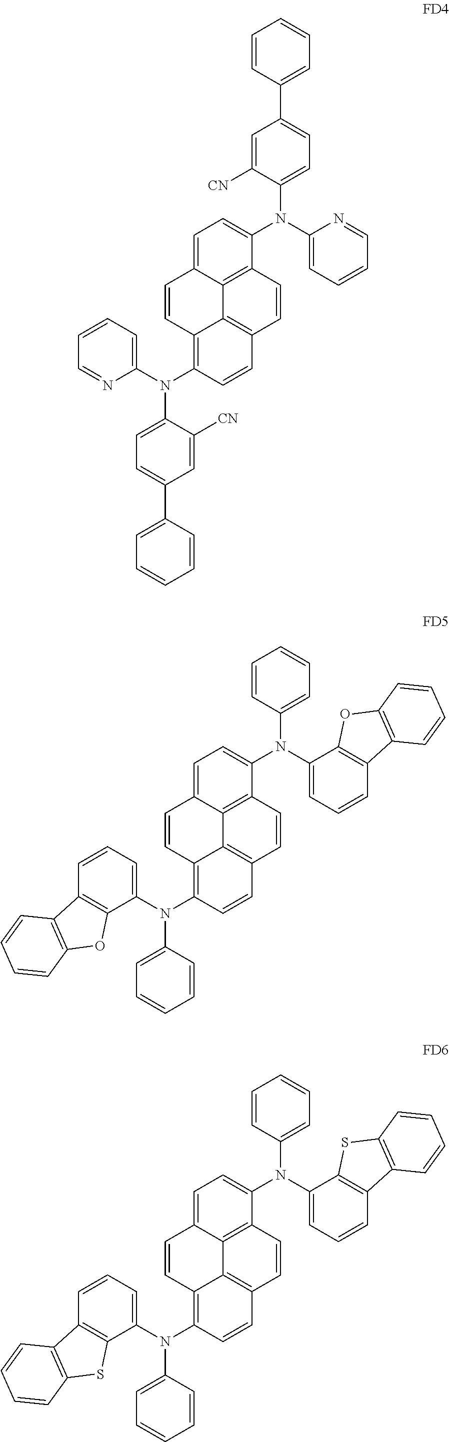

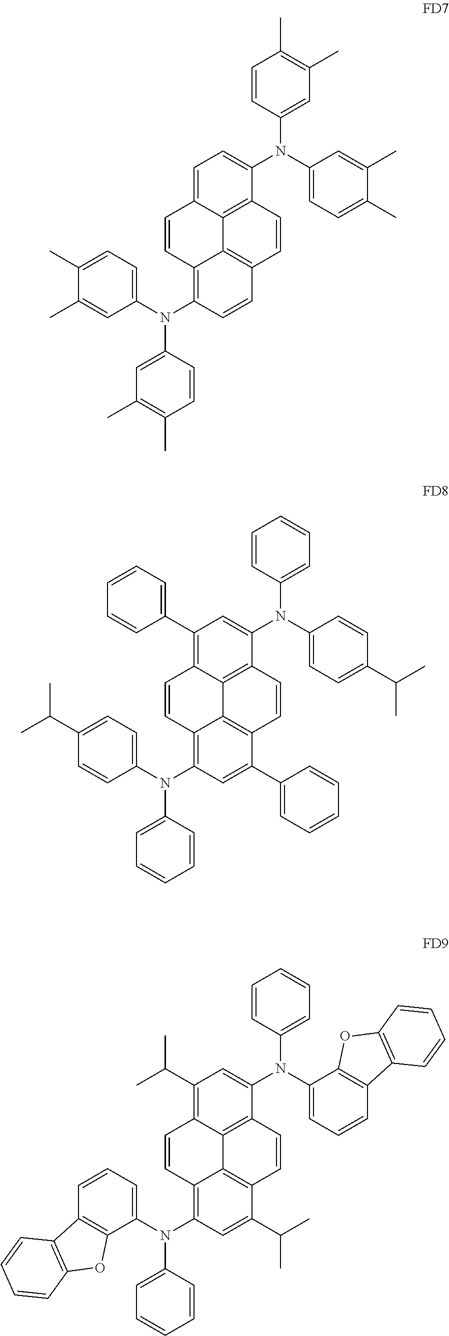

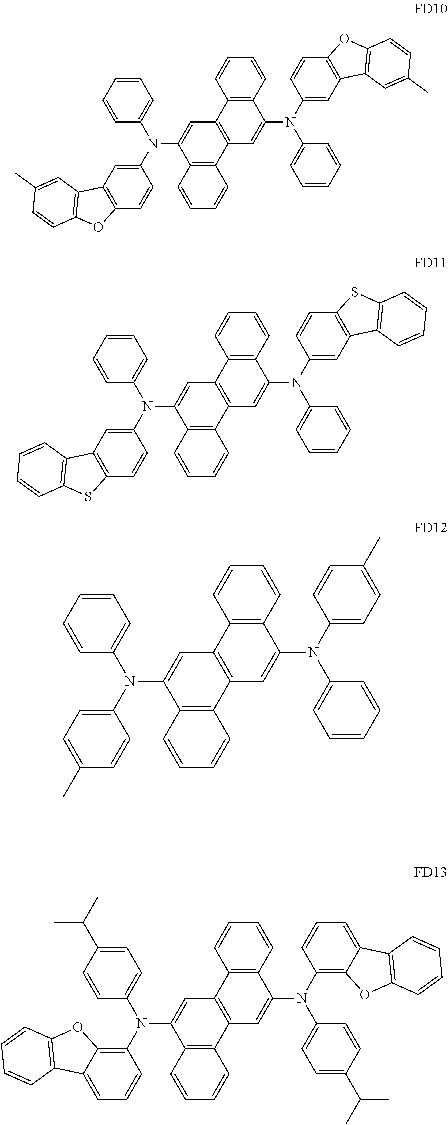

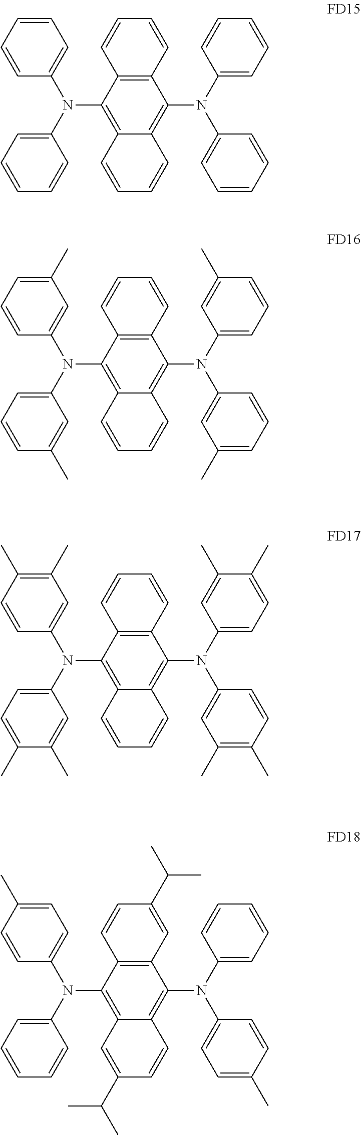 [SMILES: c1ccc(N(c2ccccc2)c2c3ccccc3c(N(c3ccccc3)c3ccccc3)c3ccccc23)cc1 ; Cc1cccc(N(c2cccc(C)c2)c2c3ccccc3c(N(c3cccc(C)c3)c3cccc(C)c3)c3ccccc23)c1 ; Cc1ccc(N(c2ccc(C)c(C)c2)c2c3ccccc3c(N(c3ccc(C)c(C)c3)c3ccc(C)c(C)c3)c3ccccc23)cc1C ; Cc1ccc(N(c2ccccc2)c2c3ccc(C(C)C)cc3c(N(c3ccccc3)c3ccc(C)cc3)c3ccc(C(C)C)cc23)cc1]

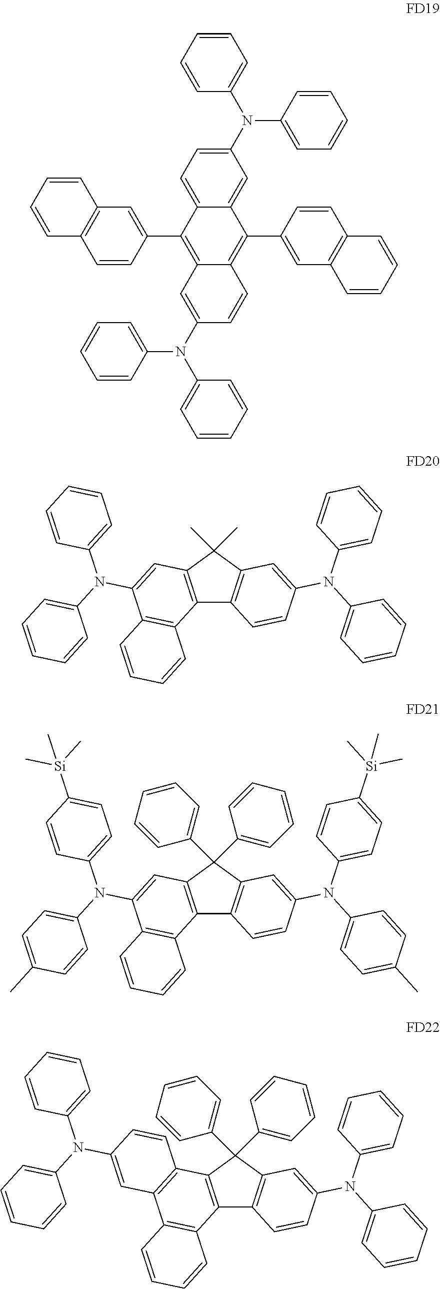

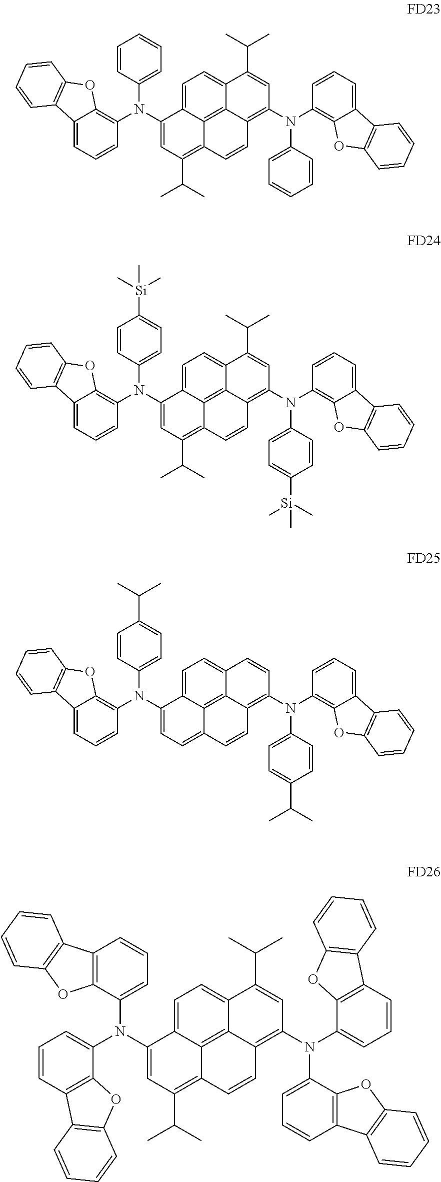 [SMILES: CC(C)c1cc(N(c2ccccc2)c2cccc3c2oc2ccccc23)c2ccc3c(C(C)C)cc(N(c4ccccc4)c4cccc5c4oc4ccccc45)c4ccc1c2c34 ; CC(C)c1cc(N(c2ccc([Si](C)(C)C)cc2)c2cccc3c2oc2ccccc23)c2ccc3c(C(C)C)cc(N(c4ccc([Si](C)(C)C)cc4)c4cccc5c4oc4ccccc45)c4ccc1c2c34 ; CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1 ; CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34]

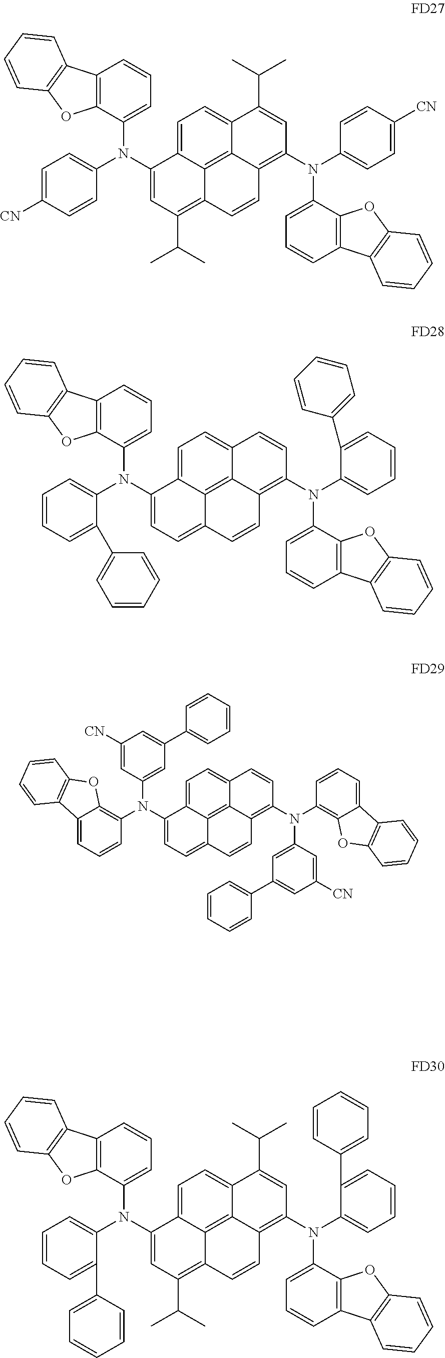

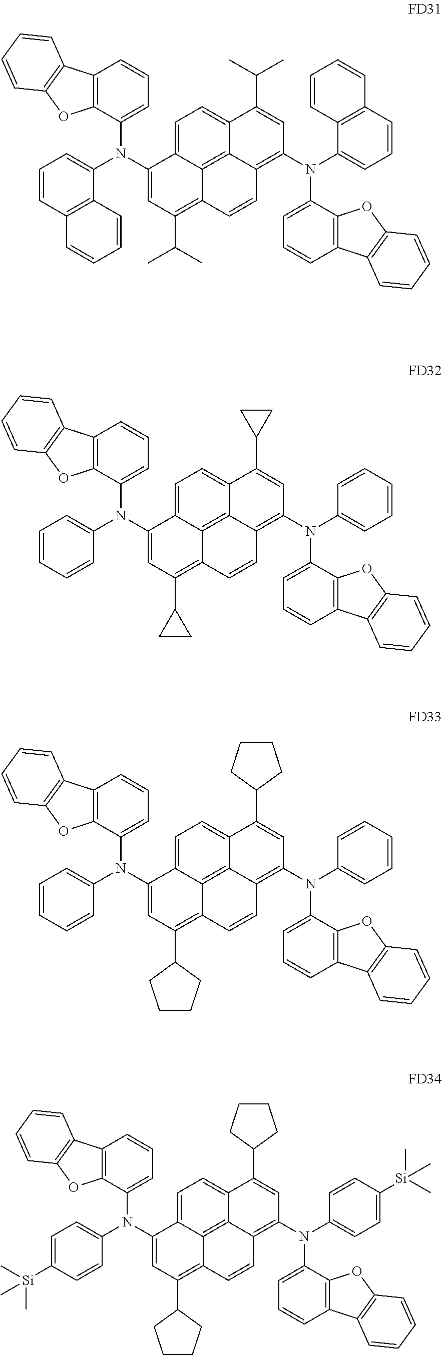

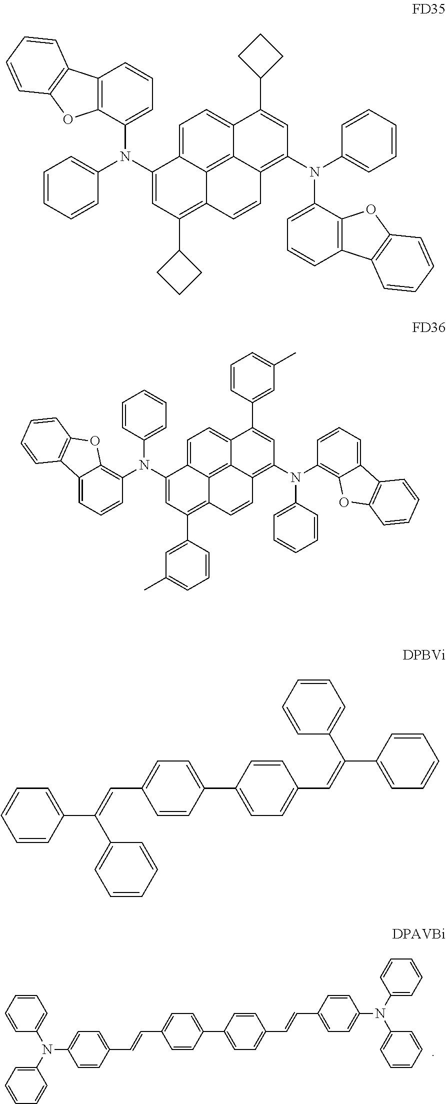

### Delayed Fluorescence Material

The emission layer may further include a delayed fluorescence material.

In the specification, the delayed fluorescence material may be any one selected from among compounds capable of emitting delayed fluorescent light based on a delayed fluorescence emission mechanism.

The delayed fluorescence material included in the emission layer may act as a host or a dopant depending on the type or kind of other materials included in the emission layer.

In one or more embodiments, the difference between the triplet energy (eV) of the delayed fluorescence material and the singlet energy level (eV) of the delayed fluorescence material may be greater than or equal to 0 eV and less than or equal to about 0.5 eV. When the difference between the triplet energy (eV) of the delayed fluorescence material and the singlet energy level (eV) of the delayed fluorescence material satisfies the above-described range, up-conversion from the triplet state to the singlet state of the delayed fluorescence materials may effectively occur, and thus, the luminescence efficiency of the light-emitting device 10 may be improved.

For example, the delayed fluorescence material may include i) a material including at least one electron donor (for example, a π electron-rich C₃-C₆₀ cyclic group, such as a carbazole group) and at least one electron acceptor (for example, a sulfoxide group, a cyano group, or a π electron-deficient nitrogen-containing C₁-C₆₀ heterocyclic group), and ii) a material including a C₈-C₆₀ polycyclic group in which two or more cyclic groups are condensed while sharing boron (B).

Examples of the delayed fluorescence material may include at least one selected from among Compounds DF1 to DF14:

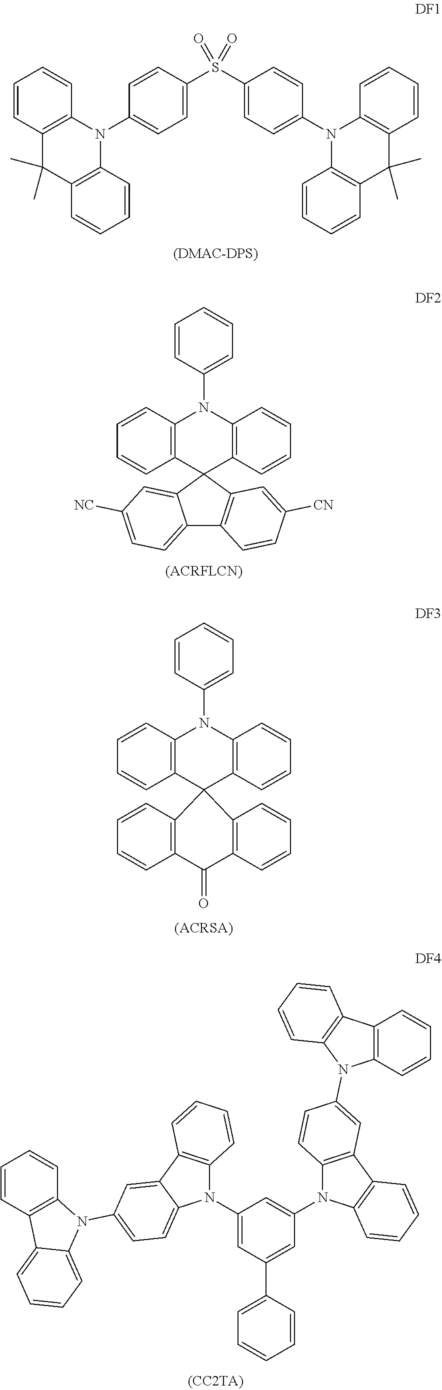

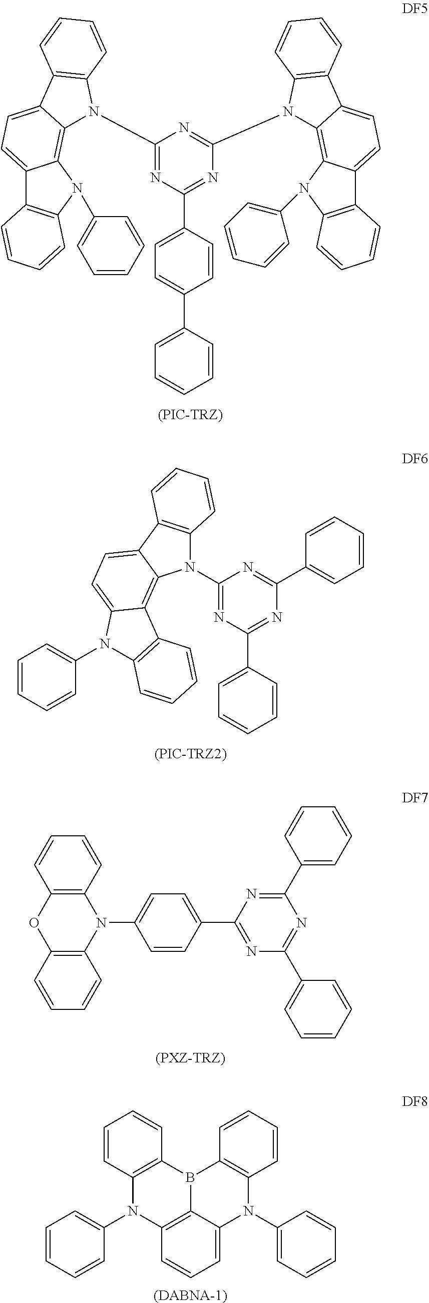

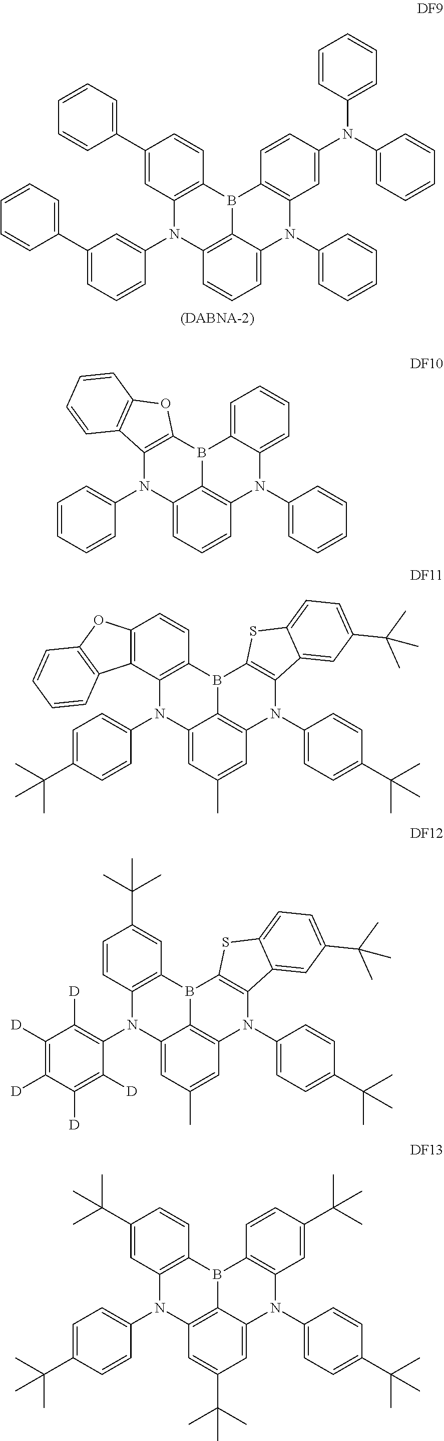

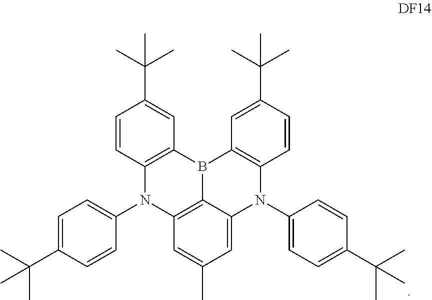 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### Electron Transport Region in Interlayer 130

The electron transport region may have: i) a single-layered structure including a single layer including a single material, ii) a single-layered structure including a single layer including a plurality of different materials, or iii) a multi-layered structure including a plurality of layers including different materials.

The electron transport region may include a buffer layer, a hole-blocking layer, an electron control layer, an electron transport layer, an electron injection layer, or any combination thereof.

For example, the electron transport region may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, the constituting layers of each structure being sequentially stacked from an emission layer.

In one or more embodiments, the electron transport region (for example, the buffer layer, the hole-blocking layer, the electron control layer, or the electron transport layer in the electron transport region) may include a metal-free compound including at least one π electron-deficient nitrogen-containing C₁-C₆₀ heterocyclic group.

For example, the electron transport region may include a compound represented by Formula 601:

[Ar₆₀₁]ₓₑ₁₁-[(L₆₀₁)ₓₑ₁-R₆₀₁]ₓₑ₂₁ Formula 601
wherein in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1,2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described herein with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ heterocyclic group unsubstituted or substituted with at least one R₁₀ₐ.

For example, if (e.g., when) xe11 in Formula 601 is 2 or more, two or more of Ar₆₀₁ may be linked to each other via a single bond.

In one or more embodiments, Ar₆₀₁ in Formula 601 may be an anthracene group unsubstituted or substituted with at least one R₁₀ₐ.

In one or more embodiments, the electron transport region may include a compound represented by Formula 601-1:

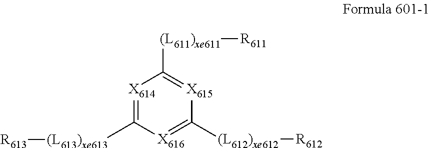

wherein in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each be the same as described herein with respect to L₆₀₁,

xe611 to xe613 may each be the same as described herein with respect to xe1,
R₆₁₁ to R₆₁₃ may each be the same as described herein with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region may include at least one selected from among Compounds ET1 to ET46, 2,9-dimethyl-4,7-diphenyl-1,10-phenanthroline (BCP), 4,7-diphenyl-1,10-phenanthroline (Bphen), Alq3, BAlq, TAZ, NTAZ, or any combination thereof:

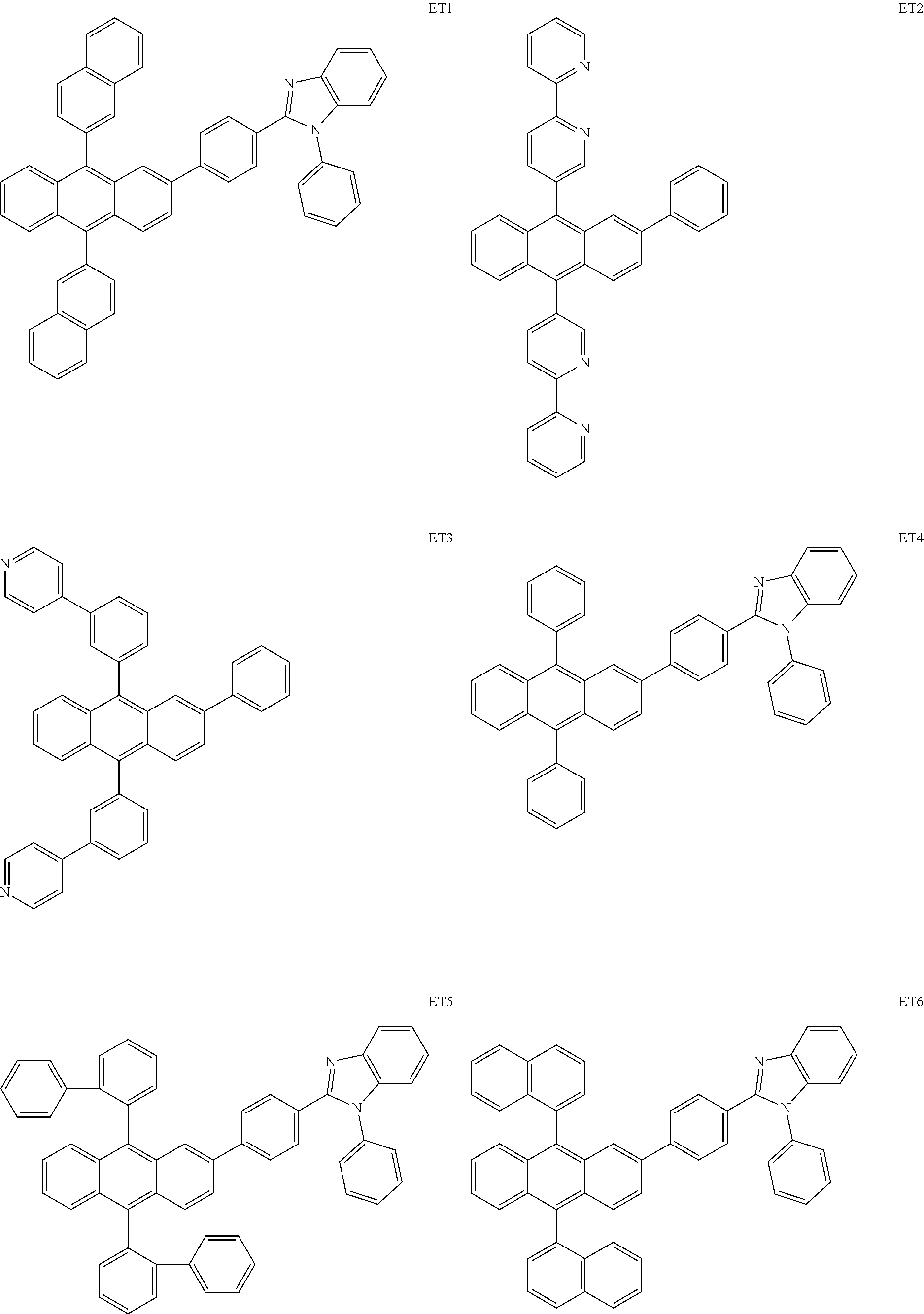

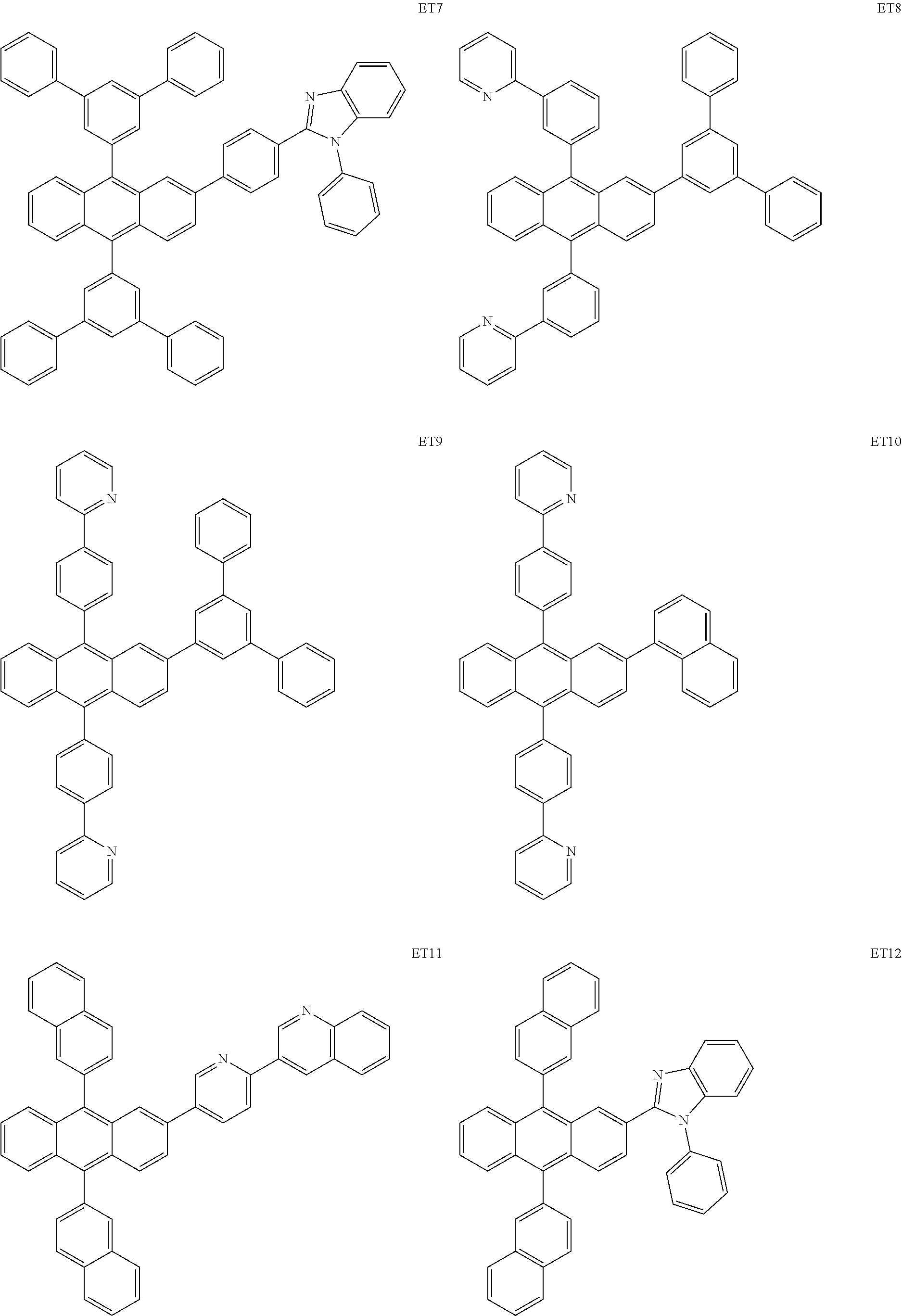

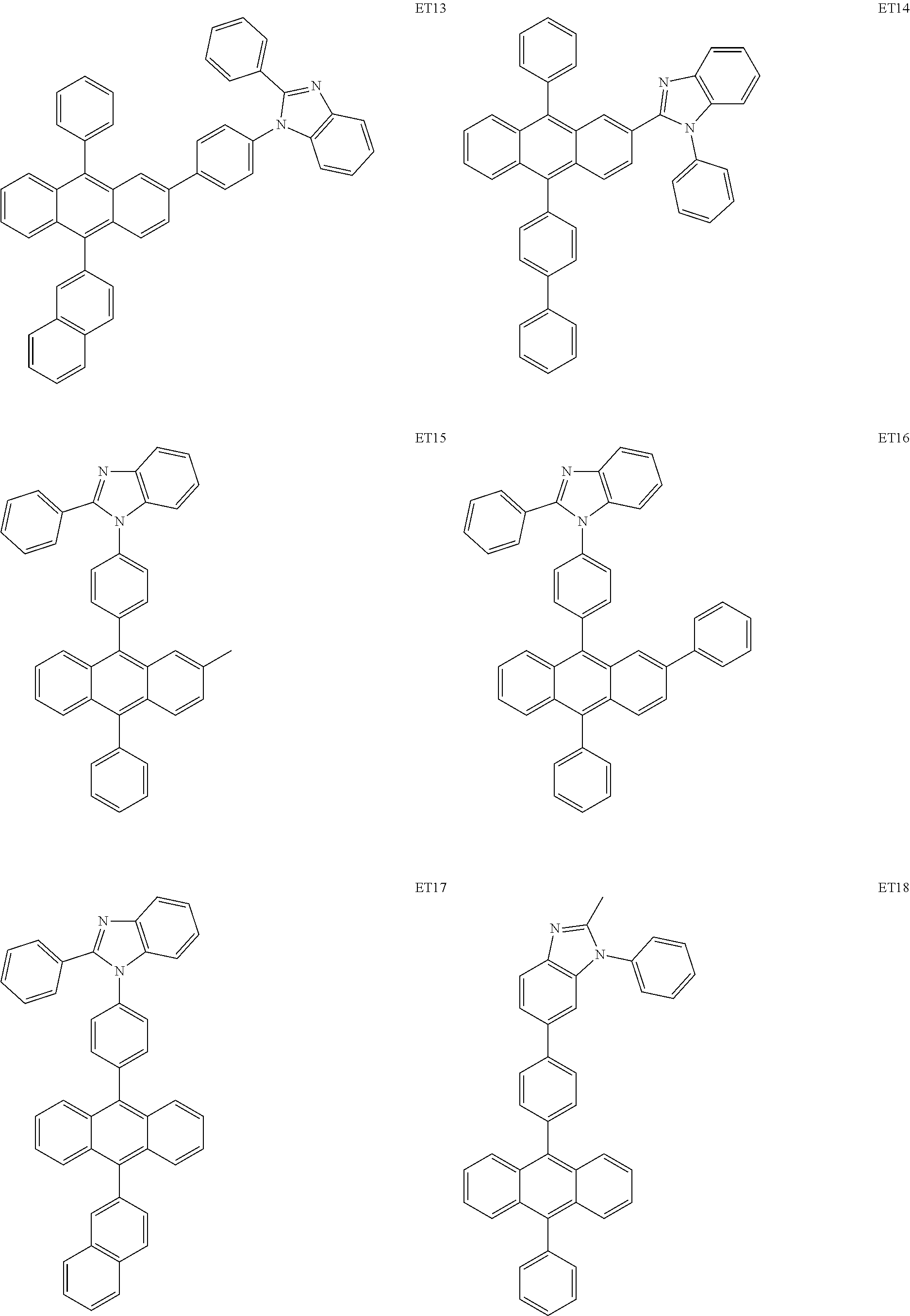 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

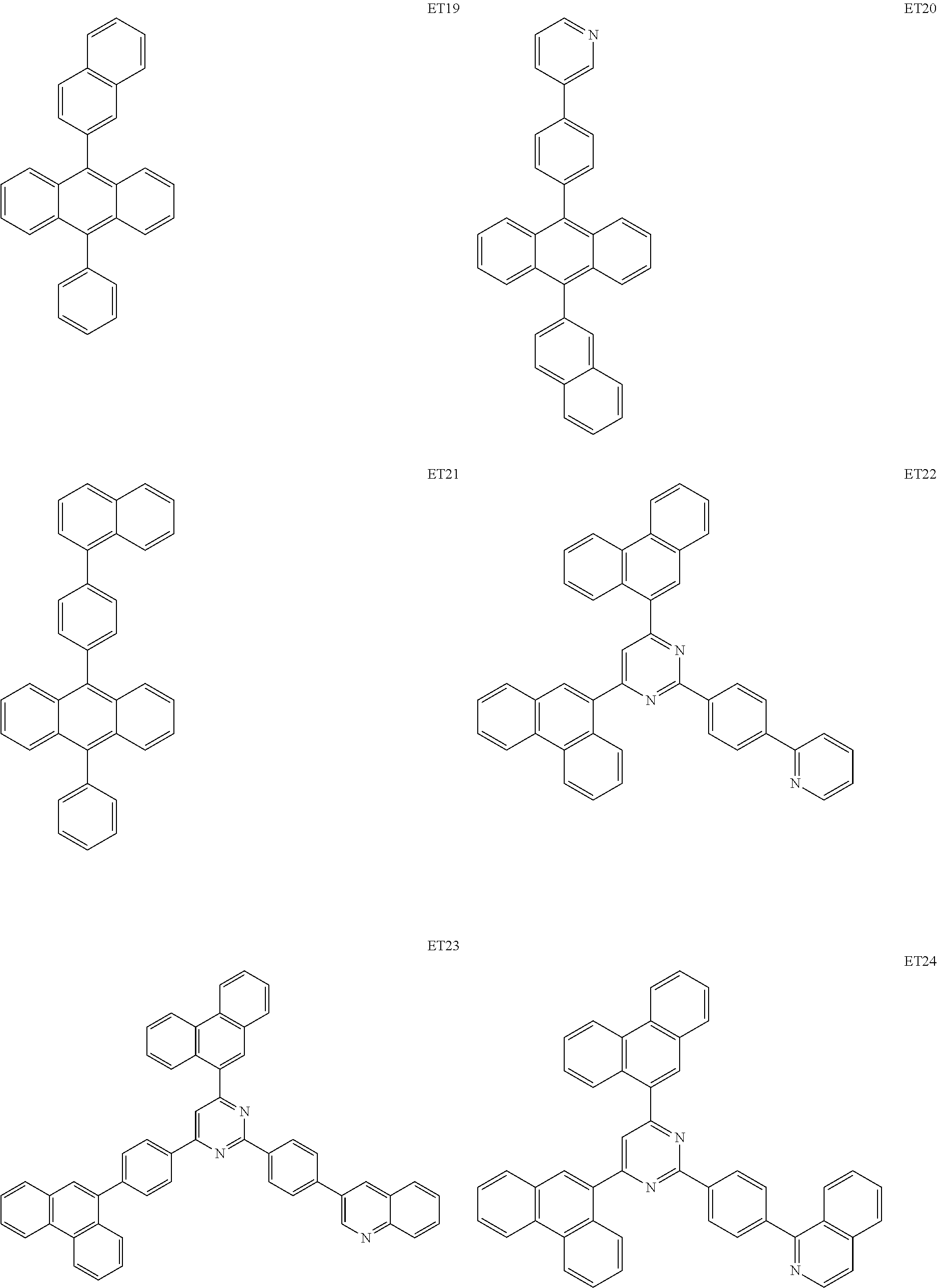

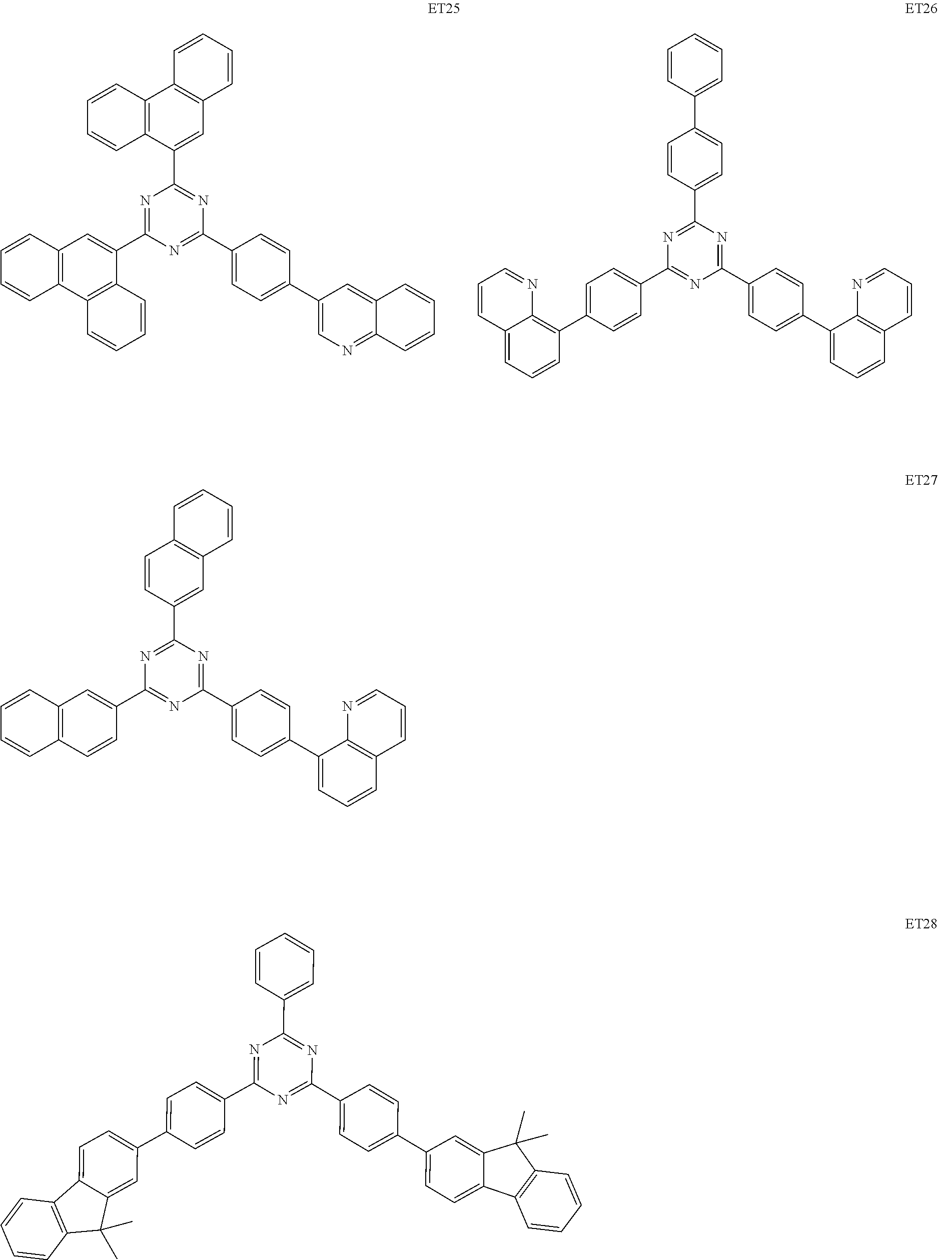

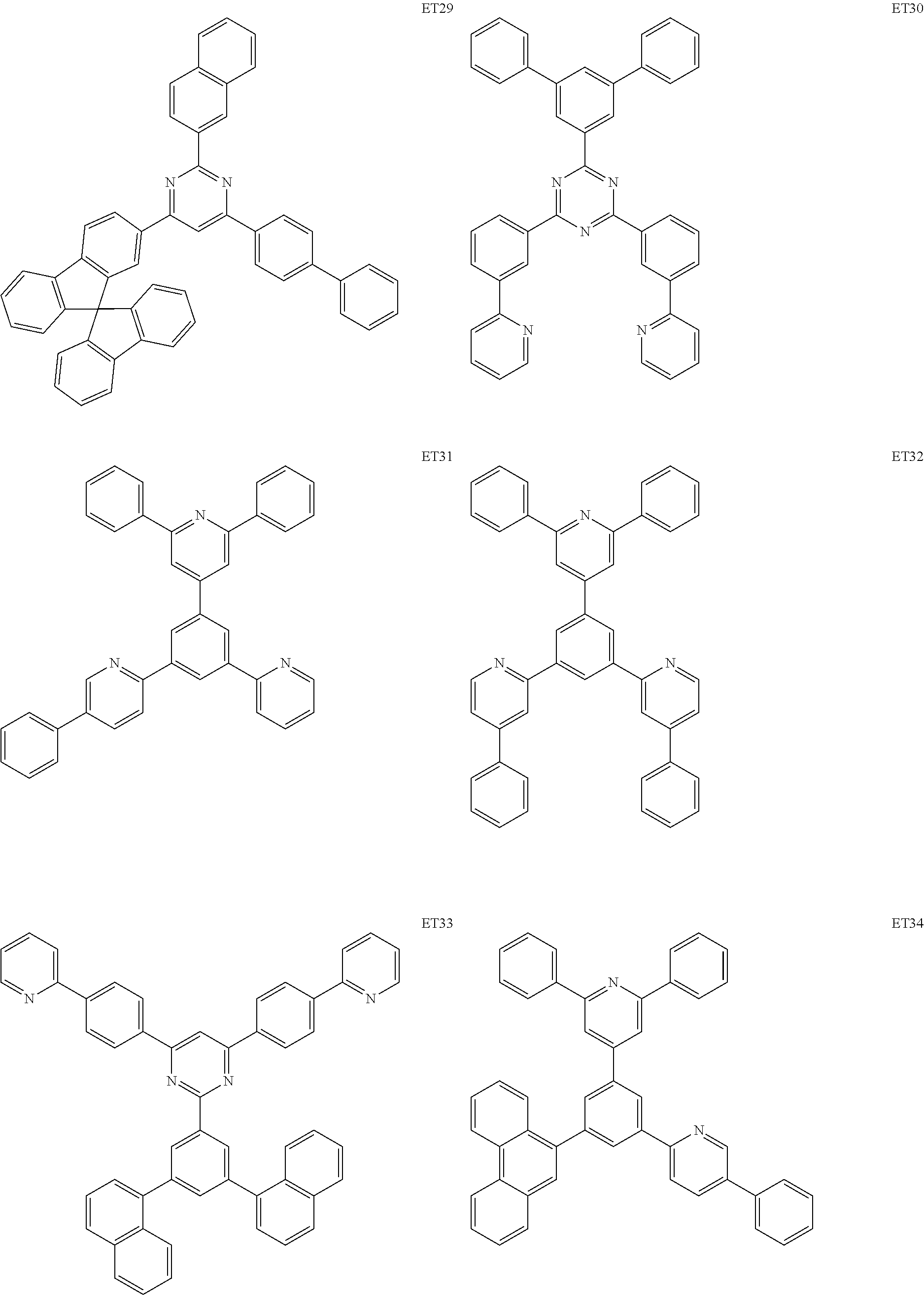

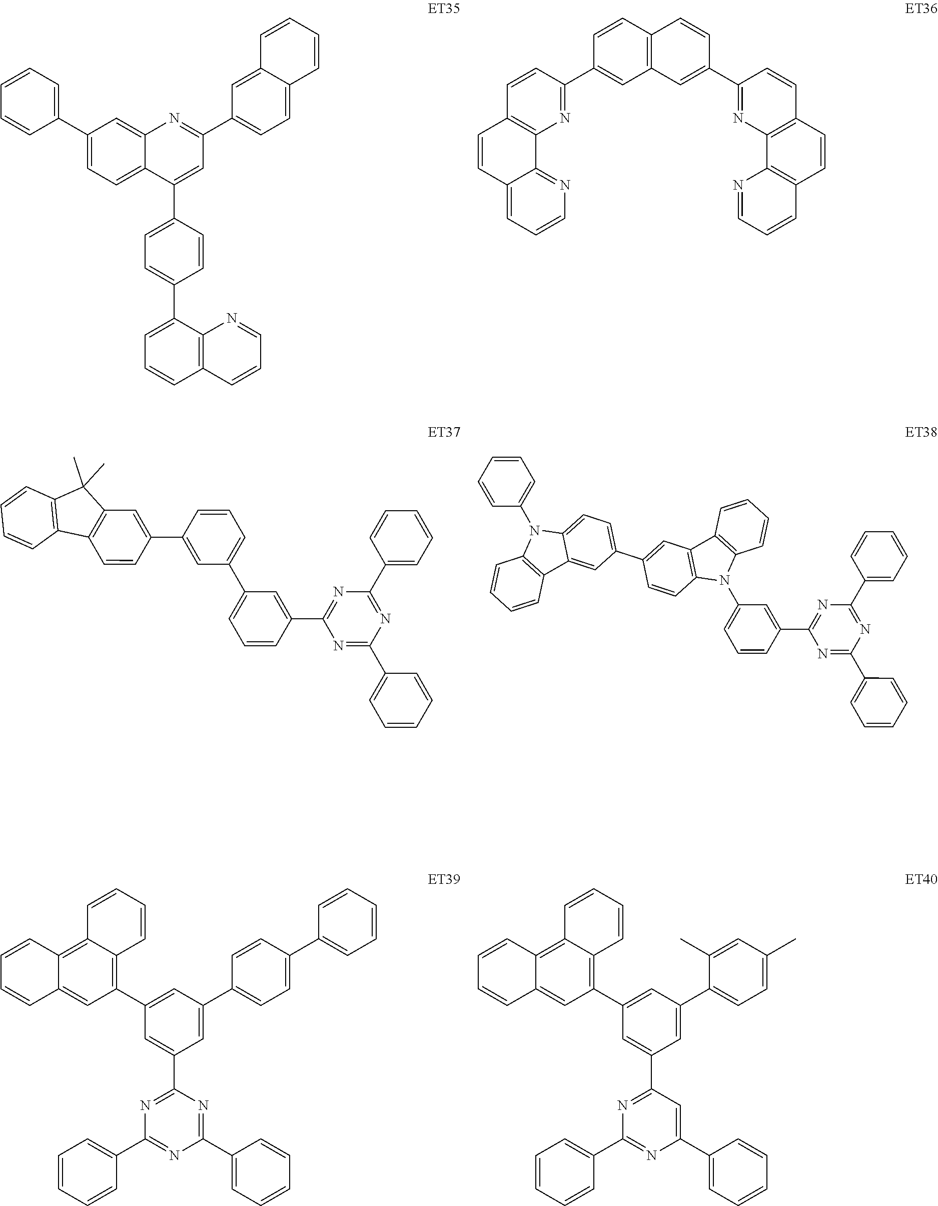 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

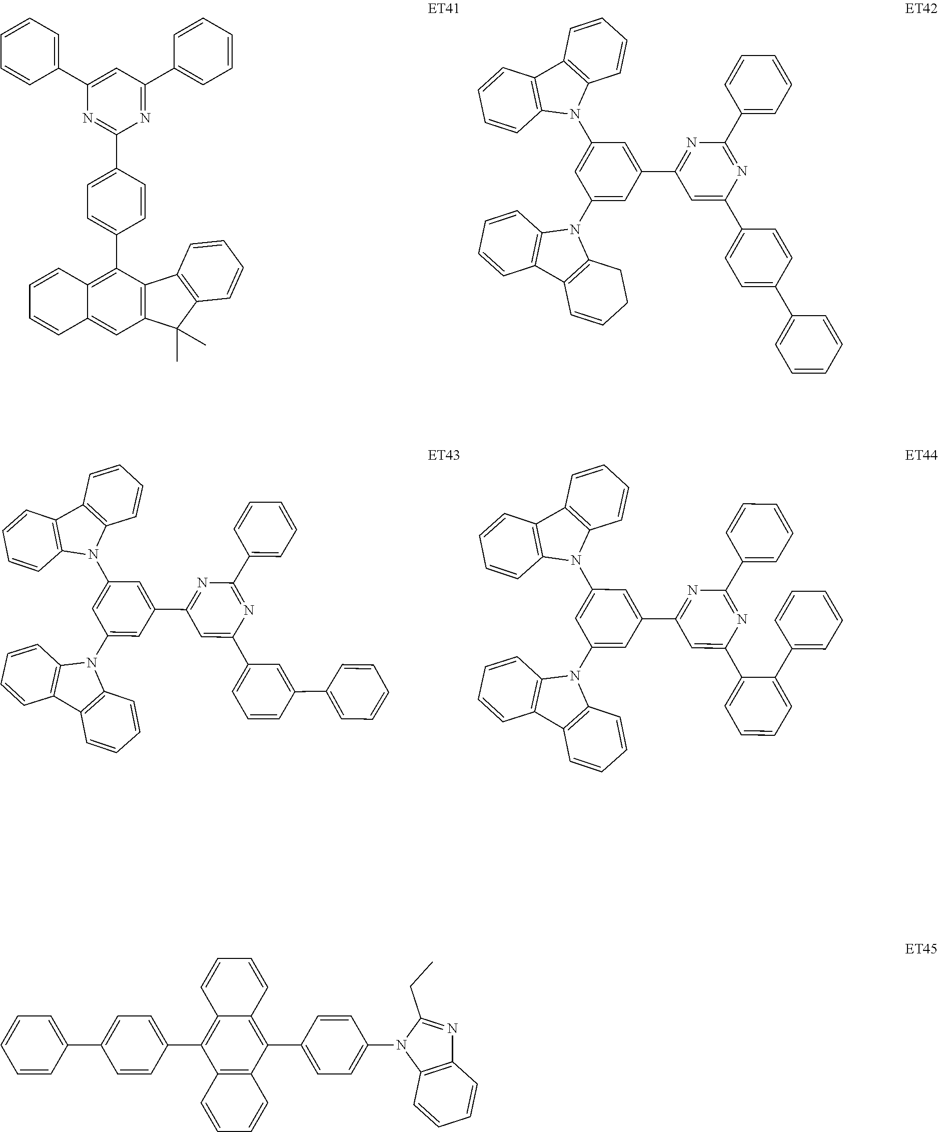 [SMILES: CC1(C)c2ccccc2-c2c1cc1ccccc1c2-c1ccc(-c2nc(-c3ccccc3)cc(-c3ccccc3)n2)cc1 ; C1=Cc2c(n(-c3cc(-c4cc(-c5ccc(-c6ccccc6)cc5)nc(-c5ccccc5)n4)cc(-n4c5ccccc5c5ccccc54)c3)c3ccccc23)CC1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

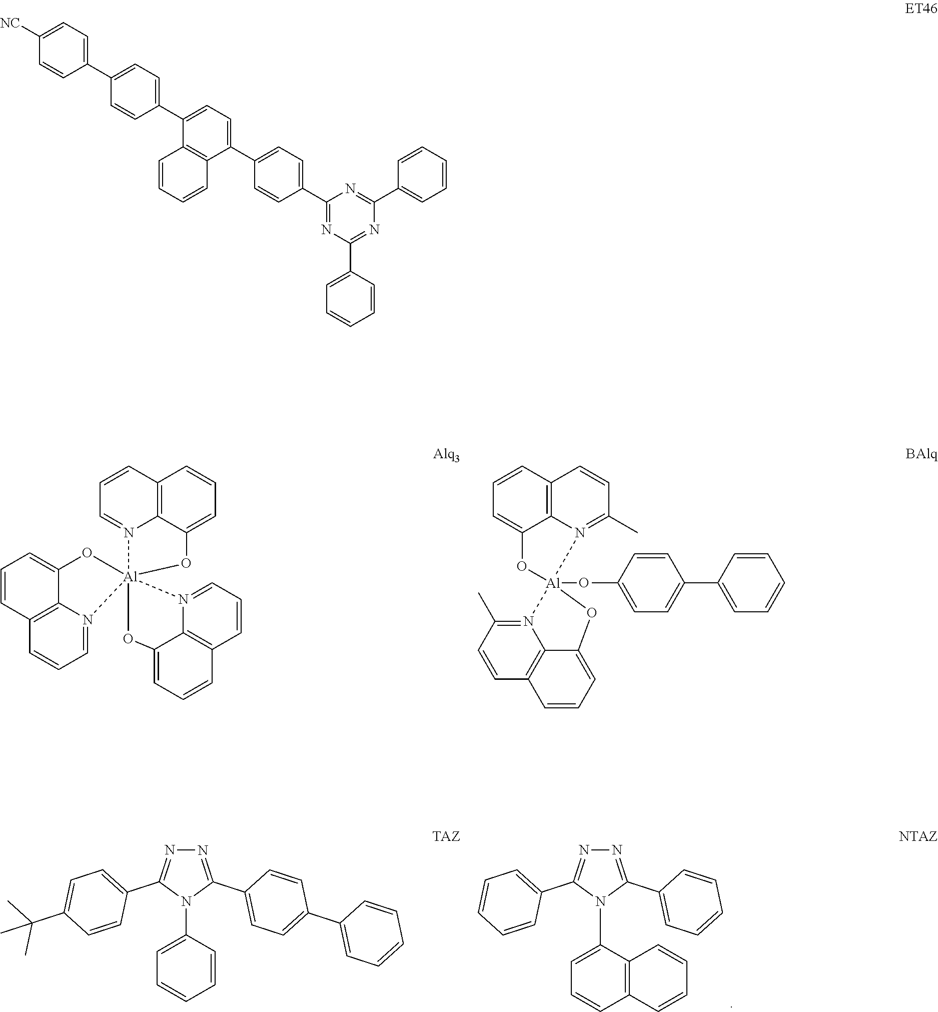

A thickness of the electron transport region may be from about 100 Å to about 5,000 Å, for example, about 160 Å to about 4,000 Å. When the electron transport region includes a buffer layer, a hole-blocking layer, an electron control layer, an electron transport layer, or any combination thereof, the thickness of the buffer layer, the hole-blocking layer, or the electron control layer may each independently be from about 20 Å to about 1,000 Å, for example, about 30 Å to about 300 Å, and the thickness of the electron transport layer may be from about 100 Å to about 1,000 Å, for example, about 150 Å to about 500 Å. When the thickness of the buffer layer, the hole-blocking layer, the electron control layer, the electron transport layer, and/or the electron transport region are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (Liq) or ET-D2:

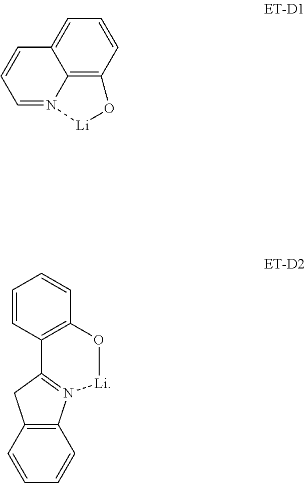

The electron transport region may include an electron injection layer that facilitates the injection of electrons from the second electrode 150. The electron injection layer may directly contact the second electrode 150.

The electron injection layer may have: i) a single-layered structure including a single layer including a single material, ii) a single-layered structure including a single layer including a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, or iodides), or tellurides of the alkali metal, the alkaline earth metal, and the rare earth metal, or any combination thereof.

The alkali metal-containing compound may include: alkali metal oxides, such as Li₂O, Cs₂O, or K₂O; alkali metal halides, such as LiF, NaF, CsF, KF, LiI, NaI, CsI, KI, or RbI; or any combination thereof. The alkaline earth metal-containing compound may include an alkaline earth metal oxide, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include lanthanide metal telluride. Examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one selected from among metal ions of the alkali metal, the alkaline earth metal, and the rare earth metal and ii), as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may include: i) an alkali metal-containing compound (for example, an alkali metal halide); or ii) a) an alkali metal-containing compound (for example, an alkali metal halide), and b) an alkali metal, an alkaline earth metal, a rare earth metal, or any combination thereof. For example, the electron injection layer may be a KI:Yb co-deposited layer, an RbI:Yb co-deposited layer, a LiF:Yb co-deposited layer, and/or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly (e.g., substantially uniformly) or non-uniformly (e.g., substantially non-uniformly) dispersed in a matrix including the organic material.

A thickness of the electron injection layer may be in a range of about 1 Å to about 100 Å, for example, about 3 Å to about 90 Å. When the thickness of the electron injection layer is within the ranges described above, satisfactory electron injection characteristics may be obtained without a substantial increase in driving voltage.

### Second Electrode 150

The second electrode 150 may be located on the interlayer 130 having a structure as described above. The second electrode 150 may be a cathode, which is an electron injection electrode, and as the material for the second electrode 150, a metal, an alloy, an electrically conductive compound, or any combination thereof, each having a low-work function, may be utilized.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure including a single layer or a multi-layered structure including a plurality of layers.

### Second Capping Layer 170

The second capping layer 170 may include the first capping material as described in the specification. The detailed description of the first capping material is the same as described in the specification.

### Electronic Apparatus

The light-emitting device may be included in one or more suitable electronic apparatuses. For example, the electronic apparatus including the light-emitting device may be a light-emitting apparatus, an authentication apparatus, and/or the like.

The electronic apparatus (for example, a light-emitting apparatus) may further include, in addition to the light-emitting device, i) a color filter, ii) a color conversion layer, or iii) a color filter and a color conversion layer. The color filter and/or the color conversion layer may be located in at least one direction in which light emitted from the light-emitting device travels. For example, the light emitted from the light-emitting device may be blue light, green light, or white light. For details on the light-emitting device, related description provided above may be referred to. In one or more embodiments, the color conversion layer may include a quantum dot.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be located among the subpixel areas to define each of the subpixel areas.

The color filter may further include a plurality of color filter areas and light-shielding patterns located among the color filter areas, and the color conversion layer may further include a plurality of color conversion areas and light-shielding patterns located among the color conversion areas.

The plurality of color filter areas (or the plurality of color conversion areas) may include a first area configured to emit a first color light, a second area configured to emit a second color light, and/or a third area configured to emit a third color light, wherein the first color light, the second color light, and/or the third color light may have different maximum emission wavelengths from one another. For example, the first color light may be red light, the second color light may be green light, and the third color light may be blue light. For example, the plurality of color filter areas (or the plurality of color conversion areas) may include quantum dots. In particular, the first area may include a red quantum dot, the second area may include a green quantum dot, and the third area may not include (e.g., may exclude) a quantum dot. For details on the quantum dot, related descriptions provided herein may be referred to. The first area, the second area, and/or the third area may each include a scatter.

For example, the light-emitting device may be configured to emit a first light, the first area may be configured to absorb the first light to emit first-first color light, the second area may be configured to absorb the first light to emit second-first color light, and the third area may be configured to absorb the first light to emit third-first color light. In this regard, the first-first color light, the second-first color light, and the third-first color light may have different maximum emission wavelengths. In particular, the first light may be blue light, the first-first color light may be red light, the second-first color light may be green light, and the third-first color light may be blue light.

The electronic apparatus may further include a thin-film transistor, in addition to the light-emitting device as described above. The thin-film transistor may include a source electrode, a drain electrode, and an activation layer, wherein any one selected from among the source electrode and the drain electrode may be electrically connected to any one selected from among the first electrode and the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion for sealing the light-emitting device. The sealing portion may be located between the color filter and/or the color conversion layer and the light-emitting device. The sealing portion allows light from the light-emitting device to be extracted to the outside, and concurrently (e.g., simultaneously) prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally located on the sealing portion, in addition to the color filter and/or the color conversion layer, according to the utilize of the electronic apparatus. Examples of the functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus that authenticates an individual by utilizing biometric information of a living body (for example, fingertips, pupils, and/or the like).

The authentication apparatus may further include, in addition to the light-emitting device as described above, a biometric information collector.

The electronic apparatus may be applied to one or more suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

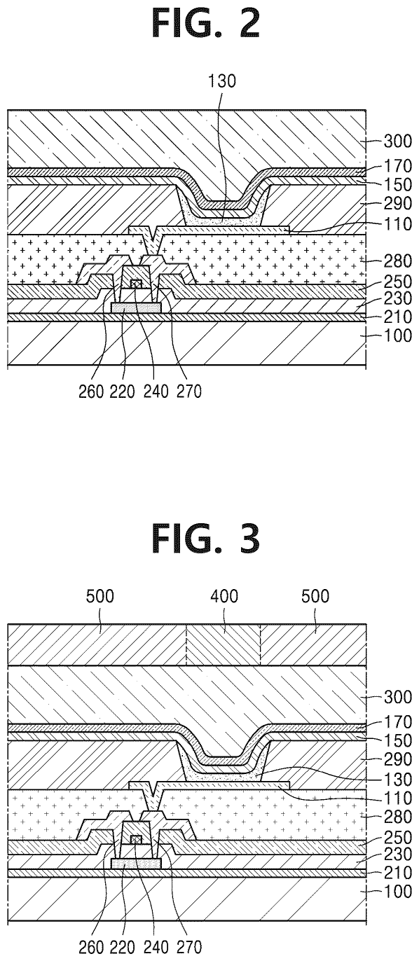

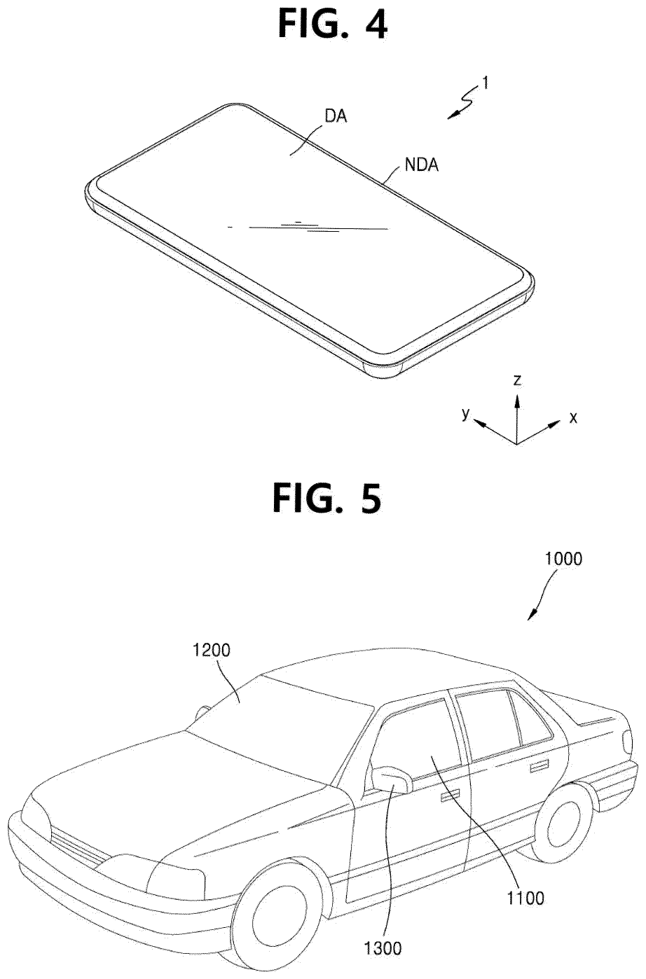

### Description of FIGS. 2 and 3

FIG. 2 is a cross-sectional view showing a light-emitting apparatus as an example of the electronic apparatus according to one or more embodiments.

The light-emitting apparatus of FIG. 2 includes a substrate 100, a thin-film transistor (TFT), a light-emitting device, and a sealing portion 300 that seals the light-emitting device.

The substrate 100 may be a flexible substrate, a glass substrate, or a metal substrate. A buffer layer 210 may be located on the substrate 100. The buffer layer 210 may prevent or reduce penetration of impurities through the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 may be located between the gate electrode 240 and the source electrode 260 and between the gate electrode 240 and the drain electrode 270, to insulate from one another.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be located in contact with the exposed portions of the source region and the drain region of the activation layer 220.

The TFT is electrically connected to a light-emitting device to drive the light-emitting device, and is covered and protected by a passivation layer 280. The passivation layer 280 may include an inorganic insulating film, an organic insulating film, or any combination thereof. A light-emitting device is provided on the passivation layer 280. The light-emitting device may include a first electrode 110, an interlayer 130, and a second electrode 150.

The first electrode 110 may be located on the passivation layer 280. The passivation layer 280 may be located to expose a portion of the drain electrode 270, not fully covering the drain electrode 270, and the first electrode 110 may be located to be connected to the exposed portion of the drain electrode 270.

A pixel defining layer 290 including an insulating material may be located on the first electrode 110. The pixel defining layer 290 may expose a certain region of the first electrode 110, and an interlayer 130 may be formed in the exposed region of the first electrode 110. The pixel defining layer 290 may be a polyimide or polyacrylic organic film. In one or more embodiments, at least some layers of the interlayer 130 may extend beyond the upper portion of the pixel defining layer 290 to be located in the form of a common layer.

A second electrode 150 may be located on the interlayer 130, and a second capping layer 170 may be additionally formed on the second electrode 150. The second capping layer 170 may be formed to cover the second electrode 150.

The sealing portion 300 may be located on the second capping layer 170. The sealing portion 300 may be located on a light-emitting device to protect the light-emitting device from moisture or oxygen. The sealing portion 300 may include: an inorganic film including silicon nitride (SiNx) (e.g., Si₃N₄),silicon oxide (SiOx) (e.g., SiO₂), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or any combination thereof; or any combination of the inorganic films and the organic films.

FIG. 3 is a schematic cross-sectional view of a light-emitting apparatus as an example of the electronic apparatus according to one or more embodiments.

The light-emitting apparatus of FIG. 3 is the same as the light-emitting apparatus of FIG. 2, except that a light-shielding pattern 500 and a functional region 400 are additionally located on the sealing portion 300. The functional region 400 may be i) a color filter area, ii) a color conversion area, or iii) a combination of the color filter area and the color conversion area. In one or more embodiments, the light-emitting device included in the light-emitting apparatus of FIG. 3 may be a tandem light-emitting device.

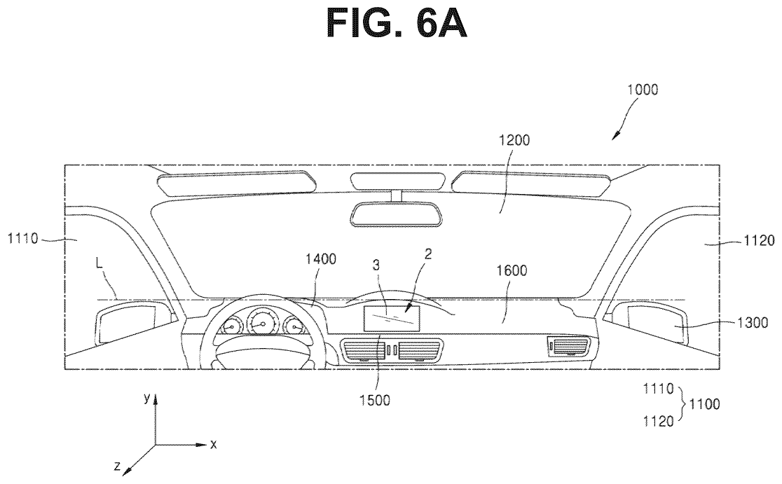

### Description of FIG. 4

FIG. 4 is a schematic perspective view of electronic equipment 1 including a light-emitting device according to one or more embodiments. The electronic equipment 1 may be, as a device apparatus that displays a moving image or still image, a portable electronic equipment, such as a mobile phone, a smart phone, a tablet personal computer (PC), a mobile communication terminal, an electronic notebook, an electronic book, a portable multimedia player (PMP), a navigation, or a ultra-mobile PC (UMPC), as well as one or more suitable products, such as a television, a laptop, a monitor, a billboards, or an Internet of things (IoT) device. The electronic equipment 1 may be such a product above or a part thereof. In addition, the electronic equipment 1 may be a wearable device, such as a smart watch, a watch phone, a glasses-type or kind display, or a head mounted display (HMD), or a part of the wearable device. However, one or more embodiments of the disclosure are not limited thereto. For example, the electronic equipment 1 may be a center information display (CID) on an instrument panel and a center fascia or dashboard of a vehicle, a room mirror display instead of a side mirror of a vehicle, an entertainment display for the rear seat of a car or a display placed on the back of the front seat, head up display (HUD) installed in front of a vehicle or projected on a front window glass, or a computer generated hologram augmented reality head up display (CGH AR HUD). FIG. 4 illustrates a case in which the electronic equipment 1 is a smartphone for convenience of explanation.

The electronic equipment 1 may include a display area DA and a non-display area NDA outside the display area DA. A display device may implement an image through an array of a plurality of pixels that are two-dimensionally arranged in the display area DA.

The non-display area NDA is an area that does not display an image, and may entirely be around (e.g., surround) the display area DA. On the non-display area NDA, a driver for providing electrical signals or power to display devices arranged on the display area DA may be arranged. On the non-display area NDA, a pad, which is an area to which an electronic element or a printing circuit board may be electrically connected, may be arranged.

In the electronic equipment 1, a length in the x-axis direction and a length in the y-axis direction may be different from each other. For example, as shown in FIG. 4, the length in the x-axis direction may be shorter than the length in the y-axis direction. In one or more embodiments, the length in the x-axis direction may be the same as the length in the y-axis direction. In one or more embodiments, the length in the x-axis direction may be longer than the length in the y-axis direction.

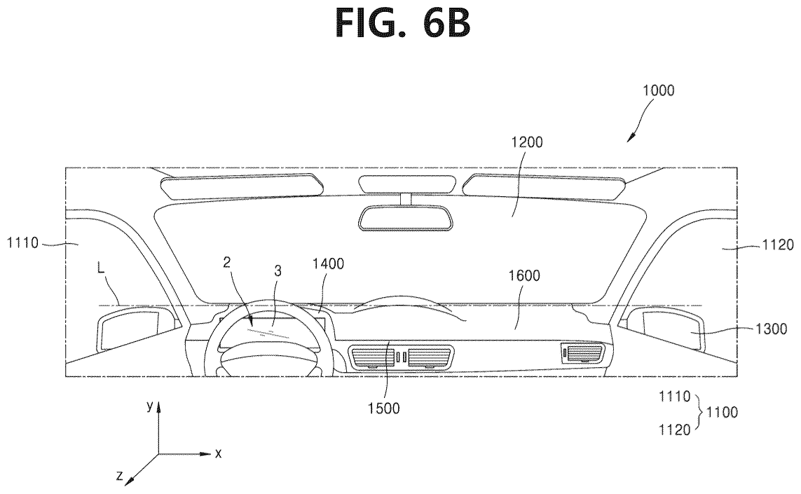

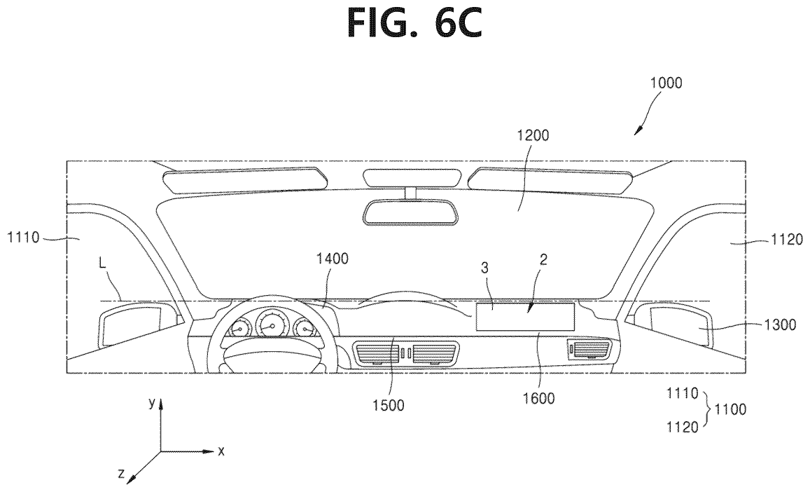

### Descriptions of FIGS. 5 and 6A to 6C

FIG. 5 is a diagram illustrating the exterior of a vehicle 1000 as electronic equipment including a light-emitting device according to one or more embodiments. FIGS. 6A to 6C are each a diagram schematically illustrating the interior of a vehicle 1000 according to one or more suitable embodiments of the disclosure.

Referring to FIGS. 5, 6A, 6B, and 6C, the vehicle 1000 may refer to one or more suitable apparatuses for moving a subject object to be transported, such as a human, an object, or an animal, from a departure point to a destination. The vehicle 1000 may include a vehicle traveling on a road or track, a vessel moving over a sea or river, an airplane flying in the sky utilizing the action of air, and/or the like.

The vehicle 1000 may travel on a road or a track. The vehicle 1000 may move in a set or predetermined direction according to the rotation of at least one wheel. For example, the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses necessary for driving are installed as other parts except for the body. The exterior of the vehicle body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in the x-direction or the −x-direction. For example, the first side window glass 1110 and the second side window glass 1120 may be spaced and/or apart (e.g., spaced apart or separated) from each other in the x direction or the −x direction. For example, an imaginary straight line L connecting the side window glasses 1100 may extend in the x-direction or the −x-direction. For example, an imaginary straight line L connecting the first side window glass 1110 and the second side window glass 1120 to each other may extend in the x direction or the −x direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In one or more embodiments, a plurality of side mirrors 1300 may be provided. Any one selected from among the plurality of side mirrors 1300 may be arranged outside the first side window glass 1110. The other one selected from among the plurality of side mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning lamp, a seat belt warning lamp, an odometer, a hodometer, an automatic shift selector indicator lamp, a door open warning lamp, an engine oil warning lamp, and/or a low fuel warning light.

The center fascia 1500 may include a control panel on which a plurality of buttons for adjusting an audio device, an air conditioning device, and a heater of a seat are arranged. The center fascia 1500 may be arranged on one side of the cluster 1400.

A passenger seat dashboard 1600 may be spaced and/or apart (e.g., spaced apart or separated) from the cluster 1400 with the center fascia 1500 arranged therebetween. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display device 2 may include a display panel 3, and the display panel 3 may display an image. The display device 2 may be arranged inside the vehicle 1000. In one or more embodiments, the display device 2 may be arranged between the side window glasses 1100 facing each other. The display device 2 may be arranged on at least one selected from among the cluster 1400, the center fascia 1500, and the passenger seat dashboard 1600.

The display device 2 may include an organic light-emitting display device, an inorganic electroluminescent (EL) display device, a quantum dot display device, and/or the like. Hereinafter, as the display device 2 according to one or more embodiments of the disclosure, an organic light-emitting display device including the light-emitting device according to the disclosure will be described as an example, but one or more suitable types (kinds) of display devices as described above may be utilized in embodiments of the disclosure.

Referring to FIG. 6A, the display device 2 may be arranged on the center fascia 1500. In one or more embodiments, the display device 2 may display navigation information. In one or more embodiments, the display device 2 may display audio, video, or information regarding vehicle settings.

Referring to FIG. 6B, the display device 2 may be arranged on the cluster 1400. When the display device 2 is arranged on the cluster 1400, the cluster 1400 may display driving information and/or the like through the display device 2. For example, the cluster 1400 may be implemented digitally. The digital cluster 1400 may display vehicle information and driving information as images. For example, a needle and a gauge of a tachometer and one or more suitable warning light icons may be displayed by a digital signal.

Referring to FIG. 6C, the display device 2 may be arranged on the dashboard 1600 of the passenger seat. The display device 2 may be embedded in the passenger seat dashboard 1600 or arranged on the passenger seat dashboard 1600. In one or more embodiments, the display device 2 arranged on the passenger seat dashboard 1600 may display an image related to information displayed on the cluster 1400 and/or information displayed on the center fascia 1500. In one or more embodiments, the display device 2 arranged on the passenger seat dashboard 1600 may display information different from information displayed on the cluster 1400 and/or information displayed on the center fascia 1500.

### Manufacturing Method

Respective layers included in the hole transport region, the emission layer, and respective layers included in the electron transport region may be formed in a certain region by utilizing one or more suitable methods selected from among vacuum deposition, spin coating, casting, Langmuir-Blodgett (LB) deposition, ink-jet printing, laser-printing, and laser-induced thermal imaging.

When layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

### DEFINITION OF TERMS

The term “C₃-C₆₀ carbocyclic group” as utilized herein refers to a cyclic group including carbon only as a ring-forming atom and having three to sixty carbon atoms, and the term “C₁-C₆₀ heterocyclic group” as utilized herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group including one ring or a polycyclic group in which two or more rings are condensed with each other. For example, the C₁-C₆₀ heterocyclic group has 3 to 61 ring-forming atoms.

The term “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has 3 to 60 carbon atoms and does not include *—N=*′ as a ring-forming moiety, and the term “π electron-deficient nitrogen-containing C₁-C₆₀ heterocyclic group” as utilized herein refers to a heterocyclic group that has 1 to 60 carbon atoms and includes *—N=*′ as a ring-forming moiety.

For example, the C₃-C₆₀ carbocyclic group may be i) Group T1 or ii) a condensed cyclic group in which two or more Groups T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) Group T2, ii) a condensed cyclic group in which two or more Groups T2 are condensed with each other, or iii) a condensed cyclic group in which at least one Group T2 and at least one Group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

the π electron-rich C₃-C₆₀ cyclic group may be i) Group T1, ii) a condensed cyclic group in which two or more Groups T1 are condensed with each other, iii) Group T3, iv) a condensed cyclic group in which two or more Groups T3 are condensed with each other, or v) a condensed cyclic group in which at least one Group T3 and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),

the π electron-deficient nitrogen-containing C₁-C₆₀ heterocyclic group may be i) Group T4, ii) a condensed cyclic group in which two or more Groups T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

Group T3 may be a furan group, a thiophene group, a 1H-pyrrole group, a silole group, or a borole group, and

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ heterocyclic group” as utilized herein may refer to a group condensed to any cyclic group that is condensed with an another cyclic group (e.g., a benzo group, a naphto group, and/or the like), a monovalent group, or a polyvalent group (e.g., a divalent group, a trivalent group, a tetravalent group, and/or the like) according to the structure of a formula for which the corresponding term is utilized. For example, the “benzene group” may be a benzo group, a phenyl group, a phenylene group, and/or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₁-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the monovalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as utilized herein refers to a linear or branched aliphatic hydrocarbon monovalent group that has one to sixty carbon atoms, and specific examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as utilized herein refers to a divalent group having the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of the C₂-C₆₀ alkyl group, and examples thereof are an ethenyl group, a propenyl group, and a butenyl group. The term “C₂-C₆₀ alkenylene group” as utilized herein refers to a divalent group having the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of the C₂-C₆₀ alkyl group, and examples thereof include an ethynyl group and a propynyl group. The term “C₂-C₆₀ alkynylene group” as utilized herein refers to a divalent group having the same structure as the C₂-C₆₀ alkynyl group.

The term “C₁-C₆₀ alkoxy group” as utilized herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as utilized herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as utilized herein refers to a divalent group having the same structure as the C₃-C₁₀ cycloalkyl group.

The term “C₁-C₁₀ heterocycloalkyl group” as utilized herein refers to a monovalent cyclic group of 1 to 10 carbon atoms, further including, in addition to carbon atoms, at least one heteroatom, as ring-forming atoms, and specific examples are a 1,2,3,4-oxatriazolidinyl group, a tetrahydrofuranyl group, and a tetrahydrothiophenyl group. The term “C₁-C₁₀ heterocycloalkylene group” as utilized herein refers to a divalent group having the same structure as the C₁-C₁₀ heterocycloalkyl group.

The term C₃-C₁₀ cycloalkenyl group utilized herein refers to a monovalent cyclic group that has three to ten carbon atoms and at least one carbon-carbon double bond in the ring thereof and no aromaticity, and specific examples thereof are a cyclopentenyl group, a cyclohexenyl group, and a cycloheptenyl group. The term “C₃-C₁₀ cycloalkenylene group” as utilized herein refers to a divalent group having the same structure as the C₃-C₁₀ cycloalkenyl group.

The term “C₁-C₁₀ heterocycloalkenyl group” as utilized herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as utilized herein refers to a divalent group having the same structure as the C₁-C₁₀ heterocycloalkenyl group.

The term “C₆-C₆₀ aryl group” as utilized herein refers to a monovalent group having a carbocyclic aromatic system of 6 to 60 carbon atoms, and the term “C₆-C₆₀ arylene group” as utilized herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed with each other.

The term “C₁-C₆₀ heteroaryl group” as utilized herein refers to a monovalent group having a heterocyclic aromatic system of 1 to 60 carbon atoms, further including, 1 in addition to carbon atoms, at least one heteroatom, as ring-forming atoms. The term “C₁-C₆₀ heteroarylene group” as utilized herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed with each other.

The term “monovalent non-aromatic condensed polycyclic group” as utilized herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as utilized herein refers to a divalent group having the same structure as the monovalent non-aromatic condensed polycyclic group described above.

The term “monovalent non-aromatic condensed heteropolycyclic group” as utilized herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group are a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphtho silolyl group, a benzofurodibenzofuranyl group, a benzofurodibenzothiophenyl group, and a benzothienodibenzothiophenyl group. The term “divalent non-aromatic condensed heteropolycyclic group” as utilized herein refers to a divalent group having the same structure as the monovalent non-aromatic condensed heteropolycyclic group described above.

The term “C₆-C₆₀ aryloxy group” as utilized herein indicates —OA₁₀₂ (wherein A₁₀₂ is the C₆-C₆₀ aryl group), and the term “C₆-C₆₀ arylthio group” as utilized herein indicates —SA₁₀₃ (wherein A₁₀₃ is the C₆-C₆₀ aryl group).

The term “C₇-C₆₀ aryl alkyl group” utilized herein refers to -A₁₀₄A₁₀₅ (where A₁₀₄ may be a C₁-C₅₄ alkylene group, and A₁₀₅ may be a C₆-C₅₉ aryl group), and the term C₂-C₆₀ heteroaryl alkyl group” utilized herein refers to -A₁₀₆A₁₀₇ (where A₁₀₆ may be a C₁-C₅₉ alkylene group, and A₁₀₇ may be a C₁-C₅₉ heteroaryl group).

The term “R₁₀ₐ” as utilized herein refers to:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ in the specification may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

The term “heteroatom” as utilized herein refers to any atom other than a carbon atom. Examples of the heteroatom are O, S, N, P, Si, B, Ge, Se, and any combinations thereof.

The term “transition metal” as utilized herein includes hafnium (Hf), tantalum (Ta), tungsten (W), rhenium (Re), osmium (Os), iridium (Ir), platinum (Pt), gold (Au), and/or the like.

The term “Ph” as utilized herein refers to a phenyl group, the term “Me” as utilized herein refers to a methyl group, the term “Et” as utilized herein refers to an ethyl group, the term “ter-Bu” or “Bu^{t}” as utilized herein refers to a tert-butyl group, and the term “OMe” as utilized herein refers to a methoxy group.

The term “biphenyl group” as utilized herein refers to “a phenyl group substituted with a phenyl group.” For example, the “biphenyl group” is a substituted phenyl group having a C₆-C₆₀ aryl group as a substituent.

The term “terphenyl group” as utilized herein refers to “a phenyl group substituted with a biphenyl group”. For example, the “terphenyl group” is a substituted phenyl group having, as a substituent, a C₆-C₆₀ aryl group substituted with a C₆-C₆₀ aryl group.

*, *′, and *″ as utilized herein, unless defined otherwise, each refer to a binding site to a neighboring atom in a corresponding formula or moiety.

Hereinafter, compounds according to one or more embodiments and light-emitting devices according to one or more embodiments will be described in more detail with reference to the following synthesis examples and examples. The wording “B was used instead of A” used in describing Synthesis Examples refers to that a substantially identical molar equivalent of B was utilized in place of A.

### EXAMPLES

### Synthesis Example 1: Synthesis of Compound CPL1

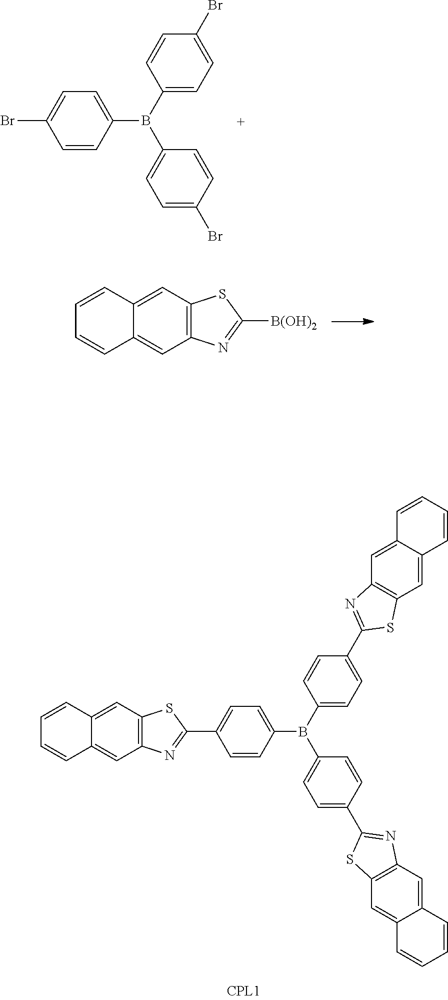 [SMILES: Brc1ccc(B(c2ccc(Br)cc2)c2ccc(Br)cc2)cc1 ; OB(O)c1nc2cc3ccccc3cc2s1 ; c1ccc2cc3sc(-c4ccc(B(c5ccc(-c6nc7cc8ccccc8cc7s6)cc5)c5ccc(-c6nc7cc8ccccc8cc7s6)cc5)cc4)nc3cc2c1]

Tris(4-bromophenyl)boron (about 10 g, about 0.021 mol), naphtho[2,3-d]thiazol-2-ylboronic acid (about 17.7 g, about 0.077 mol), potassium carbonate (about 17.28 g, about 0.125 mol), and catalyst Pd(PPh₃)₄ (about 1.16 g, about 0.001 mol) were added to about 150 mL of toluene, about 40 mL of ethanol, and about 20 mL of H₂O and then stirred and reacted at about 90° C. for about 12 hours. After the reaction was completed, an extraction process was performed thereon, and the resultant product was purified by column chromatography to obtain about 10.4 g of Compound CPL1 (yield: about 62.5%).

1H-NMR (500 MHz, CDCl₃): δ ppm, 8.23 (s, 3H), 8.12 (s, 3H), 8.06 (d, J=7.7, 1.3 Hz, 6H), 7.94 (d, J=7.4, 1.5 Hz, 6H), 7.84 (d, J=7.6, 1.4 Hz, 6H), 7.48 (dd, J=7.5, 1.5 Hz, 6H)

ESI-MS: m/z=791.2[M]⁺

### Synthesis Example 2: Synthesis of Compound CPL2

### Synthesis of Compound 2-1

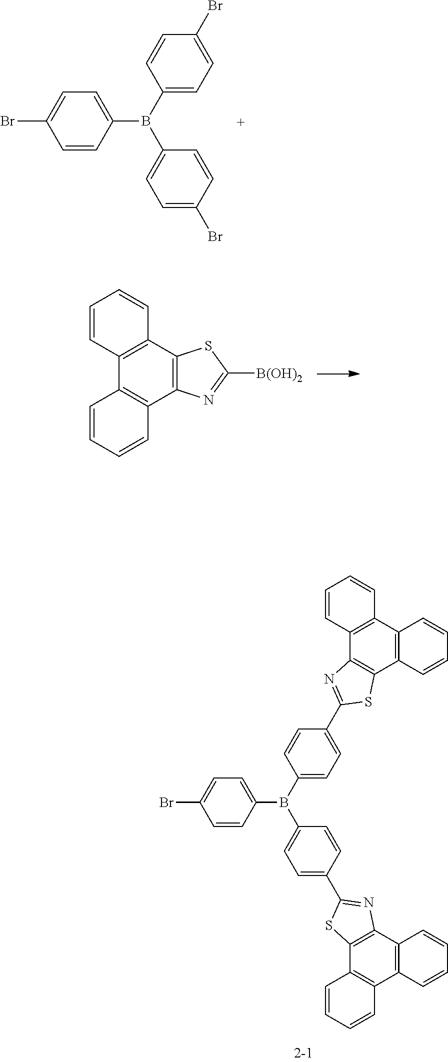 [SMILES: Brc1ccc(B(c2ccc(Br)cc2)c2ccc(Br)cc2)cc1 ; OB(O)c1nc2c3ccccc3c3ccccc3c2s1 ; Brc1ccc(B(c2ccc(-c3nc4c5ccccc5c5ccccc5c4s3)cc2)c2ccc(-c3nc4c5ccccc5c5ccccc5c4s3)cc2)cc1]

Tris(4-bromophenyl)boron (about 10 g, about 0.021 mol), phenanthro[9,10-d]thiazol-2-ylboronic acid (about 12.24 g, about 0.044 mol), potassium carbonate (about 28.86 g, about 0.209 mol), and catalyst Pd(PPh₃)₄ (about 2.41 g, about 0.002 mol) were added to about 250 mL of toluene, about 70 mL of ethanol, and about 60 mL of H₂O, and then stirred and reacted at about 90° C. for about 12 hours. After the reaction was completed, an extraction process was performed thereon, and the resultant product was purified by column chromatography to obtain about 10.3 g of Compound 2-1 (yield: about 62.3%).

### Synthesis of Compound CPL2

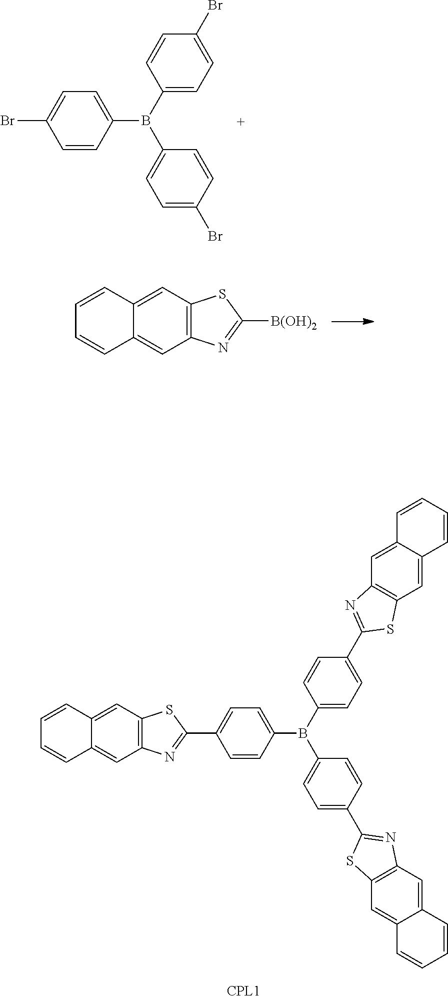 [SMILES: Brc1ccc(B(c2ccc(Br)cc2)c2ccc(Br)cc2)cc1 ; OB(O)c1nc2cc3ccccc3cc2s1 ; c1ccc2cc3sc(-c4ccc(B(c5ccc(-c6nc7cc8ccccc8cc7s6)cc5)c5ccc(-c6nc7cc8ccccc8cc7s6)cc5)cc4)nc3cc2c1]

Compound 2-1 (about 10 g, about 0.013 mol), naphtho[2,3-d]oxazol-2-ylboronic acid (about 3.25 g, about 0.015 mol), potassium carbonate (about 17.55 g, 1 about 0.127 mol), and catalyst Pd(PPh₃)₄ (about 1.47 g, about 0.001 mol) were added to about 200 mL of toluene, about 50 mL of ethanol, and about 25 mL of H₂O, and then stirred and reacted at about 90° C. for about 12 hours. After the reaction was completed, an extraction process was performed thereon, and the resultant product was purified by column chromatography to obtain about 11.2 g of Compound CPL2 (yield: about 60.9%).

1H-NMR (500 MHz, CDCl₃): δ ppm, 7.32 (d, J=7.4 Hz, 2H), 7.54 (m, 10H), 7.77 (d, J=7.2 Hz, 2H), 7.82 (d, J=7.3 Hz, 6H), 8.12-8.32 (m, 10H), 8.88 (d, J=7.5 Hz, 4H)

ESI-MS: m/z=875.22[M]⁺

### Synthesis Example 3: Synthesis of Compound CPL3

### Synthesis of Compound 3-1

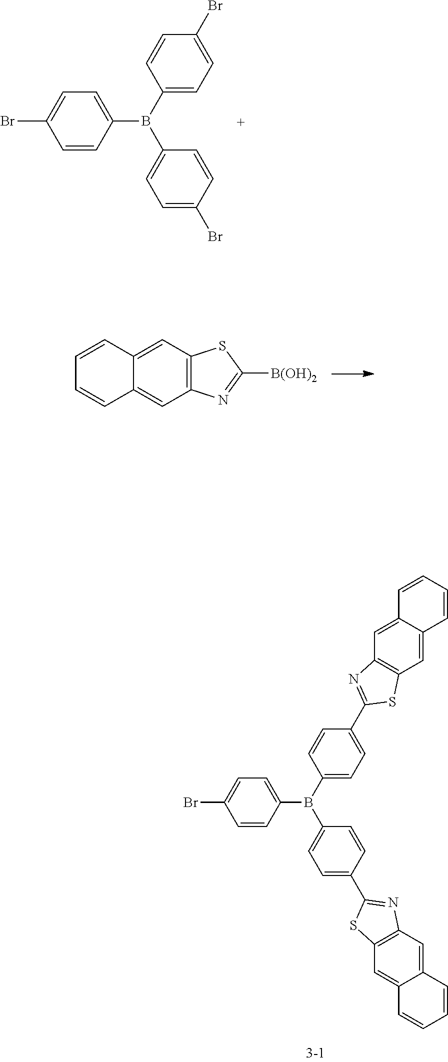 [SMILES: Brc1ccc(B(c2ccc(Br)cc2)c2ccc(Br)cc2)cc1 ; OB(O)c1nc2cc3ccccc3cc2s1 ; Brc1ccc(B(c2ccc(-c3nc4cc5ccccc5cc4s3)cc2)c2ccc(-c3nc4cc5ccccc5cc4s3)cc2)cc1]

Compound 3-1 was synthesized in substantially the same manner as in the synthesis of Compound 2-1 in Synthesis Example 2, except that naphtho[2,3-d]thiazol-2-ylboronic acid was utilized instead of phenanthro[9,10-d]thiazol-2-ylboronic acid.

### Synthesis of Compound CPL3

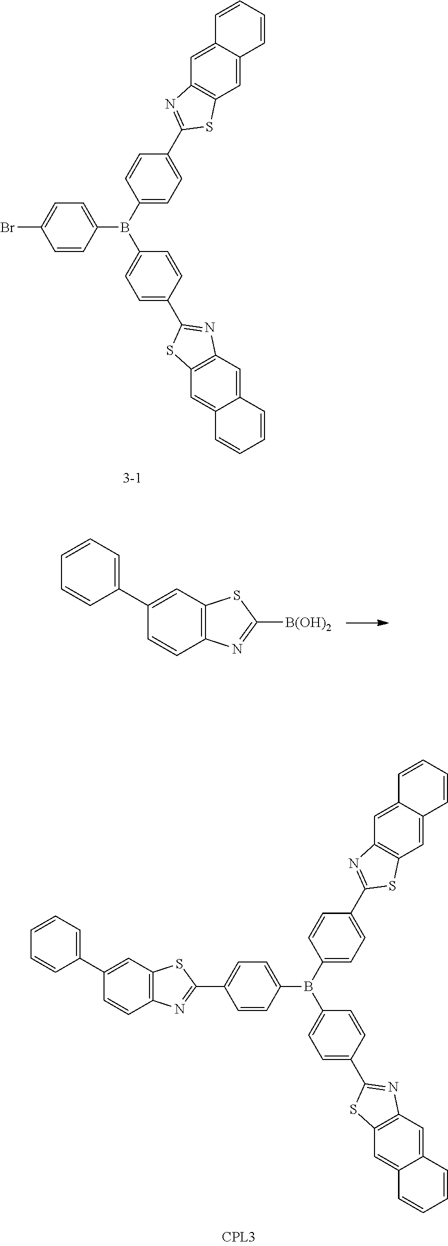 [SMILES: Brc1ccc(B(c2ccc(-c3nc4cc5ccccc5cc4s3)cc2)c2ccc(-c3nc4cc5ccccc5cc4s3)cc2)cc1 ; OB(O)c1nc2ccc(-c3ccccc3)cc2s1 ; c1ccc(-c2ccc3nc(-c4ccc(B(c5ccc(-c6nc7cc8ccccc8cc7s6)cc5)c5ccc(-c6nc7cc8ccccc8cc7s6)cc5)cc4)sc3c2)cc1]

About 7.45 g of Compound CPL3 was synthesized (yield: about 78.3%) in substantially the same manner as in the synthesis of Compound CPL2 in Synthesis Example 2, except that Compound 3-1 and (6-phenylbenzo[d]thiazol-2-yl)boronic acid were utilized instead of Compound 2-1 and naphtho[2,3-d]oxazol-2-ylboronic acid, respectively.

1H-NMR (500 MHz, CDCl₃): δ ppm, 7.37˜7.6 (m, 7H), 7.65 (dd, J=7.4, 2.3 Hz, 2H), 7.80-7.95 (m, 12H), 8.04-8.15 (m, 8H), 8.33 (s, J=7.6 Hz, 2H), 8.56 (s, 1H)

ESI-MS: m/z=817.2[M]⁺

### Synthesis Example 4; Synthesis of Compound CPL4

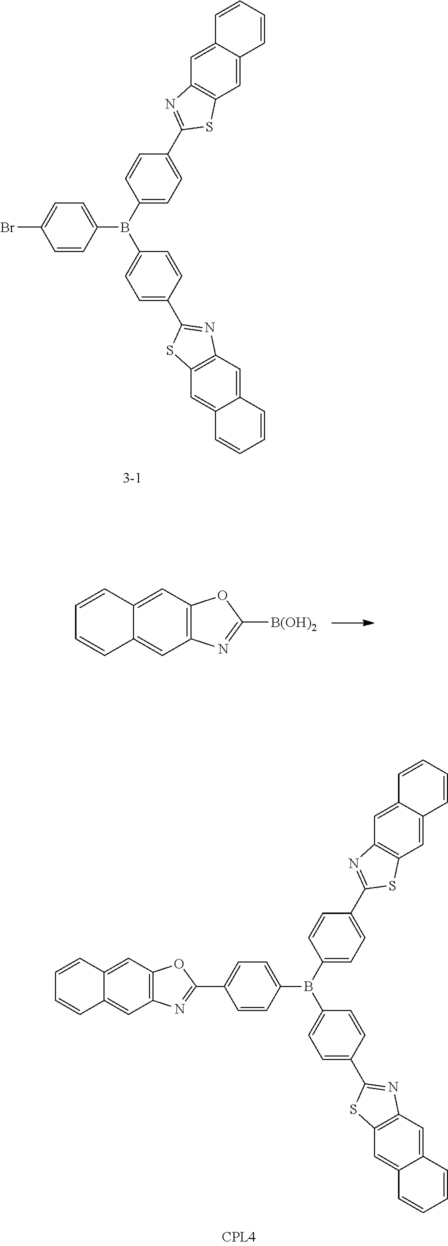 [SMILES: Brc1ccc(B(c2ccc(-c3nc4cc5ccccc5cc4s3)cc2)c2ccc(-c3nc4cc5ccccc5cc4s3)cc2)cc1 ; OB(O)c1nc2cc3ccccc3cc2o1 ; c1ccc2cc3oc(-c4ccc(B(c5ccc(-c6nc7cc8ccccc8cc7s6)cc5)c5ccc(-c6nc7cc8ccccc8cc7s6)cc5)cc4)nc3cc2c1]

About 6.9 g of Compound CPL4 was synthesized (yield: about 76.4%) in substantially the same manner as in the synthesis of Compound CPL2 in Synthesis Example 2, except that Compound 3-1 was utilized instead of Compound 2-1.

1H-NMR (500 MHz, CDCl₃): δ ppm, 7.46˜7.52 (m, 6H), 7.77 (s, 2H), 7.82-7.92 (m, 6H), 8.03 (m, 14H), 8.52 (s, 2H)

ESI-MS: m/z=775.2[M]⁺

### Evaluation Example 1

The HOMO energy level and the LUMO energy level of Compound 101 were evaluated through optimization of molecular structure in the ground state according to DFT at B3LYP/6-311 G(d,p) level by utilizing Gaussian 09 program, and after performing the molecular structure calculation in the ground state, the singlet energy (S₁) and the triplet energy (T₁) of Compound 101 were evaluated through TD-DFT for the excited state. Then a calculation of a difference between S₁ and T₁ of Compound 101, the ΔE_{ST} energy of Compound 101 was obtained, and the HOMO energy level, the LUMO energy level, the S₁ energy, the T₁ energy, and the ΔE_{ST} energy of Compound 101 are shown in Table 1. The same process was repeated for each of the compounds shown in Tables 1 and 2, and the results thereof are shown in Tables 1 and 2.

TABLE 1

| | HOMO | LUMO | S₁ | T₁ | ΔE_{ST} |
|---|---|---|---|---|---|
| | Energy level | Energy level | energy | energy | energy |
| p-dopant | (eV) | (eV) | (eV) | (eV) | (eV) |
| 101 | −9.05 | −4.81 | 3.47 | 2.55 | 0.92 |
| (HATCN) | | | | | |
| 102 | −7.91 | −5.50 | 2.61 | 2.11 | 0.50 |
| (F4-TCNQ) | | | | | |
| 103 | −7.58 | −5.02 | 3.02 | 2.72 | 0.30 |
| (TCNQ) | | | | | |
| C56 | −7.35 | −5.55 | 1.38 | 0.19 | 1.19 |
| C68 | −7.59 | −5.78 | 1.60 | 0.15 | 1.45 |
| C70 | −7.50 | −5.57 | 2.29 | 0.21 | 2.08 |
| S1 | −6.99 | −5.11 | 1.88 | 0.24 | 1.64 |
| S44 | −6.78 | −4.88 | 1.83 | 0.10 | 1.73 |

TABLE 2

| Second | | | | | |
|---|---|---|---|---|---|
| hole | HOMO | LUMO | S₁ | T₁ | ΔE_{ST} |
| transport | Energy level | Energy level | energy | energy | energy |
| material | (eV) | (eV) | (eV) | (eV) | (eV) |
| 201 | −5.00 | −1.42 | 3.05 | 2.50 | 0.56 |
| (NPB) | | | | | |
| 202 (m- | −5.03 | −0.79 | 3.67 | 3.10 | 0.57 |
| MTDATA) | | | | | |
| 203 | −4.98 | −1.21 | 3.26 | 2.63 | 0.63 |
| (HT45) | | | | | |
| HT(2)1 | −4.96 | −1.12 | 3.35 | 2.66 | 0.69 |
| HT(2)2 | −4.95 | −1.12 | 3.34 | 2.66 | 0.68 |
| HT(2)3 | −4.95 | −1.14 | 3.30 | 2.65 | 0.65 |
| HT(2)4 | −4.94 | −1.10 | 3.34 | 2.65 | 0.69 |
| HT(2)5 | −4.97 | −1.17 | 3.32 | 2.64 | 0.68 |
| HT(2)6 | −5.02 | −1.12 | 3.32 | 2.67 | 0.64 |
| HT(2)7 | −4.96 | −1.13 | 3.33 | 2.64 | 0.69 |
| HT(2)8 | −5.06 | −1.29 | 3.29 | 2.70 | 0.59 |
| HT(2)9 | −5.05 | −1.23 | 3.32 | 2.70 | 0.62 |

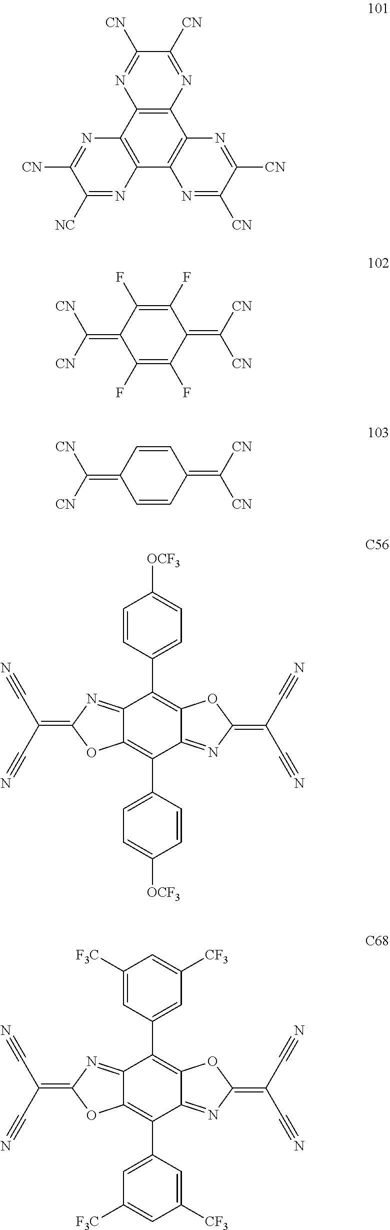

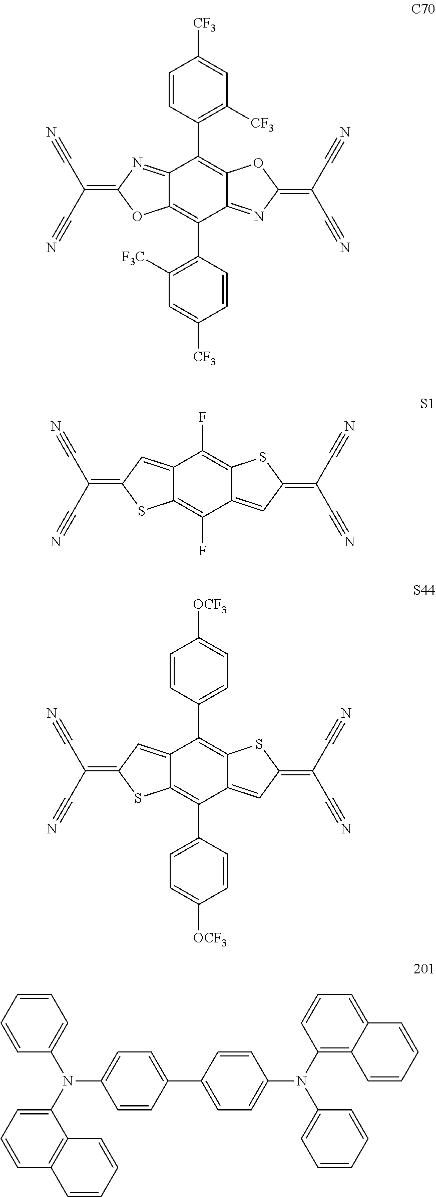 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1cc2c(F)c3sc(=C(C#N)C#N)cc3c(F)c2s1 ; N#CC(C#N)=c1cc2c(-c3ccc(OC(F)(F)F)cc3)c3sc(=C(C#N)C#N)cc3c(-c3ccc(OC(F)(F)F)cc3)c2s1 ; c1ccc(N(c2ccc(-c3ccc(N(c4ccccc4)c4cccc5ccccc45)cc3)cc2)c2cccc3ccccc23)cc1]

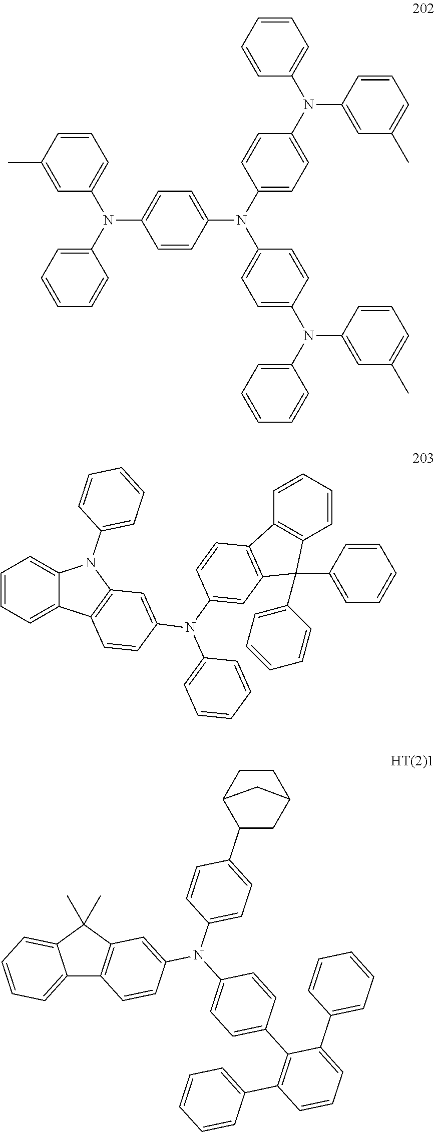

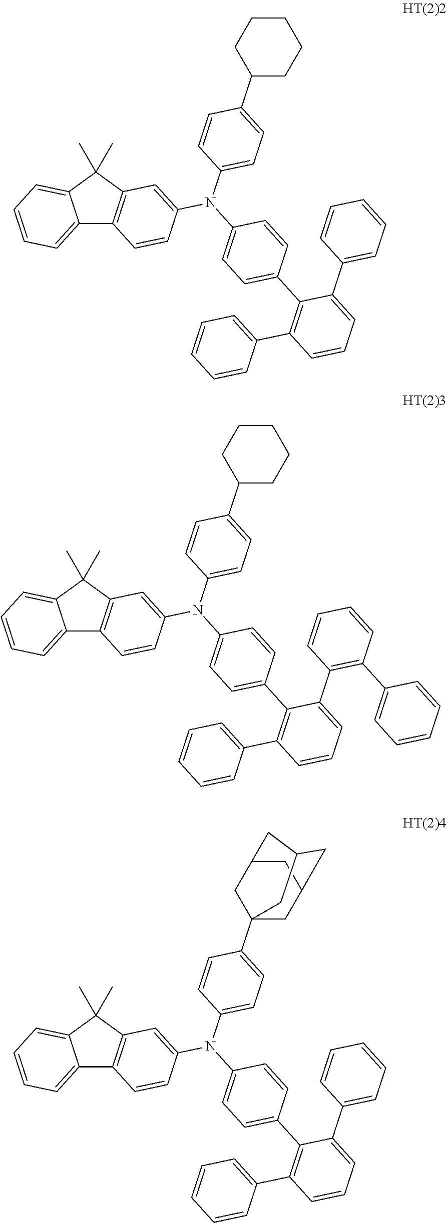 [SMILES: CC1(C)c2ccccc2-c2ccc(N(c3ccc(-c4c(-c5ccccc5)cccc4-c4ccccc4)cc3)c3ccc(C4CCCCC4)cc3)cc21 ; CC1(C)c2ccccc2-c2ccc(N(c3ccc(-c4c(-c5ccccc5)cccc4-c4ccccc4-c4ccccc4)cc3)c3ccc(C4CCCCC4)cc3)cc21 ; CC1(C)c2ccccc2-c2ccc(N(c3ccc(-c4c(-c5ccccc5)cccc4-c4ccccc4)cc3)c3ccc(C45CC6CC(CC(C6)C4)C5)cc3)cc21]

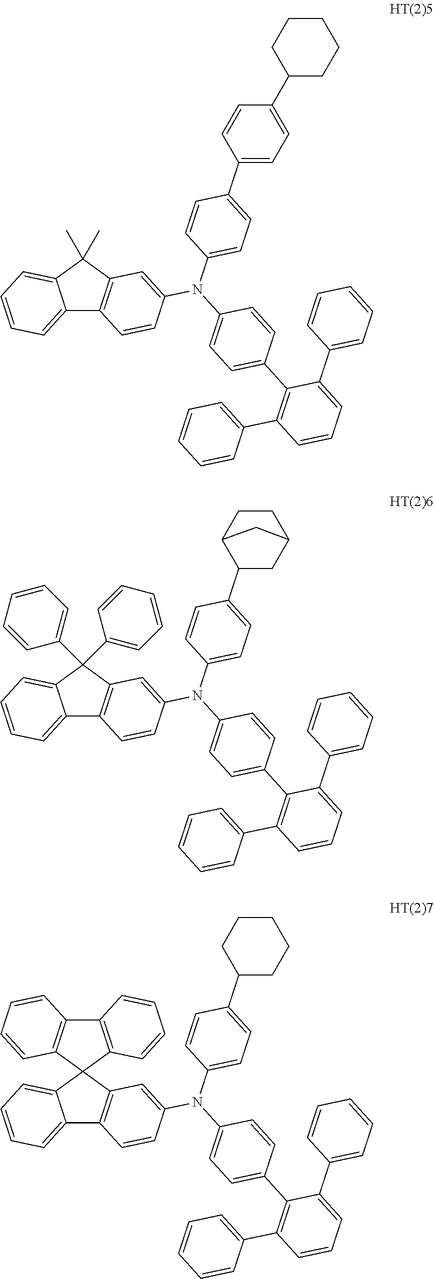 [SMILES: CC1(C)c2ccccc2-c2ccc(N(c3ccc(-c4ccc(C5CCCCC5)cc4)cc3)c3ccc(-c4c(-c5ccccc5)cccc4-c4ccccc4)cc3)cc21 ; c1ccc(-c2cccc(-c3ccccc3)c2-c2ccc(N(c3ccc(C4CC5CCC4C5)cc3)c3ccc4c(c3)C(c3ccccc3)(c3ccccc3)c3ccccc3-4)cc2)cc1 ; c1ccc(-c2cccc(-c3ccccc3)c2-c2ccc(N(c3ccc(C4CCCCC4)cc3)c3ccc4c(c3)C3(c5ccccc5-c5ccccc53)c3ccccc3-4)cc2)cc1]

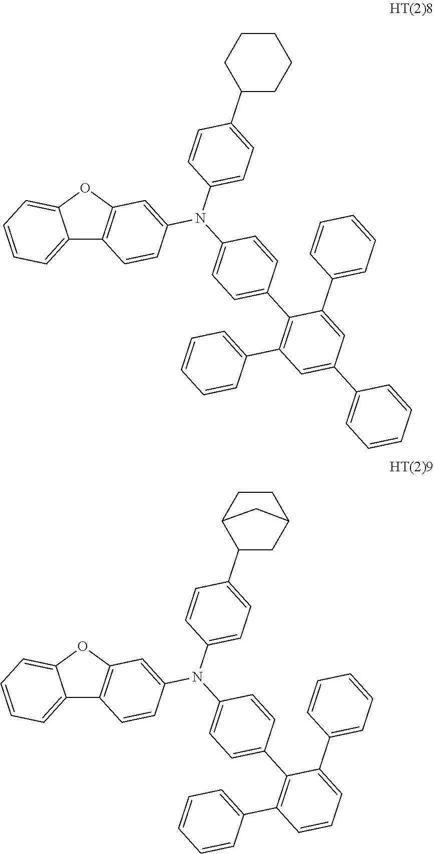 [SMILES: c1ccc(-c2cc(-c3ccccc3)c(-c3ccc(N(c4ccc(C5CCCCC5)cc4)c4ccc5c(c4)oc4ccccc45)cc3)c(-c3ccccc3)c2)cc1 ; c1ccc(-c2cccc(-c3ccccc3)c2-c2ccc(N(c3ccc(C4CC5CCC4C5)cc3)c3ccc4c(c3)oc3ccccc34)cc2)cc1]

### Evaluation Example 2

After Film CPL1 having a thickness of about 1,500 nm was manufactured by depositing Compound CPL1 on a glass substrate, the manufactured film was utilized to evaluate the refractive index of Compound CPL1 for each of light having a wavelength of about 633 nm, light having a wavelength of about 530 nm, and light having a wavelength of about 450 nm according to Cauchy Film Model by utilizing Ellipsometer M-2000 (J. A. Woollam) at a temperature of about 25° C. and relative humidity of about 50%. The results thereof are shown in Table 3. The same process was repeated for each of the compounds shown in Table 3, and the results thereof are shown in Table 3.

TABLE 3

| | Refractive index | | |
|---|---|---|---|
| | Refractive index | Refractive index | Refractive index |
| | for light having a | for light having a | for light having a |
| | wavelength of | wavelength of | wavelength of |
| Film no. | 633 nm | 530 nm | 450 nm |
| CPL1 | 1.90 | 2.02 | 2.29 |
| CPL2 | 1.87 | 1.97 | 2.25 |
| CPL3 | 1.90 | 2.01 | 2.29 |
| CPL4 | 1.90 | 2.01 | 2.27 |
| CPL-R1 | 1.66 | 1.68 | 1.75 |
| CPL-R2 | 1.63 | 1.81 | 1.99 |

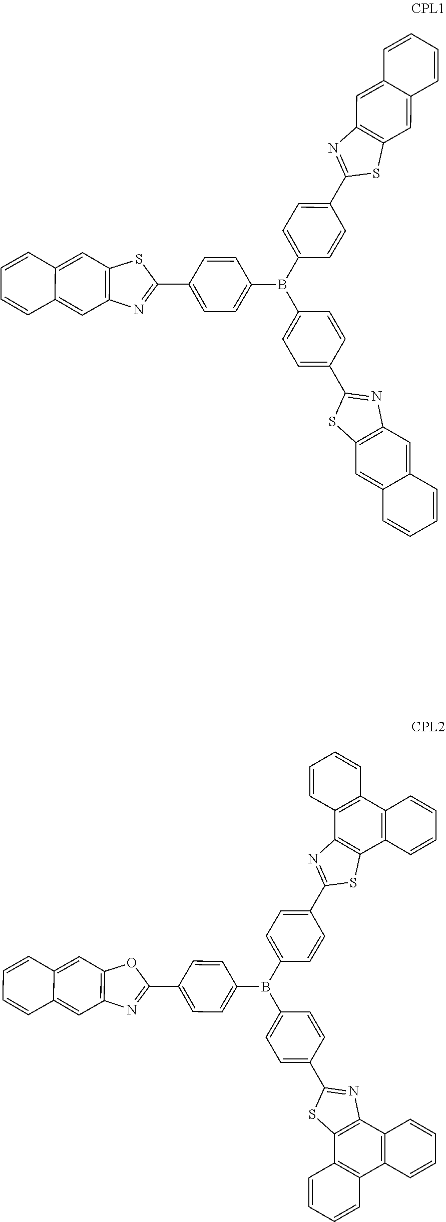 [SMILES: c1ccc2cc3sc(-c4ccc(B(c5ccc(-c6nc7cc8ccccc8cc7s6)cc5)c5ccc(-c6nc7cc8ccccc8cc7s6)cc5)cc4)nc3cc2c1 ; c1ccc2cc3oc(-c4ccc(B(c5ccc(-c6nc7c8ccccc8c8ccccc8c7s6)cc5)c5ccc(-c6nc7c8ccccc8c8ccccc8c7s6)cc5)cc4)nc3cc2c1]

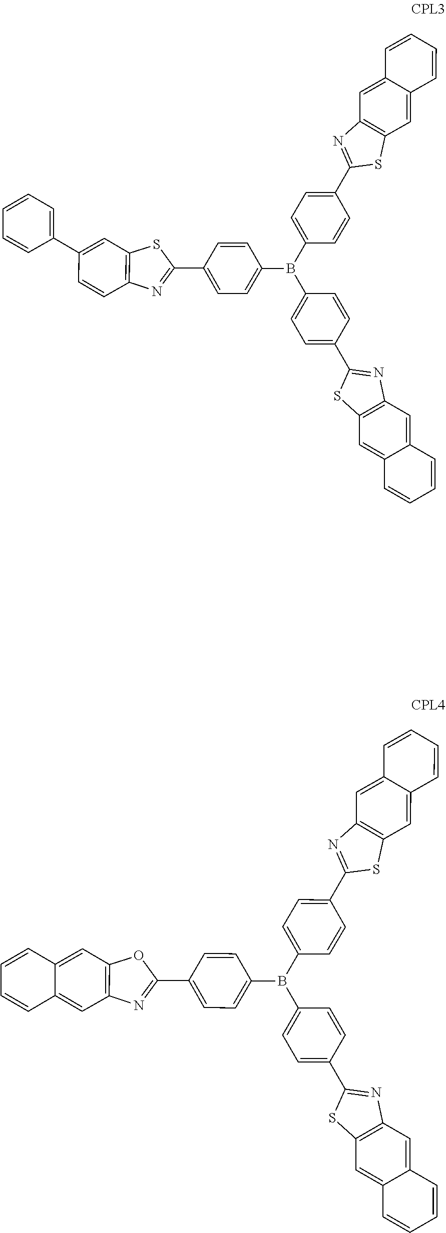 [SMILES: c1ccc(-c2ccc3nc(-c4ccc(B(c5ccc(-c6nc7cc8ccccc8cc7s6)cc5)c5ccc(-c6nc7cc8ccccc8cc7s6)cc5)cc4)sc3c2)cc1 ; c1ccc2cc3oc(-c4ccc(B(c5ccc(-c6nc7cc8ccccc8cc7s6)cc5)c5ccc(-c6nc7cc8ccccc8cc7s6)cc5)cc4)nc3cc2c1]

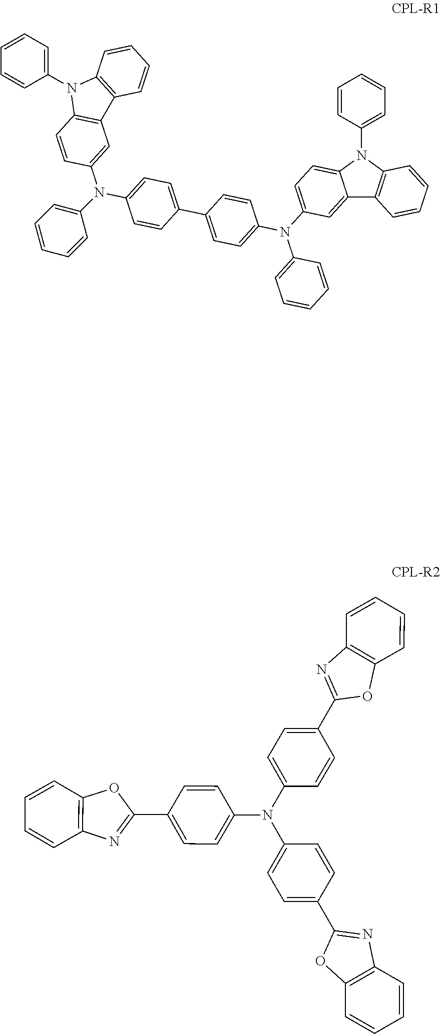 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc2oc(-c3ccc(N(c4ccc(-c5nc6ccccc6o5)cc4)c4ccc(-c5nc6ccccc6o5)cc4)cc3)nc2c1]

### Example 1

A glass substrate (product of Corning Inc.) with an anode including Ag having a thickness of about 1,000 Å and ITO (about 15 Ω/cm²) having a thickness of about 1,200 Å was cut to a size of about 50 mm×about 50 mm×about 0.7 mm, sonicated with isopropyl alcohol and pure water each for about 5 minutes, and then cleaned by exposure to ultraviolet rays and ozone for about 30 minutes. Then, the glass substrate was provided to a vacuum deposition apparatus.

A p-dopant (Compound C₅₆) and a first hole transport material (Compound 201) were vacuum-deposited on the anode at a weight ratio of about 3:97 to form a first layer having a thickness of about 100 Å, and a second hole transport material (Compound HT(2)1) was vacuum-deposited on the first layer to form a second layer having a thickness of about 1,250 Å.

A host (Compounds H125 and H126) and a dopant (Compound R01) were vacuum-deposited on the second layer to form an emission layer having a thickness of about 200 Å. The weight ratio of Compound H125 and Compound H126 was about 5:5, and the amount of the dopant was about 10 wt % based on the total weight (100 wt %) of the emission layer.

Compound ET37 was vacuum-deposited on the emission layer to form a hole blocking layer having a thickness of about 50 Å, and Compound ET46 and Liq were vacuum-deposited on the hole blocking layer at a weight ratio of about 5:5 to form an electron transport layer having a thickness of about 310 Å. Subsequently, Yb was vacuum-deposited on the electron transport layer to form an electron injection layer having a thickness of about 15 Å, and Ag and Mg were vacuum-deposited thereon at a weight ratio of about 9:1 to form a cathode having a thickness of about 80 Å.

Next, a capping material (Compound CPL1) was vacuum-deposited on the cathode to form a capping layer having a thickness of about 700 Å, thereby completing the manufacture of an organic light-emitting device.

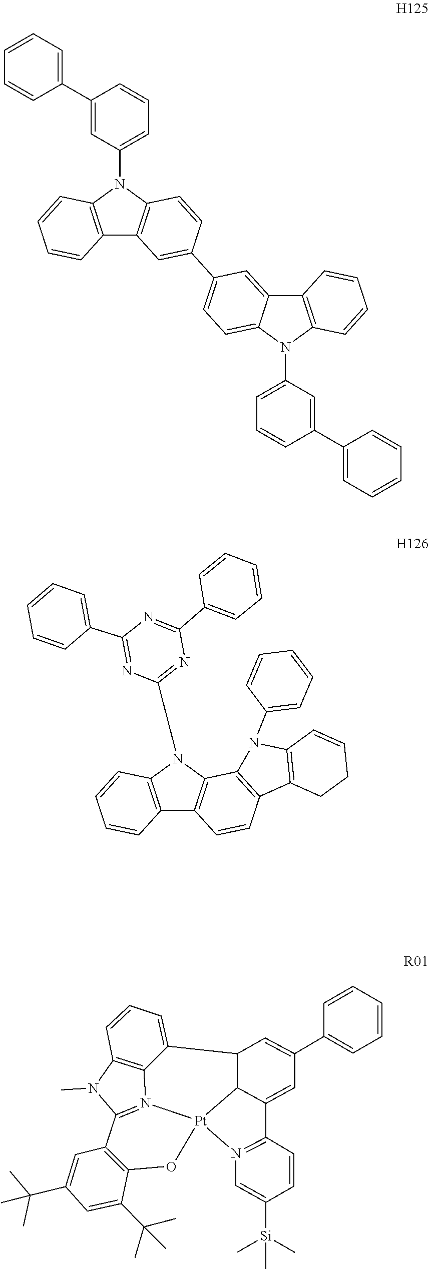

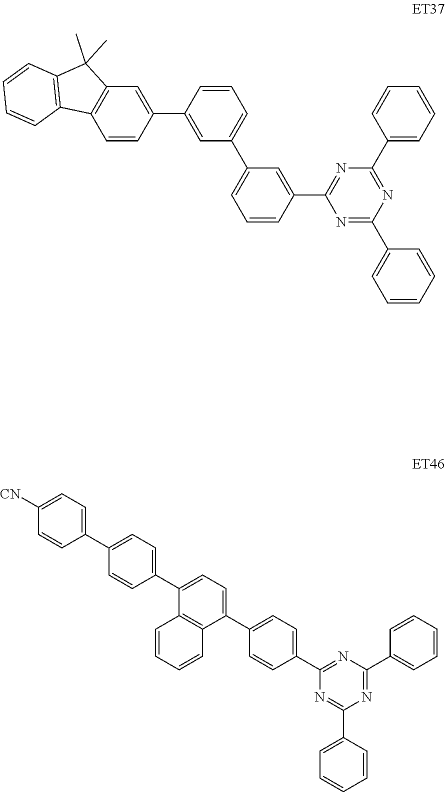

### Examples 2 to 180 and Comparative Examples 1 to 6 and 10 to 15

Organic light-emitting devices were manufactured in substantially the same manner as in Example 1, except that the compounds shown in Tables 4 to 8 were each utilized as the p-dopant, the second hole transport material, and the capping material.

### Comparative Examples 7 to 9 and 16 to 18

Organic light-emitting devices were manufactured in substantially the same manner as in Example 1, except that, if (e.g., when) forming the first layer, the p-dopant was not utilized, and the compounds shown in Table 8 were each utilized as the second hole transport material and the capping material.

### Comparative Examples 19 to 24

Organic light-emitting devices were manufactured in substantially the same manner as in Example 1, except that the compounds shown in Table 8 were each utilized as the p-dopant and the second hole transport material, and the capping layer was not formed.

### Comparative Examples 25 to 27

Organic light-emitting devices were manufactured in substantially the same manner as in Example 1, except that, if (e.g., when) forming the first layer, the p-dopant was not utilized, the compounds shown in Table 8 were each utilized as the second hole transport material, and the capping layer was not formed.

### Evaluation Example 3

The driving voltage (V) and the luminescence efficiency (cd/A) of the organic light-emitting devices manufactured in Examples 1 to 180 and Comparative Examples 1 to 27 were each evaluated by utilizing Keithley MU 236 and a luminance meter (Minolta Cs-1000A), and the results thereof are shown as relative values (%) with respect to Comparative Example 27 in Tables 4 to 8.

Then, the lifespan at about 1,000 cd/m², i.e., time taken for the initial luminance to decrease to about 95% thereof (Hr) of the organic light-emitting devices manufactured in Examples 1 to 180 and Comparative Examples 1 to 27 were measured and evaluated, and the results thereof are shown as relative values (%) with respect to Comparative Example 27 in Tables 4 to 8.

In Tables 4 to 8, ΔT₁ represents a difference between T₁ energy of the p-dopant and T₁ energy of the second hole transport material (i.e., absolute value of the difference between the T₁ energy of the p-dopant and the T₁ energy of the second hole transport material).

TABLE 4

| | | Second | | | Driving | Luminescence | |
|---|---|---|---|---|---|---|---|
| | | hole | | | voltage | efficiency | Lifespan |
| | p- | transport | ΔT₁ | Capping | (relative | (relative | (relative |
| No. | dopant | material | (eV) | material | value) | value) | value) |
| Example 1 | C56 | HT(2)1 | 2.47 | CPL1 | 78% | 124% | 131% |
| Example 2 | C56 | HT(2)2 | 2.47 | CPL1 | 79% | 124% | 131% |
| Example 3 | C56 | HT(2)3 | 2.46 | CPL1 | 79% | 124% | 131% |
| Example 4 | C56 | HT(2)4 | 2.46 | CPL1 | 80% | 124% | 131% |
| Example 5 | C56 | HT(2)5 | 2.45 | CPL1 | 77% | 124% | 131% |
| Example 6 | C56 | HT(2)6 | 2.48 | CPL1 | 76% | 124% | 131% |
| Example 7 | C56 | HT(2)7 | 2.45 | CPL1 | 78% | 124% | 131% |
| Example 8 | C56 | HT(2)8 | 2.51 | CPL1 | 79% | 124% | 131% |
| Example 9 | C56 | HT(2)9 | 2.51 | CPL1 | 78% | 124% | 131% |
| Example | C68 | HT(2)1 | 2.51 | CPL1 | 78% | 124% | 131% |
| 10 | | | | | | | |
| Example | C68 | HT(2)2 | 2.51 | CPL1 | 79% | 124% | 131% |
| 11 | | | | | | | |
| Example | C68 | HT(2)3 | 2.50 | CPL1 | 79% | 124% | 131% |
| 12 | | | | | | | |
| Example | C68 | HT(2)4 | 2.50 | CPL1 | 80% | 124% | 131% |
| 13 | | | | | | | |
| Example | C68 | HT(2)5 | 2.49 | CPL1 | 77% | 124% | 131% |
| 14 | | | | | | | |
| Example | C68 | HT(2)6 | 2.52 | CPL1 | 76% | 124% | 131% |
| 15 | | | | | | | |
| Example | C68 | HT(2)7 | 2.49 | CPL1 | 78% | 124% | 131% |
| 16 | | | | | | | |
| Example | C68 | HT(2)8 | 2.55 | CPL1 | 78% | 124% | 131% |
| 17 | | | | | | | |
| Example | C68 | HT(2)9 | 2.55 | CPL1 | 77% | 124% | 131% |
| 18 | | | | | | | |
| Example | C70 | HT(2)1 | 2.45 | CPL1 | 79% | 124% | 131% |
| 19 | | | | | | | |
| Example | C70 | HT(2)2 | 2.45 | CPL1 | 80% | 124% | 131% |
| 20 | | | | | | | |
| Example | C70 | HT(2)3 | 2.44 | CPL1 | 80% | 124% | 131% |
| 21 | | | | | | | |
| Example | C70 | HT(2)4 | 2.44 | CPL1 | 81% | 124% | 131% |
| 22 | | | | | | | |
| Example | C70 | HT(2)5 | 2.43 | CPL1 | 78% | 124% | 131% |
| 23 | | | | | | | |
| Example | C70 | HT(2)6 | 2.46 | CPL1 | 77% | 124% | 131% |
| 24 | | | | | | | |
| Example | C70 | HT(2)7 | 2.43 | CPL1 | 79% | 124% | 131% |
| 25 | | | | | | | |
| Example | C70 | HT(2)8 | 2.49 | CPL1 | 79% | 124% | 131% |
| 26 | | | | | | | |
| Example | C70 | HT(2)9 | 2.49 | CPL1 | 78% | 124% | 131% |
| 27 | | | | | | | |
| Example | S1 | HT(2)1 | 2.42 | CPL1 | 74% | 124% | 132% |
| 28 | | | | | | | |
| Example | S1 | HT(2)2 | 2.42 | CPL1 | 73% | 125% | 132% |
| 29 | | | | | | | |
| Example | S1 | HT(2)3 | 2.41 | CPL1 | 73% | 125% | 132% |
| 30 | | | | | | | |
| Example | S1 | HT(2)4 | 2.41 | CPL1 | 72% | 125% | 133% |
| 31 | | | | | | | |
| Example | S1 | HT(2)5 | 2.40 | CPL1 | 75% | 124% | 132% |
| 32 | | | | | | | |
| Example | S1 | HT(2)6 | 2.43 | CPL1 | 80% | 124% | 131% |
| 33 | | | | | | | |
| Example | S1 | HT(2)7 | 2.40 | CPL1 | 74% | 124% | 132% |
| 34 | | | | | | | |
| Example | S1 | HT(2)8 | 2.46 | CPL1 | 84% | 124% | 130% |
| 35 | | | | | | | |
| Example | S1 | HT(2)9 | 2.46 | CPL1 | 83% | 124% | 130% |
| 36 | | | | | | | |
| Example | S44 | HT(2)1 | 2.56 | CPL1 | 72% | 124% | 131% |
| 37 | | | | | | | |
| Example | S44 | HT(2)2 | 2.56 | CPL1 | 70% | 125% | 131% |
| 38 | | | | | | | |
| Example | S44 | HT(2)3 | 2.55 | CPL1 | 70% | 125% | 131% |
| 39 | | | | | | | |
| Example | S44 | HT(2)4 | 2.55 | CPL1 | 68% | 125% | 131% |
| 40 | | | | | | | |
| Example | S44 | HT(2)5 | 2.54 | CPL1 | 75% | 124% | 131% |
| 41 | | | | | | | |
| Example | S44 | HT(2)6 | 2.57 | CPL1 | 87% | 124% | 130% |
| 42 | | | | | | | |
| Example | S44 | HT(2)7 | 2.54 | CPL1 | 73% | 124% | 131% |
| 43 | | | | | | | |
| Example | S44 | HT(2)8 | 2.60 | CPL1 | 97% | 124% | 129% |
| 44 | | | | | | | |
| Example | S44 | HT(2)9 | 2.60 | CPL1 | 95% | 124% | 129% |
| 45 | | | | | | | |

TABLE 5

| | | Second | | | Driving | Luminescence | |
|---|---|---|---|---|---|---|---|
| | | hole | | | voltage | efficiency | Lifespan |
| | p- | transport | ΔT₁ | Capping | (relative | (relative | (relative |
| No. | dopant | material | (eV) | material | value) | value) | value) |
| Example | C56 | HT(2)1 | 2.47 | CPL2 | 79% | 122% | 129% |
| 46 | | | | | | | |
| Example | C56 | HT(2)2 | 2.47 | CPL2 | 80% | 122% | 129% |
| 47 | | | | | | | |
| Example | C56 | HT(2)3 | 2.46 | CPL2 | 80% | 122% | 129% |
| 48 | | | | | | | |
| Example | C56 | HT(2)4 | 2.46 | CPL2 | 81% | 122% | 129% |
| 49 | | | | | | | |
| Example | C56 | HT(2)5 | 2.45 | CPL2 | 78% | 122% | 129% |
| 50 | | | | | | | |
| Example | C56 | HT(2)6 | 2.48 | CPL2 | 77% | 122% | 129% |
| 51 | | | | | | | |
| Example | C56 | HT(2)7 | 2.45 | CPL2 | 79% | 122% | 129% |
| 52 | | | | | | | |
| Example | C56 | HT(2)8 | 2.51 | CPL2 | 80% | 122% | 129% |
| 53 | | | | | | | |
| Example | C56 | HT(2)9 | 2.51 | CPL2 | 79% | 122% | 129% |
| 54 | | | | | | | |
| Example | C68 | HT(2)1 | 2.51 | CPL2 | 80% | 122% | 129% |
| 55 | | | | | | | |
| Example | C68 | HT(2)2 | 2.51 | CPL2 | 80% | 122% | 129% |
| 56 | | | | | | | |
| Example | C68 | HT(2)3 | 2.50 | CPL2 | 80% | 122% | 129% |
| 57 | | | | | | | |
| Example | C68 | HT(2)4 | 2.50 | CPL2 | 82% | 122% | 129% |
| 58 | | | | | | | |
| Example | C68 | HT(2)5 | 2.49 | CPL2 | 79% | 122% | 129% |
| 59 | | | | | | | |
| Example | C68 | HT(2)6 | 2.52 | CPL2 | 77% | 122% | 129% |
| 60 | | | | | | | |
| Example | C68 | HT(2)7 | 2.49 | CPL2 | 80% | 122% | 129% |
| 61 | | | | | | | |
| Example | C68 | HT(2)8 | 2.55 | CPL2 | 80% | 122% | 129% |
| 62 | | | | | | | |
| Example | C68 | HT(2)9 | 2.55 | CPL2 | 79% | 122% | 129% |
| 63 | | | | | | | |
| Example | C70 | HT(2)1 | 2.45 | CPL2 | 80% | 122% | 129% |
| 64 | | | | | | | |
| Example | C70 | HT(2)2 | 2.45 | CPL2 | 81% | 122% | 129% |
| 65 | | | | | | | |
| Example | C70 | HT(2)3 | 2.44 | CPL2 | 81% | 122% | 129% |
| 66 | | | | | | | |
| Example | C70 | HT(2)4 | 2.44 | CPL2 | 82% | 122% | 129% |
| 67 | | | | | | | |
| Example | C70 | HT(2)5 | 2.43 | CPL2 | 79% | 122% | 129% |
| 68 | | | | | | | |
| Example | C70 | HT(2)6 | 2.46 | CPL2 | 78% | 122% | 129% |
| 69 | | | | | | | |
| Example | C70 | HT(2)7 | 2.43 | CPL2 | 80% | 122% | 129% |
| 70 | | | | | | | |
| Example | C70 | HT(2)8 | 2.49 | CPL2 | 80% | 122% | 129% |
| 71 | | | | | | | |
| Example | C70 | HT(2)9 | 2.49 | CPL2 | 80% | 122% | 129% |
| 72 | | | | | | | |
| Example | S1 | HT(2)1 | 2.42 | CPL2 | 75% | 122% | 130% |
| 73 | | | | | | | |
| Example | S1 | HT(2)2 | 2.42 | CPL2 | 74% | 123% | 130% |
| 74 | | | | | | | |
| Example | S1 | HT(2)3 | 2.41 | CPL2 | 74% | 123% | 130% |
| 75 | | | | | | | |
| Example | S1 | HT(2)4 | 2.41 | CPL2 | 73% | 123% | 131% |
| 76 | | | | | | | |
| Example | S1 | HT(2)5 | 2.40 | CPL2 | 76% | 122% | 130% |
| 77 | | | | | | | |
| Example | S1 | HT(2)6 | 2.43 | CPL2 | 81% | 122% | 129% |
| 78 | | | | | | | |
| Example | S1 | HT(2)7 | 2.40 | CPL2 | 75% | 122% | 130% |
| 79 | | | | | | | |
| Example | S1 | HT(2)8 | 2.46 | CPL2 | 85% | 122% | 128% |
| 80 | | | | | | | |
| Example | S1 | HT(2)9 | 2.46 | CPL2 | 85% | 122% | 128% |
| 81 | | | | | | | |
| Example | S44 | HT(2)1 | 2.56 | CPL2 | 73% | 122% | 129% |
| 82 | | | | | | | |
| Example | S44 | HT(2)2 | 2.56 | CPL2 | 72% | 123% | 129% |
| 83 | | | | | | | |
| Example | S44 | HT(2)3 | 2.55 | CPL2 | 72% | 123% | 129% |
| 84 | | | | | | | |
| Example | S44 | HT(2)4 | 2.55 | CPL2 | 69% | 123% | 129% |
| 85 | | | | | | | |
| Example | S44 | HT(2)5 | 2.54 | CPL2 | 77% | 122% | 129% |
| 86 | | | | | | | |
| Example | S44 | HT(2)6 | 2.57 | CPL2 | 89% | 122% | 128% |
| 87 | | | | | | | |
| Example | S44 | HT(2)7 | 2.54 | CPL2 | 74% | 122% | 129% |
| 88 | | | | | | | |
| Example | S44 | HT(2)8 | 2.60 | CPL2 | 99% | 122% | 127% |
| 89 | | | | | | | |
| Example | S44 | HT(2)9 | 2.60 | CPL2 | 96% | 122% | 127% |
| 90 | | | | | | | |

TABLE 6

| | | Second | | | Driving | Luminescence | |
|---|---|---|---|---|---|---|---|
| | | hole | | | voltage | efficiency | Lifespan |
| | p- | transport | ΔT₁ | Capping | (relative | (relative | (relative |
| No. | dopant | material | (eV) | material | value) | value) | value) |
| Example | C56 | HT(2)1 | 2.47 | CPL3 | 78% | 124% | 131% |
| 91 | | | | | | | |
| Example | C56 | HT(2)2 | 2.47 | CPL3 | 79% | 124% | 131% |
| 92 | | | | | | | |
| Example | C56 | HT(2)3 | 2.46 | CPL3 | 79% | 124% | 131% |
| 93 | | | | | | | |
| Example | C56 | HT(2)4 | 2.46 | CPL3 | 80% | 124% | 131% |
| 94 | | | | | | | |
| Example | C56 | HT(2)5 | 2.45 | CPL3 | 77% | 124% | 131% |
| 95 | | | | | | | |
| Example | C56 | HT(2)6 | 2.48 | CPL3 | 76% | 124% | 131% |
| 96 | | | | | | | |
| Example | C56 | HT(2)7 | 2.45 | CPL3 | 78% | 124% | 131% |
| 97 | | | | | | | |
| Example | C56 | HT(2)8 | 2.51 | CPL3 | 79% | 124% | 131% |
| 98 | | | | | | | |
| Example | C56 | HT(2)9 | 2.51 | CPL3 | 78% | 124% | 131% |
| 99 | | | | | | | |
| Example | C68 | HT(2)1 | 2.51 | CPL3 | 78% | 124% | 131% |
| 100 | | | | | | | |
| Example | C68 | HT(2)2 | 2.51 | CPL3 | 79% | 124% | 131% |
| 101 | | | | | | | |
| Example | C68 | HT(2)3 | 2.50 | CPL3 | 79% | 124% | 131% |
| 102 | | | | | | | |
| Example | C68 | HT(2)4 | 2.50 | CPL3 | 80% | 124% | 131% |
| 103 | | | | | | | |
| Example | C68 | HT(2)5 | 2.49 | CPL3 | 77% | 124% | 131% |
| 104 | | | | | | | |
| Example | C68 | HT(2)6 | 2.52 | CPL3 | 76% | 124% | 131% |
| 105 | | | | | | | |
| Example | C68 | HT(2)7 | 2.49 | CPL3 | 78% | 124% | 131% |
| 106 | | | | | | | |
| Example | C68 | HT(2)8 | 2.55 | CPL3 | 78% | 124% | 131% |
| 107 | | | | | | | |
| Example | C68 | HT(2)9 | 2.55 | CPL3 | 77% | 124% | 131% |
| 108 | | | | | | | |
| Example | C70 | HT(2)1 | 2.45 | CPL3 | 79% | 124% | 131% |
| 109 | | | | | | | |
| Example | C70 | HT(2)2 | 2.45 | CPL3 | 80% | 124% | 131% |
| 110 | | | | | | | |
| Example | C70 | HT(2)3 | 2.44 | CPL3 | 80% | 124% | 131% |
| 111 | | | | | | | |
| Example | C70 | HT(2)4 | 2.44 | CPL3 | 81% | 124% | 131% |
| 112 | | | | | | | |
| Example | C70 | HT(2)5 | 2.43 | CPL3 | 78% | 124% | 131% |
| 113 | | | | | | | |
| Example | C70 | HT(2)6 | 2.46 | CPL3 | 77% | 124% | 131% |
| 114 | | | | | | | |
| Example | C70 | HT(2)7 | 2.43 | CPL3 | 79% | 124% | 131% |
| 115 | | | | | | | |
| Example | C70 | HT(2)8 | 2.49 | CPL3 | 79% | 124% | 131% |
| 116 | | | | | | | |
| Example | C70 | HT(2)9 | 2.49 | CPL3 | 78% | 124% | 131% |
| 117 | | | | | | | |
| Example | S1 | HT(2)1 | 2.42 | CPL3 | 74% | 124% | 132% |
| 118 | | | | | | | |
| Example | S1 | HT(2)2 | 2.42 | CPL3 | 73% | 125% | 132% |
| 119 | | | | | | | |
| Example | S1 | HT(2)3 | 2.41 | CPL3 | 73% | 125% | 132% |
| 120 | | | | | | | |
| Example | S1 | HT(2)4 | 2.41 | CPL3 | 72% | 125% | 133% |
| 121 | | | | | | | |
| Example | S1 | HT(2)5 | 2.40 | CPL3 | 75% | 124% | 132% |
| 122 | | | | | | | |
| Example | S1 | HT(2)6 | 2.43 | CPL3 | 80% | 124% | 131% |
| 123 | | | | | | | |
| Example | S1 | HT(2)7 | 2.40 | CPL3 | 74% | 124% | 132% |
| 124 | | | | | | | |
| Example | S1 | HT(2)8 | 2.46 | CPL3 | 84% | 124% | 130% |
| 125 | | | | | | | |
| Example | S1 | HT(2)9 | 2.46 | CPL3 | 83% | 124% | 130% |
| 126 | | | | | | | |
| Example | S44 | HT(2)1 | 2.56 | CPL3 | 72% | 124% | 131% |
| 127 | | | | | | | |
| Example | S44 | HT(2)2 | 2.56 | CPL3 | 70% | 125% | 131% |
| 128 | | | | | | | |
| Example | S44 | HT(2)3 | 2.55 | CPL3 | 70% | 125% | 131% |
| 129 | | | | | | | |
| Example | S44 | HT(2)4 | 2.55 | CPL3 | 68% | 125% | 131% |
| 130 | | | | | | | |
| Example | S44 | HT(2)5 | 2.54 | CPL3 | 75% | 124% | 131% |
| 131 | | | | | | | |
| Example | S44 | HT(2)6 | 2.57 | CPL3 | 87% | 124% | 130% |
| 132 | | | | | | | |
| Example | S44 | HT(2)7 | 2.54 | CPL3 | 73% | 124% | 131% |
| 133 | | | | | | | |
| Example | S44 | HT(2)8 | 2.60 | CPL3 | 97% | 124% | 129% |
| 134 | | | | | | | |
| Example | S44 | HT(2)9 | 2.60 | CPL3 | 95% | 124% | 129% |
| 135 | | | | | | | |

TABLE 7

| | | Second | | | Driving | Luminescence | |
|---|---|---|---|---|---|---|---|
| | | hole | | | voltage | efficiency | Lifespan |
| | p- | transport | ΔT₁ | Capping | (relative | (relative | (relative |
| No. | dopant | material | (eV) | material | value) | value) | value) |
| Example | C56 | HT(2)1 | 2.47 | CPL4 | 79% | 123% | 130% |
| 136 | | | | | | | |
| Example | C56 | HT(2)2 | 2.47 | CPL4 | 80% | 123% | 130% |
| 137 | | | | | | | |
| Example | C56 | HT(2)3 | 2.46 | CPL4 | 80% | 123% | 130% |
| 138 | | | | | | | |
| Example | C56 | HT(2)4 | 2.46 | CPL4 | 81% | 123% | 130% |
| 139 | | | | | | | |
| Example | C56 | HT(2)5 | 2.45 | CPL4 | 78% | 123% | 130% |
| 140 | | | | | | | |
| Example | C56 | HT(2)6 | 2.48 | CPL4 | 76% | 123% | 130% |
| 141 | | | | | | | |
| Example | C56 | HT(2)7 | 2.45 | CPL4 | 79% | 123% | 130% |
| 142 | | | | | | | |
| Example | C56 | HT(2)8 | 2.51 | CPL4 | 79% | 123% | 130% |
| 143 | | | | | | | |
| Example | C56 | HT(2)9 | 2.51 | CPL4 | 78% | 123% | 130% |
| 144 | | | | | | | |
| Example | C68 | HT(2)1 | 2.51 | CPL4 | 79% | 123% | 130% |
| 145 | | | | | | | |
| Example | C68 | HT(2)2 | 2.51 | CPL4 | 80% | 123% | 130% |
| 146 | | | | | | | |
| Example | C68 | HT(2)3 | 2.50 | CPL4 | 80% | 123% | 130% |
| 147 | | | | | | | |
| Example | C68 | HT(2)4 | 2.50 | CPL4 | 81% | 123% | 130% |
| 148 | | | | | | | |
| Example | C68 | HT(2)5 | 2.49 | CPL4 | 78% | 123% | 130% |
| 149 | | | | | | | |
| Example | C68 | HT(2)6 | 2.52 | CPL4 | 77% | 123% | 130% |
| 150 | | | | | | | |
| Example | C68 | HT(2)7 | 2.49 | CPL4 | 79% | 123% | 130% |
| 151 | | | | | | | |
| Example | C68 | HT(2)8 | 2.55 | CPL4 | 79% | 123% | 130% |
| 152 | | | | | | | |
| Example | C68 | HT(2)9 | 2.55 | CPL4 | 78% | 123% | 130% |
| 153 | | | | | | | |
| Example | C70 | HT(2)1 | 2.45 | CPL4 | 80% | 123% | 130% |
| 154 | | | | | | | |
| Example | C70 | HT(2)2 | 2.45 | CPL4 | 80% | 123% | 130% |
| 155 | | | | | | | |
| Example | C70 | HT(2)3 | 2.44 | CPL4 | 80% | 123% | 130% |
| 156 | | | | | | | |
| Example | C70 | HT(2)4 | 2.44 | CPL4 | 82% | 123% | 130% |
| 157 | | | | | | | |
| Example | C70 | HT(2)5 | 2.43 | CPL4 | 79% | 123% | 130% |
| 158 | | | | | | | |
| Example | C70 | HT(2)6 | 2.46 | CPL4 | 77% | 123% | 130% |
| 159 | | | | | | | |
| Example | C70 | HT(2)7 | 2.43 | CPL4 | 79% | 123% | 130% |
| 160 | | | | | | | |
| Example | C70 | HT(2)8 | 2.49 | CPL4 | 80% | 123% | 130% |
| 161 | | | | | | | |
| Example | C70 | HT(2)9 | 2.49 | CPL4 | 79% | 123% | 130% |
| 162 | | | | | | | |
| Example | S1 | HT(2)1 | 2.42 | CPL4 | 74% | 123% | 131% |
| 163 | | | | | | | |
| Example | S1 | HT(2)2 | 2.42 | CPL4 | 73% | 124% | 131% |
| 164 | | | | | | | |
| Example | S1 | HT(2)3 | 2.41 | CPL4 | 73% | 124% | 131% |
| 165 | | | | | | | |
| Example | S1 | HT(2)4 | 2.41 | CPL4 | 72% | 124% | 132% |
| 166 | | | | | | | |
| Example | S1 | HT(2)5 | 2.40 | CPL4 | 75% | 123% | 131% |
| 167 | | | | | | | |
| Example | S1 | HT(2)6 | 2.43 | CPL4 | 81% | 123% | 130% |
| 168 | | | | | | | |
| Example | S1 | HT(2)7 | 2.40 | CPL4 | 74% | 123% | 131% |
| 169 | | | | | | | |
| Example | S1 | HT(2)8 | 2.46 | CPL4 | 85% | 123% | 129% |
| 170 | | | | | | | |
| Example | S1 | HT(2)9 | 2.46 | CPL4 | 84% | 123% | 129% |
| 171 | | | | | | | |
| Example | S44 | HT(2)1 | 2.56 | CPL4 | 73% | 123% | 130% |
| 172 | | | | | | | |
| Example | S44 | HT(2)2 | 2.56 | CPL4 | 71% | 124% | 130% |
| 173 | | | | | | | |
| Example | S44 | HT(2)3 | 2.55 | CPL4 | 71% | 124% | 130% |
| 174 | | | | | | | |
| Example | S44 | HT(2)4 | 2.55 | CPL4 | 69% | 124% | 130% |
| 175 | | | | | | | |
| Example | S44 | HT(2)5 | 2.54 | CPL4 | 76% | 123% | 130% |
| 176 | | | | | | | |
| Example | S44 | HT(2)6 | 2.57 | CPL4 | 88% | 123% | 129% |
| 177 | | | | | | | |
| Example | S44 | HT(2)7 | 2.54 | CPL4 | 73% | 123% | 130% |
| 178 | | | | | | | |
| Example | S44 | HT(2)8 | 2.60 | CPL4 | 98% | 123% | 128% |
| 179 | | | | | | | |
| Example | S44 | HT(2)9 | 2.60 | CPL4 | 96% | 123% | 128% |
| 180 | | | | | | | |

TABLE 8

| | | | | | Driving | Luminescence | |
|---|---|---|---|---|---|---|---|
| | | Second hole | | | voltage | efficiency | Lifespan |
| | p- | transport | ΔT₁ | Capping | (relative | (relative | (relative |
| No. | dopant | material | (eV) | material | value) | value) | value) |
| Comparative | 101 | 201 | 0.05 | CPL-R1 | 144% | 103% | 96% |
| Example 1 | | | | | | | |
| Comparative | 101 | 202 | 0.55 | CPL-R1 | 192% | 101% | 92% |
| Example 2 | | | | | | | |
| Comparative | 102 | 201 | 0.39 | CPL-R1 | 99% | 103% | 107% |
| Example 3 | | | | | | | |
| Comparative | 102 | 202 | 0.99 | CPL-R1 | 100% | 103% | 107% |
| Example 4 | | | | | | | |
| Comparative | 103 | 201 | 0.22 | CPL-R1 | 122% | 103% | 102% |
| Example 5 | | | | | | | |
| Comparative | 103 | 202 | 0.39 | CPL-R1 | 124% | 103% | 102% |
| Example 6 | | | | | | | |
| Comparative | — | 201 | — | CPL-R1 | 101% | 103% | 107% |
| Example 7 | | | | | | | |
| Comparative | — | 202 | — | CPL-R1 | 105% | 103% | 107% |
| Example 8 | | | | | | | |
| Comparative | — | 203 | — | CPL-R1 | 97% | 103% | 108% |
| Example 9 | | | | | | | |
| Comparative | 101 | 201 | 0.05 | CPL-R2 | 134% | 110% | 102% |
| Example 10 | | | | | | | |
| Comparative | 101 | 202 | 0.55 | CPL-R2 | 180% | 108% | 98% |
| Example 11 | | | | | | | |
| Comparative | 102 | 201 | 0.39 | CPL-R2 | 93% | 110% | 114% |
| Example 12 | | | | | | | |
| Comparative | 102 | 202 | 0.99 | CPL-R2 | 93% | 110% | 114% |
| Example 13 | | | | | | | |
| Comparative | 103 | 201 | 0.22 | CPL-R2 | 114% | 110% | 109% |
| Example 14 | | | | | | | |
| Comparative | 103 | 202 | 0.39 | CPL-R2 | 116% | 110% | 109% |
| Example 15 | | | | | | | |
| Comparative | — | 201 | — | CPL-R2 | 95% | 110% | 115% |
| Example 16 | | | | | | | |
| Comparative | — | 202 | — | CPL-R2 | 98% | 110% | 114% |
| Example 17 | | | | | | | |
| Comparative | — | 203 | — | CPL-R2 | 91% | 110% | 115% |
| Example 18 | | | | | | | |
| Comparative | 101 | 201 | 0.05 | — | 148% | 100% | 89% |
| Example 19 | | | | | | | |
| Comparative | 101 | 202 | 0.55 | — | 197% | 99% | 85% |
| Example 20 | | | | | | | |
| Comparative | 102 | 201 | 0.39 | — | 102% | 100% | 99% |
| Example 21 | | | | | | | |
| Comparative | 102 | 202 | 0.99 | — | 103% | 100% | 99% |
| Example 22 | | | | | | | |
| Comparative | 103 | 201 | 0.22 | — | 125% | 100% | 95% |
| Example 23 | | | | | | | |
| Comparative | 103 | 202 | 0.39 | — | 128% | 100% | 94% |
| Example 24 | | | | | | | |
| Comparative | — | 201 | — | — | 104% | 100% | 100% |
| Example 25 | | | | | | | |
| Comparative | — | 202 | — | — | 107% | 100% | 99% |
| Example 26 | | | | | | | |
| Comparative | — | 203 | — | — | 100% | 100% | 100% |
| Example 27 | | | | | | | |

From Tables 4 to 8, it was confirmed that the organic light-emitting devices of Example 1 to 180 had excellent or desired driving voltage, luminescence efficiency, and lifespan characteristics, compared to the organic light-emitting devices of Comparative Examples 1 to 27.

As the light-emitting device described above has a low driving voltage, high luminescence efficiency, and long lifespan, by utilizing the light-emitting device, a high-quality electronic apparatus and electronic equipment may be manufactured.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A light-emitting device comprising:
a first electrode;
a second electrode opposite the first electrode;
an interlayer arranged between the first electrode and the second electrode; and
a capping layer,
wherein
the interlayer comprises a hole transport region and an emission layer,
the hole transport region is arranged between the first electrode and the emission layer,
the hole transport region comprises a first layer and a second layer,
the first layer is arranged between the first electrode and the second layer,
the first layer comprises a first hole transport material and a p-dopant,
the second layer comprises a second hole transport material,
an absolute value of a difference between triplet energy of the p-dopant and triplet energy of the second hole transport material is about 1.50 eV or greater,
the second hole transport material is an amine-containing compound comprising i) a 1,1′:3′,1″-terphen-2′-yl group and ii) a cycloalkane group having 3 to 10 carbon atoms,
the emission layer is configured to emit a first light,
the capping layer is located in a path of travel of the first light,
the capping layer comprises a first capping material, and
the first capping material satisfies at least one selected from among Conditions 1 to 3:
Condition 1
the first capping material has a refractive index of about 1.70 or greater for light having a wavelength of about 633 nm;
Condition 2
the first capping material has a refractive index of about 1.90 or greater for light having a wavelength of about 530 nm; and
Condition 3
the first capping material has a refractive index of about 2.10 or greater for light having a wavelength of about 450 nm.

2. The light-emitting device of claim 1, wherein an amount of the p-dopant is about 0.01 parts by weight to about 10 parts by weight, based on 100 parts by weight of the first layer.

3. The light-emitting device of claim 1, wherein the second layer does not comprise a p-dopant.

4. The light-emitting device of claim 1, wherein the absolute value of the difference between the triplet energy of the p-dopant and the triplet energy of the second hole transport material is about 2.00 eV to about 3.00 eV.

5. The light-emitting device of claim 1, wherein the triplet energy of the p-dopant is about 0.05 eV to about 0.30 eV.

6. The light-emitting device of claim 1, wherein the singlet energy of the p-dopant is about 1.00 eV to about 2.50 eV.

7. The light-emitting device of claim 1, wherein an absolute value of a difference between the triplet energy and the singlet energy of the p-dopant is about 0.80 eV to about 2.45 eV.

8. The light-emitting device of claim 1, wherein the first hole transport material and the second hole transport material are each an amine-containing compound.

9. The light-emitting device of claim 1, wherein the first capping material satisfies Condition 1,
the first light is red light, and
the first capping material has a refractive index of about 1.70 or greater for the first light.

10. The light-emitting device of claim 1, wherein the first capping material satisfies Condition 2,
the first light is green light, and
the first capping material has a refractive index of about 1.90 or greater for the first light.

11. The light-emitting device of claim 1, wherein the first capping material satisfies Condition 3,
the first light is blue light, and
the first capping material has a refractive index of about 2.10 or greater for the first light.

12. The light-emitting device of claim 1, wherein the first capping material is a boron-containing compound.

13. The light-emitting device of claim 1, wherein the first capping material is a compound represented by Formula 8: 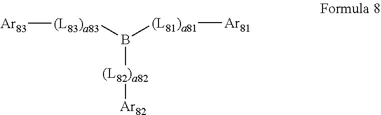
wherein in Formula 8,
L₈₁ to L₈₃ are each independently a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a81 to a83 are each independently an integer from 1 to 5,
Ar₈₁ to Ar₈₃ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

14. The light-emitting device of claim 13, wherein the first capping material is a compound represented by Formula 8-1: 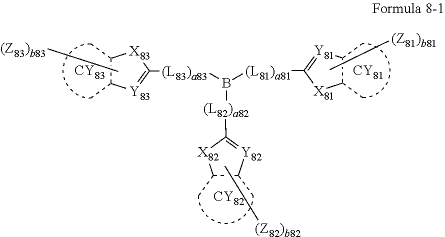
wherein in Formula 8-1,
L₈₁ to L₈₃ and a81 to a83 are each as described in Formula 8,
X₈₁ to X₈₃ are each independently O or S,
Y₈₁ to Y₈₃ are each independently N or C,
ring CY₈₁ to ring CY₈₃ are each independently a C₃-C₆₀ carbocyclic group or a C₁-C₆₀ heterocyclic group,
Z₈₁ to Z₈₃ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₁-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b81 to b83 are each independently an integer from 0 to 20,
Q₁ to Q₃ are each as described in connection with Q₁₁ in Formula 8, and
R₁₀ₐ is as described in Formula 8.

15. The light-emitting device of claim 14, wherein at least one selected from among ring CY₈₁ to ring CY₈₃ is a polycyclic group in which two or more 6-membered rings are condensed with each other, and
the two or more 6-membered rings are each a benzene group, a pyridine group, a pyrimidine group, a pyridazine group, or a pyrazine group.

16. The light-emitting device of claim 14, wherein ring CY₈₁ to ring CY₈₃ are each independently a benzene group, a naphthalene group, a phenanthrene group, an anthracene group, a pyrene group, a quinoline group, an isoquinoline group, or a phenanthroline group, and
at least one selected from among ring CY₈₁ to ring CY₈₃ is independently a naphthalene group, a phenanthrene group, an anthracene group, a pyrene group, a quinoline group, an isoquinoline group, or a phenanthroline group.

17. An electronic apparatus comprising the light-emitting device of claim 1.

18. The electronic apparatus of claim 17, further comprising a color filter, a color conversion layer, a touch screen layer, a polarizing layer, or any combination thereof.

19. An electronic equipment comprising the light-emitting device of claim 1.

20. The electronic equipment of claim 19, wherein the electronic equipment is one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard.
